(19) United States
(12) Patent Application Publication
(10) Pub. No.: US 2026/0362648 A1
(43) Pub. Date: Nov. 12, 2026

(54) DATA CENTER HVAC SYSTEM WITH COOLING DISTRIBUTION MATCHED TO POWER CONSUMPTION

(71) Applicant: Tyco Fire & Security GmbH, Neuhausen am Rheinfall (CH)

(72) Inventors: Michael J. Risbeck, West Chester, OH (US); Matthew J. Asmus, Watertown, WI (US); Jonathan D. Douglas, Mequon, WI (US); Timothy C. Gamroth, Dousman, WI (US)

(21) Appl. No.: 19/673,708

(22) Filed: May 11, 2026

Related U.S. Application Data
(60) Provisional application No. 63/804,558, filed on May 12, 2025.

(51) Int. Cl. H05K 7/20; H05K 7/14

(52) U.S. Cl. CPC H05K 7/207; H05K 7/1489; H05K 7/1497; H05K 7/20572; H05K 7/2059; H05K 7/20672; H05K 7/20681

(57) ABSTRACT

A data center cooling system includes cooling equipment operable to independently control a first amount of cooling provided to first heat-generating data center equipment within the data center and a second amount of cooling provided to second heat-generating data center equipment within the data center. The data center cooling system further includes a controller comprising one or more processing circuits and configured to determine a first power consumption of the first heat-generating data center equipment and a second power consumption of the second heat-generating data center equipment and operate the cooling equipment to adjust the first amount of cooling based on the first power consumption and adjust the second amount of cooling based on the second power consumption.

### CROSS-REFERENCE TO RELATED PATENT APPLICATION

This application claims the benefit of and priority to U.S. Provisional Patent Application No. 63/804,558 filed May 12, 2025, the entire disclosure of which is incorporated by reference herein.

### BACKGROUND

The present disclosure relates generally to heating, ventilation, and air conditioning (HVAC) systems for data centers. The present disclosure relates more particularly to cooling systems for data center equipment that generate heat during operation (e.g., servers, racks, blades, power supplies, etc.).

Data centers typically include racks of servers or other data center equipment that generate a substantial amount of heat during operation. Some data center cooling systems use fans to circulate cooled air through the server racks and provide cooling to the heat-generating equipment. Other data center cooling systems circulate a liquid coolant to the racks to draw heat directly from the heat-generating equipment or use a combination of air and liquid cooling. As data centers expand to support the rapid growth of cloud computing, artificial intelligence, and other modern applications having high computing loads and power densities, data centers need effective, energy-efficient cooling solutions that serve these applications while minimizing environmental impact.

### SUMMARY

At least one aspect relates to a data center cooling system. The system can include cooling equipment operable to independently control a first amount of cooling provided to first heat-generating data center equipment within a data center and a second amount of cooling provided to second heat-generating data center equipment within the data center. The system can include a controller comprising one or more processing circuits and configured to determine a first power consumption of the first heat-generating data center equipment and a second power consumption of the second heat-generating data center equipment. The system can operate the cooling equipment to adjust the first amount of cooling based on the first power consumption and adjust the second amount of cooling based on the second power consumption.

In some implementations, the controller can be configured to determine the first power consumption and the second power consumption based on power supply information provided by one or more power distribution units that supply power to the first heat-generating data center equipment and the second heat-generating data center equipment.

In some implementations, the first heat-generating data center equipment can be located within a first rack of the data center. In some implementations, the second heat-generating data center equipment can be located within a second rack of the data center. In some implementations, the controller can be configured to determine the first power consumption and the second power consumption based on power supply information provided by a first power distribution unit for the first rack and a second power distribution unit for the second rack.

In some implementations, the first heat-generating data center equipment can be installed on a first server tray located within a rack of the data center. In some implementations, the second heat-generating data center equipment can be installed on a second server tray located within the rack of the data center. In some implementations, the controller can be configured to determine the first power consumption and the second power consumption based on respective amounts of power delivered to the first server tray and the second server tray by a power distribution unit for the rack.

In some implementations, the controller can be configured to adjust the first amount of cooling and the second amount of cooling to be proportionate to the first power consumption and the second power consumption respectively.

In some implementations, the controller can be configured to determine a first proportion of the first power consumption to a total power consumption of heat-generating data center equipment served by the cooling system. In some implementations, the controller can be configured to determine a second proportion of the second power consumption to the total power consumption of the heat-generating data center equipment served by the cooling system. In some implementations, the controller can be configured to operate the cooling equipment to adjust the first amount of cooling and the second amount of cooling based on the first proportion and the second proportion respectively.

In some implementations, the controller can be configured to determine a total amount of cooling to be provided by the cooling system. In some implementations, the controller can be configured to adjust the first amount of cooling such that a proportion of the first amount of cooling to the total amount of cooling is equal to the first proportion. In some implementations, the controller can be configured to adjust the second amount of cooling such that a proportion of the second amount of cooling to the total amount of cooling is equal to the second proportion.

In some implementations, the cooling equipment can comprise a liquid cooling system configured to supply a liquid coolant to the first heat-generating data center equipment and the second heat-generating data center equipment. In some implementations, the controller can be configured to operate the liquid cooling system to adjust a first flow rate of the liquid coolant supplied to the first heat-generating data center equipment based on the first power consumption. In some implementations, the controller can be configured to operate the liquid cooling system to adjust a second flow rate of the liquid coolant supplied to the second heat-generating data center equipment based on the second power consumption.

In some implementations, the controller can be configured to adjust the first flow rate of the liquid coolant supplied to the first heat-generating data center equipment and the second flow rate of the liquid coolant supplied to the second heat-generating data center equipment to be proportionate to the first power consumption and the second power consumption respectively.

In some implementations, the cooling equipment can comprise an air cooling system configured to supply chilled air to the first heat-generating data center equipment and the second heat-generating data center equipment. In some implementations, the controller can be configured to operate the air cooling system to adjust a first flow rate of the chilled air supplied to the first heat-generating data center equipment based on the first power consumption. In some implementations, the controller can be configured to operate the air cooling system to adjust a second flow rate of the chilled air supplied to the second heat-generating data center equipment based on the second power consumption.

In some implementations, the controller can be configured to adjust the first flow rate of the chilled air supplied to the first heat-generating data center equipment and the second flow rate of the chilled air supplied to the second heat-generating data center equipment to be proportionate to the first power consumption and the second power consumption respectively.

In some implementations, the controller can be configured to estimate a first cooling load of the first heat-generating data center equipment based on the first power consumption. In some implementations, the controller can be configured to estimate a second cooling load of the second heat-generating data center equipment based on the second power consumption. In some implementations, the controller can be configured to operate the cooling equipment to provide the first amount of cooling the first heat-generating data center equipment and provides the second amount of cooling the second heat-generating data center equipment based on the first cooling load and the second cooling load respectively.

In some implementations, the cooling equipment can comprise a liquid cooling system configured to supply a liquid coolant to the first heat-generating data center equipment and the second heat-generating data center equipment. In some implementations, operating the cooling equipment can comprise operating one or more pumps or valves of the liquid cooling system to control a distribution of the liquid coolant to the first heat-generating data center equipment and the second heat-generating data center equipment based on the first power consumption and the second power consumption.

In some implementations, controlling the distribution of the liquid coolant can comprise adjusting a first flow rate of the liquid coolant supplied to the first heat-generating data center equipment based on the first power consumption. In some implementations, controlling the distribution of the liquid coolant can comprise adjusting a second flow rate of the liquid coolant supplied to the second heat-generating data center equipment based on the second power consumption.

In some implementations, the cooling equipment can comprise an air cooling system configured to supply chilled air to the first heat-generating data center equipment and the second heat-generating data center equipment. In some implementations, operating the cooling equipment can comprise operating one or more fans or dampers of the air cooling system to control a distribution of the chilled air to the first heat-generating data center equipment and the second heat-generating data center equipment based on the first power consumption and the second power consumption.

In some implementations, controlling the distribution of the chilled air can comprise adjusting a first flow rate of the chilled air supplied to the first heat-generating data center equipment based on the first power consumption. In some implementations, controlling the distribution of the liquid coolant can comprise adjusting a second flow rate of the chilled air supplied to the second heat-generating data center equipment based on the second power consumption.

In some implementations, the controller can be configured to determine the first power consumption and the second power consumption based on measurements from one or more sensors within the data center.

In some implementations, the measurements can comprise measurements of power, voltage, current, energy, or any other quantity from which the first power consumption and the second power consumption can be derived.

In some implementations, the controller can be configured to obtain values of a plurality of controlled temperatures affected by cooling the heat-generating data center equipment, the plurality of controlled temperatures comprising temperatures of a plurality of components of the data center comprising one or more racks, one or more server trays, one or more server blades, one or more chips, and/or one or more devices of the heat-generating data center equipment. In some implementations, the controller can be configured to independently adjust amounts of cooling provided to the plurality of components of the data center based on their respective controlled temperatures, wherein independently adjusting an amount of cooling provided to a component of the data center comprises adjusting a temperature, a pressure, and/or a flow rate of the liquid coolant supplied to that component of the data center independent of the temperatures, flow rates, and/or pressures of the liquid coolant supplied to other components of the data center.

In some implementations, the controller can be configured to obtain a plurality of power consumption values for a plurality of components of the data center comprising one or more racks, one or more server trays, one or more server blades, one or more chips, and/or one or more devices of the heat-generating data center equipment. In some implementations, the controller can be configured to independently adjust amounts of cooling provided to the plurality of components of the data center based on their respective power consumption values, wherein independently adjusting an amount of cooling provided to a component of the data center comprises adjusting a temperature, a pressure, and/or a flow rate of the liquid coolant supplied to that component of the data center independent of the temperatures, flow rates, and/or pressures of the liquid coolant supplied to other components of the data center.

In some implementations, the controller can be configured to obtain a first temperature value affected by cooling the first heat-generating data center equipment and a second temperature value affected by cooling the second heat-generating data center equipment. In some implementations, the controller can be configured to operate the cooling equipment to adjust the first amount of cooling based on the first power consumption and the first temperature value. In some implementations, the controller can be configured to operate the cooling equipment to adjust the second amount of cooling based on the second power consumption and the second temperature value.

In some implementations, the first temperature value and the second temperature value can comprise at least one of measured or reported temperatures of the first heat-generating data center equipment and the second heat-generating data center equipment respectively, measured temperatures of a liquid coolant returning to the cooling equipment after absorbing heat from the first heat-generating data center equipment and the second heat-generating data center equipment respectively, and/or measured temperatures of chilled air returning to the cooling equipment after absorbing heat from the first heat-generating data center equipment and the second heat-generating data center equipment respectively.

At least one other aspect relates to a method. The method can be performed, for example, by one or more processors coupled to non-transitory memory. The method can include determining a first power consumption of first heat-generating data center equipment and a second power consumption of second heat-generating data center equipment cooled by a data center cooling system. The method can include determining a first amount of cooling to provide to the first heat-generating data center equipment based on the first power consumption and a second amount of cooling to provide to the second heat-generating data center equipment based on the second power consumption. The method can include operating the data center cooling system to provide the first amount of cooling to the first heat-generating data center equipment and the second amount of cooling to the second heat-generating data center equipment.

In some embodiments, the method includes determining the first power consumption and the second power consumption based on power supply information provided by one or more power distribution units that supply power to the first heat-generating data center equipment and the second heat-generating data center equipment.

In some embodiments, the first heat-generating data center equipment are located within a first rack of the data center, the second heat-generating data center equipment are located within a second rack of the data center, and the first power consumption and the second power consumption are determined based on power supply information provided by a first power distribution unit for the first rack and a second power distribution unit for the second rack.

These and other aspects and implementations are discussed in detail below. The foregoing information and the following detailed description include illustrative examples of various aspects and implementations and provide an overview or framework for understanding the nature and character of the claimed aspects and implementations. The drawings provide illustration and a further understanding of the various aspects and implementations and are incorporated in and constitute a part of this specification. Aspects can be combined, and it will be readily appreciated that features described in the context of one aspect of the invention can be combined with other aspects. Aspects can be implemented in any convenient form, for example, by appropriate computer programs, which may be carried on appropriate carrier media (computer readable media), which may be tangible carrier media (e.g., disks) or intangible carrier media (e.g., communications signals). Aspects may also be implemented using any suitable apparatus, which may take the form of programmable computers running computer programs arranged to implement the aspect. As used in the specification and in the claims, the singular form of ‘a,’ ‘an,’ and ‘the’ include plural referents unless the context clearly dictates otherwise.

### BRIEF DESCRIPTION OF THE DRAWINGS

The accompanying drawings are not intended to be drawn to scale. Like reference numbers and designations in the various drawings indicate like elements. For purposes of clarity, not every component may be labeled in every drawing. In the drawings:

FIG. 1 is a perspective view of a data center room including racks served by a data center cooling system, according to some embodiments.

FIG. 2 is a block diagram of the data center cooling system of FIG. 1, according to some embodiments.

FIG. 3 is a block diagram illustrating a rack of the data center room of FIG. 1 in greater detail, according to some embodiments.

FIG. 4 is a perspective view of a server tray which can be installed in the racks of the data center room of FIG. 1, according to some embodiments.

FIG. 5 is a block diagram illustrating operation of the data center cooling system of FIG. 1 to control pressure or flow rate of a liquid coolant in a liquid circuit based on feedback indicating a controlled temperature affected by the data center cooling system, according to some embodiments.

FIG. 6 is a flowchart of a process executed by the data center cooling system of FIG. 1 when performing the operation illustrated in FIG. 5, according to some embodiments.

FIG. 7 is a block diagram illustrating operation of the data center cooling system of FIG. 1 to control temperature of a liquid coolant supplied by a liquid coolant circuit based on feedback indicating a controlled temperature affected by the data center cooling system, according to some embodiments.

FIG. 8 is a flowchart of a process executed by the data center cooling system of FIG. 1 when performing the operation illustrated in FIG. 7, according to some embodiments.

FIG. 9 is a block diagram illustrating operation of the data center cooling system of FIG. 1 to predict an amount of heat that will be generated by data center equipment at a future time and operate a liquid cooling system and an air cooling system of the data center cooling system based on the predicted amount of heat, according to some embodiments.

FIG. 10 is a flowchart of a process executed by the data center cooling system of FIG. 1 when performing the operation illustrated in FIG. 9, according to some embodiments.

FIG. 11 is a block diagram illustrating operation of the data center cooling system of FIG. 1 to adjust a flow rate or pressure of a liquid coolant in a liquid coolant circuit in response to a change in a hydraulic resistance of the liquid coolant circuit caused by fluidly disconnecting a first branch from the liquid coolant circuit or fluidly connecting the first branch to the liquid coolant circuit, according to some embodiments.

FIG. 12 is a flowchart of a process executed by the data center cooling system of FIG. 1 when performing the operation illustrated in FIG. 11, according to some embodiments.

FIG. 13 is a schematic diagram of a hydraulic network of the data center cooling system of FIG. 1, illustrating an example arrangement in which one or more variable-Cv flow control valves are positioned at a rack level of the hydraulic network, according to some embodiments.

FIG. 14 is a schematic diagram of a hydraulic network of the data center cooling system of FIG. 1, illustrating an example arrangement in which one or more variable-Cv flow control valves are positioned at a server level of the hydraulic network, according to some embodiments.

FIG. 15 is a schematic diagram of a hydraulic network of the data center cooling system of FIG. 1, illustrating an example arrangement in which one or more variable-Cv flow control valves are positioned at a chip level of the hydraulic network, according to some embodiments.

FIG. 16 is a block diagram illustrating operation of the data center cooling system of FIG. 1 to determine power consumption of multiple different sets of data center equipment and allocate cooling to each set of data center equipment based on its respective power consumption, according to some embodiments.

FIG. 17 is a flowchart of a process executed by the data center cooling system of FIG. 1 when performing the operation illustrated in FIG. 16, according to some embodiments.

### DETAILED DESCRIPTION

Below are detailed descriptions of various concepts related to, and approaches, methods, apparatuses, and systems for implementing the various techniques described herein. The various concepts introduced above and discussed in greater detail below may be implemented in any of numerous ways, as the described concepts are not limited to any particular manner of implementation. Examples of specific implementations and applications are provided primarily for illustrative purposes.

Referring generally to the FIGURES, a HVAC system for a data center is shown, according to some embodiments. Data centers typically include racks of servers or other data center equipment that generate a substantial amount of heat during operation. Some data center cooling systems use fans to circulate cooled air through the server racks and provide cooling to the heat-generating equipment. Other data center cooling systems circulate a liquid coolant (e.g., water, glycol, etc.) to the racks to draw heat directly from the heat-generating equipment or use a combination of air and liquid cooling.

As data centers expand to support the rapid growth of cloud computing, artificial intelligence (AI), and high-performance computing (HPC), data centers need effective, energy-efficient cooling solutions to handle rising power densities while minimizing environmental impact. Conventional data center cooling infrastructures are often inadequate to provide sufficient cooling to modern data centers due to significantly higher power densities and heat generated relative to traditional data centers. For example, each central processing unit (CPU) in a traditional data center server may have a thermal design power (TDP) of 250-350 Watts, whereas a modern data center server may include several graphics processing units (GPUs) with TDPs of 1.2 kW each to support AI applications. A modern data center server with 8 GPUs and 2 CPUs may have a total TDP of 10,000 Watts per AI server, as compared to 700 Watts for traditional servers with two CPUs. Conventional data center cooling infrastructures often cannot support the high power densities and thermal loads of modern data centers.

Additionally, conventional data center cooling systems are often designed to provide the same amount of cooling (e.g., airflow, water flow, etc.) to all server racks in a given data center room or aisle. This can lead to inefficiencies (e.g., excess cooling, increased energy consumption, etc.) if the heat load generated by the data center equipment is concentrated in a subset of the server racks because the cooling system will operate to ensure that the hottest server rack is kept within temperature limits, and thus provides more cooling than necessary to the server racks that are generating a lesser heat load. This problem is exacerbated in modern data centers which have high disparities in TDP between server racks or individual servers used for different purposes (e.g., conventional CPU-based computing vs. GPU-based AI applications). It would be desirable to provide an improved cooling infrastructure for modern data centers that addresses these and other deficiencies of conventional data center cooling systems.

The data center cooling system described herein provides an improved cooling infrastructure which addresses several challenges unique to modern data centers. For example, the data center cooling system described herein provides an effective, energy-efficient cooling infrastructure for modern data centers designed to handle rising power densities while minimizing environmental impact.

One advantage provided by the data center cooling system described herein is the ability to precisely control the amount of cooling provided to individual racks, blades, servers, or individual CPUs, GPUs, or other heat-generating components in the data center. The data center cooling system may use a combination of air cooling and liquid cooling, both of which can be precisely controlled to provide targeted cooling to specific heat-generating components to efficiently serve the heat load of the data center without providing overcooling. For example, the data center cooling system may include controllable dampers, fans, or other airside equipment capable of increasing or decreasing the amount of airflow through each rack, to each server or blade, or to individual heat-generating components within a given rack or blade to individually modulate the amount of cooling provided by the air cooling components. Similarly, the data center cooling system may include valves, actuators, pumps, or other waterside equipment capable of increasing or decreasing the amount of liquid coolant flowing through each rack, to each server or blade, or to individual heat-generating components within a given rack or blade to individually modulate the amount of cooling provided by the liquid cooling components. In some embodiments, the temperatures of the air, the liquid coolant, or both the air and the liquid coolant can be independently controlled, in addition to or instead of controlling their flow rates, to adjust the amount of cooling provided by the air and the liquid coolant respectively.

Another advantage provided by the data center cooling system described herein is the ability to respond to sudden changes in cooling requirements of the data center equipment. The amount of cooling required depends on the computing load of each data center component (e.g., CPUs, GPUs, power supplies, etc.) at each point in time and may change rapidly in some cases. The data center cooling system can satisfy the time-varying cooling loads of the data center equipment in an economical manner, using a combination of targeted air cooling and liquid cooling. For example, liquid cooling or a combination of liquid cooling and air cooling can be used for computing devices with relatively higher cooling requirements (e.g., AI racks, GPU blades, etc.), whereas air cooling alone can be used for computing devices with relatively lower cooling requirements (e.g., conventional CPU racks or blades). The amount of cooling provided to each data center component can be controlled granularly and rapidly adjusted to respond to observed changes in heat generation and/or to preemptively compensate for predicted changes in heat generation (e.g., using a feedback control technique and/or a feedforward or predictive control technique).

The data center cooling system may include a variety of sensors (e.g., temperature sensors, flow rate sensors, pressure sensors, etc.) positioned to measure the temperatures, flow rates, pressures, or other conditions of the airflow and liquid flow at various locations within the cooling system. For example, air sensors can be positioned at the outlet of an air cooler, within an under-floor plenum, at the inlet or outlet of each rack, at the inlet or outlet of each server or blade, or otherwise within the data center to measure the temperatures, flow rates, pressures, and/or other conditions of the airflow at the locations of the air sensors. Similarly, liquid sensors can be positioned at the inlets or outlets of the chillers, inlets or outlets of a coolant distribution unit (CDU), inlets or outlets of individual racks, servers, or blades, or immediately upstream or downstream of individual heat-generating components to measure the temperatures, flow rates, pressures, and/or other conditions of the liquid coolant at the locations of the liquid sensors. The data center cooling system may include a controller configured to use the feedback from these and other sensors to control the operable components (e.g., fans, dampers, valves, pumps, chillers, etc.) to precisely modulate the amount of cooling provided to each heat-generating component, server, blade, rack, or other portion of the data center. These and other features of the data center cooling system are described in detail below.

### Data Center Cooling System

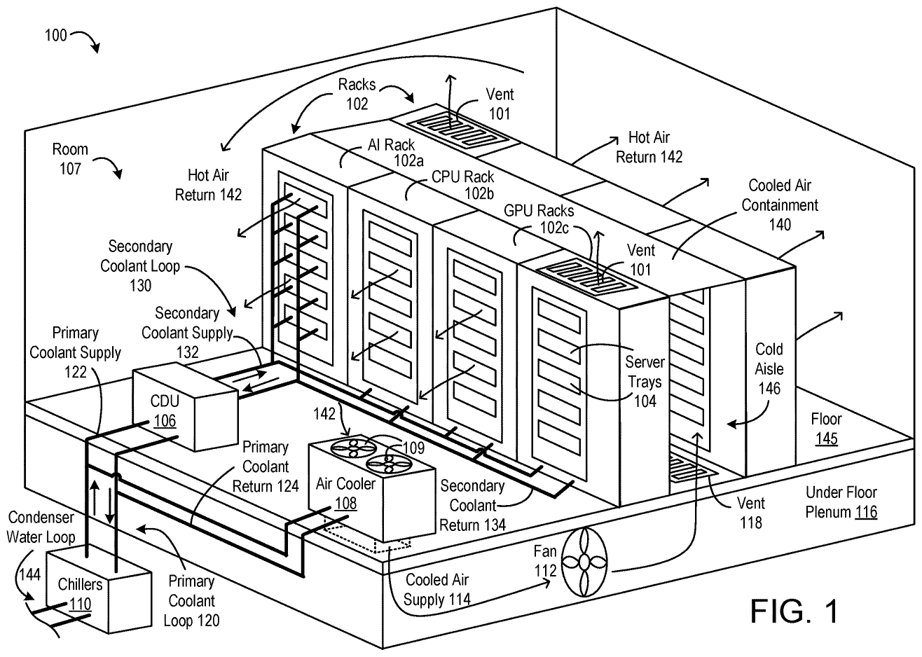

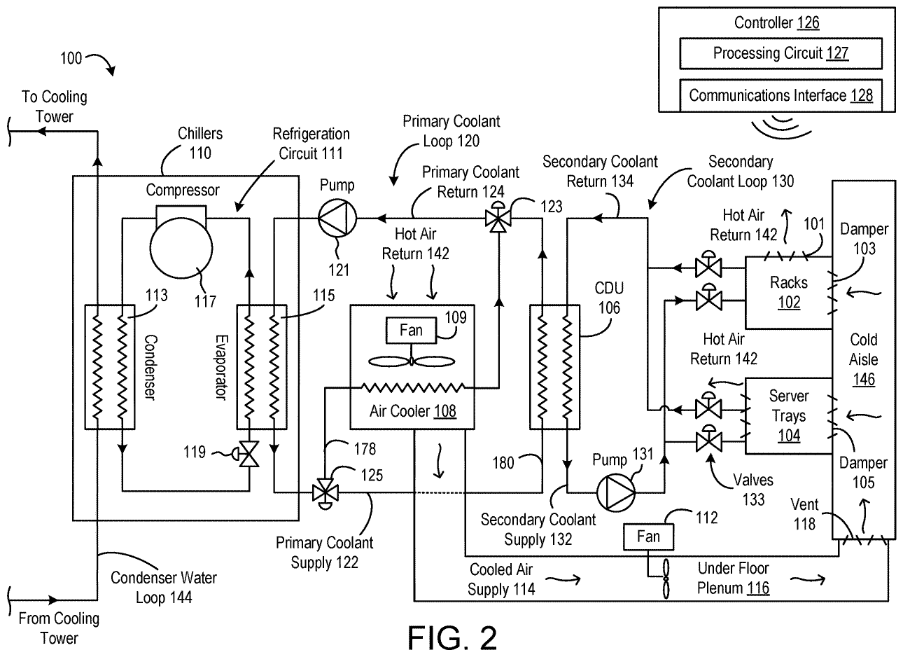

Referring now to FIGS. 1-2, a data center cooling system 100 is shown, according to an exemplary embodiment. FIG. 1 is a perspective view of a data center room 107 served by data center cooling system 100, whereas FIG. 2 is a block diagram of data center cooling system 100. Data center room 107 is shown to include several racks 102a, 102b, and 102c (collectively racks 102) containing server trays 104 (e.g., server blades, server boxes, other computing devices, etc.). Racks 102 may be arranged in rows (e.g., side-to-side) to form aisles between adjacent rows of racks 102. In some embodiments, the aisles form an alternating sequence of cold aisles and hot aisles on opposite sides of racks 102. For example, the space between the two rows of racks 102 in FIG. 1 is shown as a cold aisle 146 which provides a cooled air supply 114 to racks 102. Cold aisle 146 may be bounded on opposite sides by racks 102, on the bottom by floor 145 (i.e., the floor of data center room 107), and on the top by a cooled air containment 140 (e.g., a solid surface) to contain cooled air supply 114 within cold aisle 146. In some embodiments, cooled air containment 140 also extends vertically along the ends of cold aisle 146 to form a wall perpendicular to both the top surface of cooled air containment 140 and the front and rear surfaces of racks 102 (i.e., the surfaces on which server trays 104 are visible) to prevent cooled air supply 114 from escaping cold aisle 146 via the ends.

In some embodiments, the adjacent rows of racks 102 are arranged front-to-front (i.e., such that the front surfaces of adjacent rows of racks 102 face each other) and back-to-back (i.e., such that the rear surfaces of adjacent rows of racks 102 face each other). For example, as shown in FIG. 1, cold aisle 146 is located between the rear surfaces of adjacent rows of racks 102, whereas the front surfaces of racks 102 face toward hot aisles. In some embodiments, a vent 118 is located along floor 145 of cold aisle 146 to allow cooled air supply 114 to flow into cold aisle 146 from an under floor plenum 116. Racks 102 may draw or receive cooled air supply 114 into racks 102 from cold aisle 146 and pass cooled air supply 114 over heat-producing data center equipment contained within racks 102 (e.g., CPUs, GPUs, dual inline memory modules (DIMMs), servers, power supplies, etc.) which transfer heat to cooled air supply 114. The heated airflow then exits racks 102 through the front surfaces of racks 102 (i.e., the surfaces opposite cold aisle 146) and/or through the top surfaces of racks 102 via vents 101. The heated airflow exiting racks 102 then flows into data center room 107 as a hot air return 142.

In some embodiments, racks 102 can be designated as a particular type based on the type of computing devices they contain (e.g., CPUs, GPUs, DIMMs, ASICs, etc.) and/or based on the type of computing application they run during operation (e.g. AI applications, high performance computing applications, standard computing applications, etc.). For example, rack 102a is shown as an AI rack, rack 102b is shown as a CPU rack, and racks 102c are shown as GPU racks. Similarly, server trays 104 can be designated as AI server trays, CPU server trays, or GPU server trays based on the type of computing devices within server trays 104 and/or the type of computing applications by server trays 104. In some embodiments, data center cooling system 100 uses the type of racks 102 and/or server trays 104 to determine the amount of cooling to provide to each of racks 102 and/or server trays 104. For example, AI rack 102a and GPU racks 102c may require a higher amount of cooling whereas CPU rack 102b may require a lower amount of cooling. Similarly, AI server trays and GPU server trays may require a higher amount of cooling whereas CPU server trays may require a lower amount of cooling.

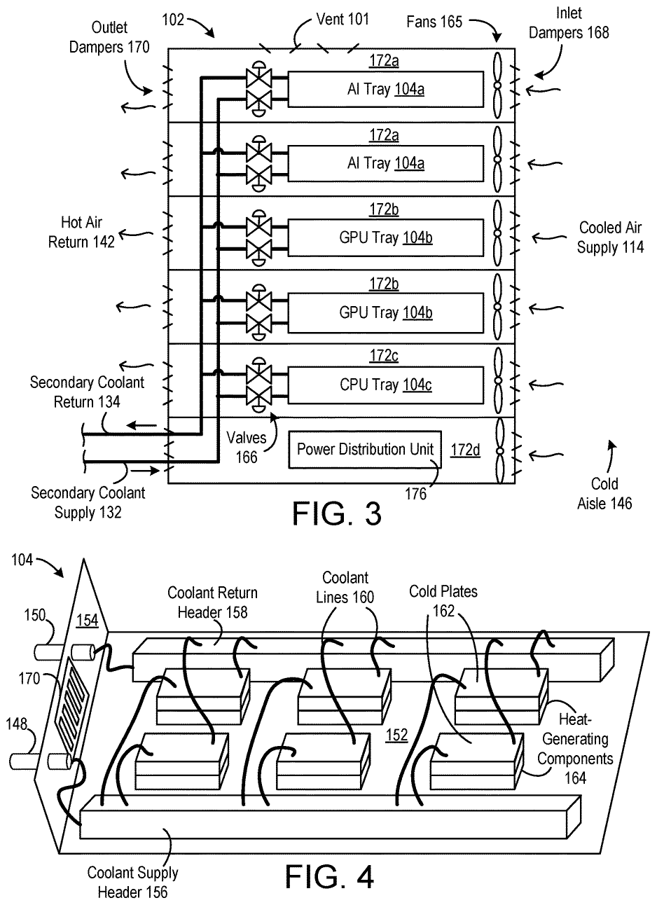

In various embodiments, racks 102 may include top vents 101 located on the top surfaces of racks 102, front vents aligned with each of server trays 104 on the front surfaces of racks 102, or a combination of top vents 101 and front vents. In some embodiments, one or more of racks 102 includes a top vent 101, whereas one or more other racks 102 include front vents. In racks 102 with top vents 101, some or all of the internal volume within such racks 102 may by fluidly connected to allow some or all of the airflow through such racks 102 to exit racks 102 via top vents 101. In racks 102 with front vents aligned with server trays 104, some or all of the internal volume within racks 102 may be portioned into separate compartments within which one or more of server trays 104 are contained. Each compartment may receive a separate airflow stream to provide targeted cooling to the heat-generating equipment contained within the corresponding compartment. One example of how racks 102 can be partitioned into isolated compartments is described in greater detail with reference to FIG. 3. Although only one of GPU racks 102c is shown with top vents 101 in FIG. 1, it is contemplated that any number or type of racks 102 can include top vents 101 and/or or front vents regardless of the type of rack 102. For example, any of AI rack 102a, CPU rack 102b, and/or GPU racks 102c can include front vents and/or top vents 101 in various embodiments.

Still referring to FIGS. 1-2, data center cooling system 100 is shown to include air cooling equipment (shown in subsequent figures as air cooling system 230) which provides air cooling to racks 102. The air cooling equipment are shown to include an air cooler 108 and fans 109 and 112 which operate to circulate airflow between air cooler 108 and racks 102. Fan 109 may be positioned to move hot air return 142 from data center room 107 into and through air cooler 108. Air cooler 108 may include any of a variety of airside HVAC equipment configured to provide cooling to hot air return 142 and/or generate cooled air supply 114. For example, air cooler 108 may include one or more computer room air conditioner (CRAC) units, computer room air handler (CRAH) units, direct evaporative cooling (DEC) units, indirect evaporative cooling (IEC) units, free cooling units (e.g., airside economizers), or any other type of airside HVAC equipment. Air cooler 108 may include one or more heat exchangers configured to absorb heat from hot air return 142 to generate cooled air supply 114. In various embodiments, air cooler 108 can be configured to provide mechanical cooling, free cooling, or a combination of mechanical cooling and free cooling to generate cooled air supply 114. For example, air cooler 108 can include any combination of mechanical cooling and free cooling components, as described U.S. Pat. No. 9,982,903 granted May 29, 2018, the entire disclosure of which is incorporated by reference herein. Fan 109 can be operated to adjust the airflow rate of cooled air supply 114 and/or the amount of cooling provided to hot air return 142 to generate cooled air supply 114 by controlling the rate at which the airflow passes through air cooler 108.

In some embodiments, air cooler 108 generates cooled air supply 114 by removing heat from hot air return 142. For example, as shown in FIG. 2, air cooler 108 may include an internal heat exchanger (e.g., an air-to-liquid heat exchanger, a cooling coil, etc.) configured to transfer heat from the airflow passing through air cooler 108 into a primary coolant circulating through air cooler 108 via the heat exchanger. In some embodiments, air cooler 108 is configured to generate cooled air supply 114 by exhausting hot air return 142 (e.g., outdoors or into another space other than data center room 107) and drawing cool air into air cooler 108 (e.g., from outdoors or another space) to replace the exhausted hot air return 142. For example, air cooler 108 may operate as an airside economizer configured to provide free cooling to data center room 107 and/or racks 102 when outdoor temperature conditions permit the use of outdoor air. In various embodiments, air cooler 108 may generate cooled air supply 114 by mechanical cooling (e.g., removing heat from hot air return 142), by free cooling (e.g., replacing some or all of hot air return 142 with cooler outdoor air), or by using a combination of mechanical cooling and free cooling.

Air cooler 108 may deliver cooled air supply 114 into under floor plenum 116 which occupies a space below floor 145 of data center room 107. Fan 112 may be located within under floor plenum 116 and configured to move cooled air supply 114 through under floor plenum 116 and into cold aisle 146 via vent 118. Fan 112 can be operated to control the flow rate of cooled air supply 114 through under floor plenum 116 and into cold aisle 146. In some embodiments, data center cooling system 100 may include dampers 103 positioned at the air inlets of racks 102 (e.g., between racks 102 and cold aisle 146 as shown in FIG. 2). Dampers 103 can be operated to modulate the amount of airflow into each of racks 102 individually. Similarly, data center cooling system 100 may include dampers 105 positioned at the air inlets of server trays 104 (e.g., between server trays 104 and cold aisle 146 as shown in FIG. 2). In some embodiments, dampers 103 are used for racks 102 in which some or all of the internal volume is fluidly connected such that the amount of airflow into each rack 102 is controllable at the rack level. Conversely, dampers 105 may be used for racks 102 which are subdivided into compartments to control the airflow through each compartment individually. Although dampers 103 and 105 are shown at the inlets of racks 102 and server trays 104 respectively in FIG. 2, it is contemplated that dampers 103 and dampers 105 may be located at the outlets of racks 102 and server trays 104 or otherwise positioned within racks 102 to control the amount of airflow through each of racks 102 and/or compartments of racks 102.

Still referring to FIGS. 1-2, data center cooling system 100 is shown to include liquid cooling equipment (shown in subsequent figures as liquid cooling system 220) which provides liquid cooling to racks 102. The liquid cooling equipment are shown to include a coolant distribution unit (CDU) 106, chillers 110, a primary coolant loop 120, a secondary coolant loop 130, and a condenser water loop 144. Chillers 110 may be configured to provide cooling to a primary coolant (e.g., water, glycol, CO2, ammonia, etc.) which circulates between chillers 110, air cooler 108, and CDU 106 via primary coolant loop 120. As shown in FIG. 2, chillers 110 may include an internal refrigeration circuit 111 including a compressor 117, a condenser 113, an expansion valve 119, and an evaporator 115. Compressor 117 can be configured to circulate a refrigerant between condenser 113 and evaporator 115 via refrigeration circuit 111. Compressor 117 operates to compress the refrigerant to a high pressure, high temperature state. The compressed refrigerant flows through condenser 113, which transfers heat from the refrigerant in refrigeration circuit 111 to the water in condenser water loop 144. The cooled refrigerant then flows through expansion valve 119, which expands the refrigerant to a low temperature, low pressure state. The expanded refrigerant flows through evaporator 115, which transfers heat from the primary coolant in primary coolant loop 120 to the refrigerant in refrigeration circuit 111. In some embodiments, condenser water loop 144 circulates water or another coolant between condenser 113 and a cooling tower or other location (e.g., another heat exchanger) where the water rejects heat before returning to condenser 113.

In various embodiments, primary coolant loop 120 circulates the primary coolant between chillers 110 and one or both of CDU 106 and air cooler 108. Primary coolant loop 120 may include a pump 121 configured to circulate the primary coolant within primary coolant loop 120. Pump 121 can be operated to control the flow rate of the primary coolant within primary coolant loop 120. In some embodiments, primary coolant loop 120 includes one or more valves 123 and 125 configured to control the flow of the primary coolant through branches 178 and 180 of primary coolant loop 120. Branch 180 may pass through CDU 106, whereas branch 178 may pass through air cooler 108. In some embodiments, as shown in FIG. 2, valves 123 and 125 may be three-way valves positioned at the intersections of branches 178 and 180 (i.e., the location at which primary coolant loop 120 splits into branches 178 and 180) and can be operated to control the flow of the primary coolant supply 122 from chillers 110 to CDU 106 and/or to air cooler 108. Alternatively, valves 123 and 125 can be two-way valves having a single inlet and a single outlet (e.g., on/off valves, adjustable valves, modulating valves, etc.) located along each branch 178 and 180 of primary coolant loop 120 such that valves 123 and 125 can be operated to control the flow of the primary coolant to each of air cooler 108 and CDU 106 individually. In various embodiments, such two-way valves can be located between the intersections shown in FIG. 2 and air cooler 108 (e.g., upstream and/or downstream of air cooler 108), between the intersections shown in FIG. 2 and CDU 106 (e.g., upstream and/or downstream of CDU 106), or otherwise positioned along branches 178 and 180 to selectively control the flow rate of primary coolant supply 122 along each of branches 178 and 180.

The liquid coolant in primary coolant loop 120 is cooled by chillers 110 in evaporator 115 to generate primary coolant supply 122. Although only one evaporator 115 is shown in FIG. 2 for ease of illustration, it is contemplated that primary coolant loop 120 may include one or more evaporators 115 arranged in parallel (e.g., parts of parallel chillers 110) or in series (e.g., parts of series chillers 110) to provide cooling to the liquid coolant circulating in primary coolant loop 120. Primary coolant supply 122 flows through primary coolant loop 120 into branch 178 which passes through air cooler 108 and/or branch 180 which passes through CDU 106. The primary coolant absorbs heat from hot air return 142 in air cooler 108 and/or from the secondary coolant in CDU 106 to generate primary coolant return 124. Primary coolant return 124 then returns from air cooler 108 and/or CDU 106 to chillers 110 to be cooled once again and the cycle repeats.

In various embodiments, the liquid coolant circulating in primary coolant loop 120 can be cooled using any combination of mechanical cooling and/or free cooling. For example, in one embodiment a first portion (e.g., a first branch) of primary coolant loop 120 may pass through chillers 110 to receive mechanical cooling from chillers 110, whereas a second portion (e.g., a second branch) of primary coolant loop 120 may pass through one or more free cooling devices (e.g., outdoor air heat exchangers, cooling towers, etc.) to receive free cooling when outdoor temperature conditions permit using free cooling. Several examples of how a hybrid mechanical cooling and free cooling system can be constructed are described in detail in U.S. Pat. No. 9,982,903 incorporated by reference above.

In some embodiments, data center cooling system 100 includes multiple primary coolant loops 120 configured to circulate the primary coolant at different temperatures. For example, a first primary coolant loop 120 may be configured to circulate a relatively higher temperature coolant, a second primary coolant loop 120 may be configured to circulate relatively colder temperature coolant, and a third primary coolant loop 120 may be configured to circulate coolant at a medium temperature between the relatively higher and lower temperatures. The different primary coolant loops 120 may be selectively coupled to different racks 102, server trays 104, or heat-generating components based on their respective cooling requirements.

CDU 106 can be configured to transfer heat between the primary coolant in primary coolant loop 120 and the secondary coolant (e.g., water, glycol, CO2, ammonia, etc.) in secondary coolant loop 130. It is expected that the secondary coolant in secondary coolant loop 130 is warmer than the primary coolant in primary coolant loop 120 and thus the direction of heat transfer within CDU 106 is from the secondary coolant to the primary coolant (i.e., from secondary coolant loop 130 to primary coolant loop 120). In various embodiments, the primary coolant and the secondary coolant may be the same or different coolants and may be kept fluidly separate from each other by containing them within their respective coolant loops 120 and 130. CDU 106 is shown as a heat exchanger (e.g., a liquid-to-liquid heat exchanger, a heat exchange coil, etc.) which receives primary coolant supply 122 from primary coolant loop 120 and secondary coolant return 134 from secondary coolant loop 130. CDU 106 may transfer heat from the relatively warmer secondary coolant return 134 into the relatively colder primary coolant supply 122 to provide cooling to the secondary coolant and generate secondary coolant supply 132.

Secondary coolant loop 130 can be configured to circulate the secondary coolant between CDU 106 and one or both of racks 102 and server trays 104. Secondary coolant loop 130 may include a pump 131 configured to circulate the secondary coolant within secondary coolant loop 130. Pump 131 can be operated to control the flow rate of the secondary coolant within secondary coolant loop 130 and/or the rate of heat transfer between the primary coolant and the secondary coolant in CDU 106. In some embodiments, secondary coolant loop 130 includes one or more valves 133 configured to control the flow of the secondary coolant through racks 102 and/or server trays 104. In various embodiments, valves 133 may be located at the coolant inlets of racks 102 or server trays 104 and/or at the coolant outlets of racks 102 or server trays 104 to control the flow of the secondary coolant through each of racks 102 and/or server trays 104 individually. Although valves 133 are shown at both the inlets and outlets of racks 102 and server trays 104 in FIG. 2, it is contemplated that such an arrangement may be redundant and that a single valve located at either the inlet or the outlet of each of racks 102 or server trays 104 may be sufficient to control the flow of the secondary coolant through each of racks 102 and server trays 104 individually.

In some embodiments, secondary coolant loop 130 provides the secondary coolant to one or more of racks 102 in parallel. For example, as shown in FIG. 1, the three racks 102b and 102c are shown receiving secondary coolant supply 132 from secondary coolant loop 130 and discharging secondary coolant return 134 as an output of racks 102. Such racks 102b and 102c may have internal valves (e.g., valves 166 shown in FIG. 3), pumps, or other flow control devices which can be operated to independently control the flow of secondary coolant supply 132 to each of server trays 104 and/or individual heat-generating components 164 located within racks 102b and 102c, as described in greater detail with reference to FIGS. 3-4. In some embodiments, secondary coolant loop 130 provides the secondary coolant directly to one or more of server trays 104 in parallel. For example, as shown in FIG. 1, rack 102a is shown with secondary coolant supply 132 being delivered to each of server trays 104 of rack 102a in parallel. In various embodiments, secondary coolant loop 130 can deliver the secondary coolant to one or more of racks 102 and/or one or more of server trays 104 in parallel.

Although server trays 104 are shown separate from racks 102 in FIG. 2, it is understood that server trays 104 may be installed within racks 102 and thus may be considered components of racks 102 in some embodiments. The separate depiction of racks 102 and server trays 104 in FIG. 2 is intended to illustrate that the air cooling system (e.g., air cooler 108, fans 109 and 112, dampers 103 and 105, etc.) may provide cooled air supply 114 directly to one or more of server trays 104 (e.g., directly from cold aisle 146) without first requiring cooled air supply 114 to enter the racks 102 within which such server trays 104 are contained. For example, one or more of server trays 104 may have a cooled air intake located along an edge or surface of racks 102 adjacent to cold aisle 146 and configured to receive cooled air supply 114 directly from cold aisle 146 (e.g., via dampers 105). Accordingly, the amount of cooling provided to each of server trays 104 by the air cooling system can be independently adjusted by controlling the airflow rate of cooled supply air 114 and/or the temperature of cooled supply air 114 provided to each of server trays 104 individually. Other server trays 104 may be located within a shared volume within racks 102 and configured to receive cooled air supply 114 after cooled air supply 114 enters racks 102. For example, racks 102 may include dampers 103 which can be operated to control the flow rate of cooled air supply 114 into each of racks 102 individually. In racks 102 with a single large compartment containing multiple server trays 104, cooled air supply 114 may pass across or through multiple server trays 104 within a given rack 102 after entering the rack 102 (e.g., via dampers 103).

Although AI rack 102a is the only type of racks 102 shown in FIG. 1 as receiving the secondary coolant directly from secondary coolant loop 130 to each of server trays 104 within rack 102a, it is contemplated that any of racks 102 can be connected to secondary coolant loop 130 at the server tray level (i.e., with a separate coolant inlet and outlet for each of server trays 104 within the rack) and that such connectivity is not limited to racks 102 designated as AI racks. For example, any of CPU rack 102b and/or GPU racks 102c can also or alternatively be connected to secondary coolant loop 130 at the server tray level in various embodiments. Similarly, while CPU rack 102b and GPU racks 102c are the only type of racks 102 shown in FIG. 1 with a single coolant inlet and single coolant outlet connecting to secondary coolant loop 130, it is contemplated that any of racks 102 can be connected to secondary coolant loop 130 at the rack level (i.e., with a single coolant inlet and outlet for the rack as a whole) and that such connectivity is not limited to racks designated as CPU racks or GPU racks. For example, AI rack 102a can also or alternatively be connected to secondary coolant loop 130 at the rack level in some embodiments.

In some embodiments, primary coolant loop 120 and/or secondary coolant loop 130 supply a liquid coolant (e.g., water, glycol, etc.) to racks 102, server trays 104, and/or to individual heat-generating components installed on server trays 104 (e.g., CPUs, GPUs, etc.) to provide targeted cooling to such components. However, it is contemplated that data center cooling system 100 is not limited to using liquid coolants in primary coolant loop 120 and/or secondary coolant loop 130, but rather can use any of a variety of fluid coolants in various embodiments (e.g., gas coolants, liquid coolants, vapor coolants, mixed phase (liquid/vapor, liquid/gas) coolants, and/or any other type of fluid coolant). Accordingly, it should be understood that all references to liquid coolants throughout the present disclosure including the claims presented herein can be replaced with any other type of fluid coolant without departing from the teachings of the present disclosure.

Referring now to FIG. 3, one of racks 102 is shown in greater detail, according to an exemplary embodiment. Rack 102 is shown to include several compartments 172a, 172b, 172c, and 172d (collectively compartments 172) containing different types of server trays 104 and a power distribution unit (PDU) 176. In particular, compartments 172a are shown containing AI trays 104a, compartments 172b are shown containing GPU trays 104b, compartment 172c is shown containing CPU tray 104c, and compartment 172d is shown containing PDU 176. As noted above, the types of server trays 104 within compartments 172 may correspond to the types of computing applications run by server trays 104 and/or the types of computing devices located on server trays 104 (e.g., AI applications, high performance computing applications, GPUs, CPUs, DIMMS, etc.).

In some embodiments, compartments 172 are fluidly isolated from each other (e.g., by solid surfaces within racks 102 forming upper and lower boundaries of compartments 172) such that the airflow streams through compartments 172 do not mix with each other within racks 102. Accordingly, each of compartments 172 may receive a separate stream of cooled air supply 114 from cold aisle 146 for use in cooling the heat-producing data center equipment therein. The streams of cooled air supply 114 may be kept separate from each other within racks 102 such that each stream of cooled air supply 114 cools a corresponding compartment 172. In other embodiments, racks 102 may not include compartments 172 (or one or more of compartments 172 may be joined into a larger compartment) such that some or all of the internal volume within racks 102 is fluidly connected. In such an embodiment, racks 102 may receive one or more streams of cooled air supply 114 from cold aisle 146 and may allow the streams of cooled air supply 114 to mix or join within racks 102.

In some embodiments, racks 102 include inlet dampers 168 positioned at the cold air intake of racks 102 (e.g., between cold aisle 146 and compartments 172). Inlet dampers 168 may be aligned with compartments 172 and individually operated to independently control the flow of cooled air supply 114 into and through each of compartments 172. Dampers 103 and 105 shown in FIG. 2 may be types of inlet dampers 168 shown in FIG. 3. Similarly, racks 102 may include inlet dampers 168 positioned at the hot air exhaust of racks 102 (e.g., between compartments 172 and the hot aisle or data center room 107). Outlet dampers 170 may be aligned with compartments 172 and individually operated to independently control the flow of cooled air supply 114 out of and through each of compartments 172. Although compartments 172 are shown equipped with both inlet dampers 168 and outlet dampers 170 in FIG. 3, it is contemplated that such an arrangement may be redundant and that only one of inlet dampers 168 or outlet dampers 170 may be installed and used to control the airflow through each of compartments 172 in some embodiments. Alternatively, both inlet dampers 168 and outlet dampers 170 may be installed and used to control the airflow through compartments 172 in some embodiments.

In some embodiments, cooled air supply 114 within cold aisle 146 is maintained at an air pressure above the air pressure within data center room 107 such that the pressure differential causes cooled air supply 114 to flow through compartments 172 when inlet dampers 168 and/or outlet dampers 170 are open. For example, air cooler 108 and/or fan 112 may be operated to maintain cold aisle 146 at a positive air pressure relative to the air pressure within data center room 107. In some embodiments, racks 102 include fans 165 positioned within each compartment 172 (e.g., upstream or downstream of server trays 104). Fans 165 can be operated to independently control the flow rate of cooled air supply 114 through each of compartments 172 to provide different air flow rates to different server trays 104 within a given rack 102.

For racks 102 that contain multiple compartments 172, each compartment 172 may be equipped with an inlet damper 168, outlet damper 170, and/or fan 165. These components can be operated to independently control the flow rate of cooled air supply 114 through each compartment 172, and thus modulate the amount of cooling provided to each of server trays 104 by cooled air supply 114. For racks 102 that do not contain multiple compartments 172, such racks 102 may include one or more of inlet dampers 168, outlet dampers 170, and/or fans 165 which can be operated to control the flow rate of cooled air supply 114 through the rack 102 as a whole. In this way, each rack 102 can be provided with a different amount of air cooling either at the rack level or at the server tray level. In some embodiments, inlet dampers 168 and/or outlet dampers 170 can be replaced with vents or held permanently open to provide the same functionality as a vent. In such embodiments, airflow through each of compartments 172 can be controlled by operating fans 165 and/or by controlling the air pressure within cold aisle 146.

Still referring to FIG. 3, rack 102 is shown to include valves 166. Valves 166 may be located along secondary coolant loop 130 and operated to control the flow of the secondary coolant through rack 102 and/or server trays 104. In various embodiments, valves 166 can be located along secondary coolant supply 132 (e.g., upstream of server trays 104), along secondary coolant return 134 (e.g., downstream of server trays 104), or in both locations as shown in FIG. 3. However, it is contemplated that positioning valves 166 both upstream and downstream of server trays 104 may be redundant and that only one of an upstream valve 166 or a downstream valve 166 may be required to control the flow of the secondary coolant through rack 102 and/or server trays 104. In some embodiments, rack 102 includes one or more valves 166 within each of compartments 172 or otherwise positioned to control the flow of the secondary coolant to each of server trays 104 individually. Such an arrangement allows each of server trays 104 to receive a different flow rate of the secondary coolant from secondary coolant supply 132 (e.g., by operating valves 166) to modulate the amount of liquid cooling provided to each of server trays 104 independently. Although not explicitly shown in FIG. 3, it is contemplated that PDU 176 may also be cooled by secondary coolant loop 130 and may receive a flow of secondary coolant supply 132 in some embodiments.

In some embodiments, valves 166 and/or valves 133 can be operated to open or close different branches of secondary coolant loop 130. For example, valves 133 shown in FIG. 2 can be closed to prevent the secondary coolant from flowing into and through one or more of racks 102 or server trays 104 connected in series with valves 133, or opened to allow the secondary coolant to flow through into and through one or more of racks 102 or server trays 104 connected in series with valves 133. Similarly, valves 166 shown in FIG. 3 can be opened or closed to allow the secondary coolant to flow through individual server trays 104 within a given rack 102 while preventing the secondary coolant from flowing through other server trays 104 within a given rack 102. Valves 166 and 133 can be modulated between fully open positions and fully closed positions (i.e., set to any position between and including fully open and fully closed) to selectively control the amount of proportion of the secondary coolant that flows through each of racks 102 and/or server trays 104. In this way, the flow of the secondary coolant can be controlled (e.g., increased, decreased, etc.) or cut-off entirely to some or all of racks 102 or server trays 104 based on their individual cooling requirements. In some embodiments, valves 166 and 133 can be closed to allow some racks 102 or server trays 104 to be disconnected from secondary coolant loop 130 (e.g., for maintenance, replacement, etc.). Valves 166 and 133 can also or alternatively be closed to increase the efficiency of pump 131 by preventing pressure losses within secondary coolant loop 130 caused by pumping the secondary coolant through racks 102 or server trays 104 that do not require liquid cooling.

Referring now to FIG. 4, one of server trays 104 is shown in greater detail, according to an exemplary embodiment. Server tray 104 is shown to include a surface 152 (e.g., a bottom surface, a board, a substrate, etc.) on which one or more heat-generating components 164 are mounted or installed. Heat-generating components 164 may include any type of computing device or other data center component that generates heat during operation (e.g., CPUs, GPUs, ASICs, DIMMs, power supplies, etc.). Server tray 104 is shown to include cold plates 162 thermally coupled to heat-generating components 164 (e.g., positioned on or near heat-generating components 164 to facilitate heat transfer between cold plates 162 and heat-generating components 164) and configured to absorb heat from heat-generating components 164 during operation. Cold plates 162 may include heat sinks, tubes, liquid-to-solid heat exchangers, or any other structure configured to draw heat away from heat-generating components 164. Cold plates 162 may receive flows of the secondary coolant from secondary coolant loop 130 and transfer heat from heat-generating components 164 into the secondary coolant.

Server tray 104 is shown to include a front surface 154 having a coolant inlet port 148 and a coolant outlet port 150. Coolant inlet port 148 may be connected to secondary coolant supply 132 and may receive a flow of the chilled secondary coolant from secondary coolant loop 130. The chilled secondary coolant may flow from coolant inlet port 148 into a coolant supply header 156. Coolant supply header 156 may be connected to each of cold plates 162 via coolant lines 160 and may deliver the chilled secondary coolant to cold plates 162. The secondary coolant absorbs heat from cold plates 162 and thus provides cooling to heat-generating components 164 thermally coupled to cold plates 162. The warmed secondary coolant then flows from cold plates 162 into coolant return header 158 via coolant lines 160. Coolant return header 158 may be fluidly coupled with coolant outlet port 150 and configured to discharge the warmed secondary coolant back to secondary coolant loop 130 via coolant outlet port 150.

In some embodiments, cold plates 162 also or alternatively include fins, plates, solid-to-air heat exchangers, or other structures configured to transfer heat from cold plates 162 into cooled air supply 114 flowing across server tray 104. Cooled air supply 114 may flow across server tray 104 and absorb heat from heat-generating components 164 either directly or via cold plates 162. The warmed airflow may then exit server tray 104 via front surface 154 through outlet damper 170 and/or a front vent in various embodiments.

Referring generally to FIGS. 1-4, data center cooling system 100 may include a variety of sensors (e.g., temperature sensors, flow rate sensors, pressure sensors, etc.) positioned to measure the temperatures, flow rates, pressures, or other conditions of the airflow and liquid coolant at various locations within data center cooling system 100. For example, data center cooling system 100 may include air sensors positioned at the inlet or outlet of air cooler 108 (e.g., upstream or downstream of the heat exchanger within air cooler 108), within under-floor plenum 116, at the air inlet or outlet of each rack 102 (e.g., upstream or downstream of server trays 104), at the air inlet or outlet of each of compartments 172 (e.g., proximate to inlet dampers 168 or outlet dampers 170), within compartments 172, within data center room 107, or otherwise within the data center to measure the temperatures, flow rates, pressures, and/or other conditions of the airflow at the locations of the air sensors. For example, data center cooling system 100 may include flow rate sensors and/or temperature sensors configured to measure the flow rate or temperature of cooled air supply 114 entering each of racks 102 or each of compartments 172 and/or the flow rate or temperature of hot air return 142 exiting each of racks 102 or each of compartments 172 independently.

Data center cooling system 100 may include liquid coolant or refrigerant sensors positioned at the coolant inlets or outlets of chillers 110 (e.g., along primary coolant loop 120 upstream or downstream of evaporator 115), at any location within refrigeration circuit 111, at the coolant inlets or outlets of CDU 106 (e.g., along primary coolant loop 120 upstream or downstream of CDU 106, along secondary coolant loop 130 upstream or downstream of CDU 106), at the inlets or outlets of individual racks 102 or server trays 104 (e.g., along secondary coolant supply 132 or secondary coolant return 134), or immediately upstream or downstream of individual heat-generating components 164 within server trays 104 to measure the temperatures, flow rates, pressures, and/or other conditions of the liquid coolant or refrigerant at the locations of the liquid coolant or refrigerant sensors. For example, data center cooling system 100 may include flow rate, pressure, or temperature sensors configured to measure the flow rate, pressure, or temperature of the primary coolant entering or exiting chillers 110 (e.g., positioned upstream or downstream of chillers 110 along primary coolant loop 120), the secondary coolant entering or exiting CDU 106 (e.g., along secondary coolant loop 130 upstream or downstream of CDU 106), the secondary coolant entering or exiting racks 102 or server trays 104 (e.g., along secondary coolant loop 130 upstream or downstream of racks 102 or server trays 104), the refrigerant in refrigeration circuit 111 (e.g., between any of condenser 113, expansion valve 119, evaporator 115, and compressor 117), along condenser water loop 144 upstream or downstream of chillers 110, or otherwise positioned to measure any variable state or condition of the refrigerant, primary coolant, secondary coolant, or condenser water at any location in data center cooling system 100.

In some embodiments, data center cooling system 100 includes temperature sensors configured to measure the temperatures of heat-generating components 164 (e.g., CPU temperatures, GPU temperatures, etc.). Such temperature sensors may be integrated with heat-generating components 164 (e.g., internal thermocouples or other built-in temperature sensors) or additional components of data center cooling system 100 installed to measure the temperatures at or near each of heat-generating components 164. In some embodiments, data center cooling system 100 includes power sensors configured to measure the amount of power delivered to each of racks 102, server trays 104, heat-generating components 164, or other computing devices within the data center. In some embodiments, the power sensors are implemented as wattage sensors, current sensors, or voltage sensors configured to measure the amount of electric power delivered to various components of the data center or measure variables from which power can be derived (e.g., voltage, current, etc.).

Referring particularly to FIG. 2, data center cooling system 100 is shown to include a controller 126. Controller 126 is shown to include a processing circuit 127 and a communications interface 128. Processing circuit 127 may include one or more processors and memory. The processors (shown in subsequent figures as processor 222) may include one or more general purpose or specific purpose processors, application specific integrated circuits (ASIC), one or more field programmable gate arrays (FPGAs), a group of processing components, or other suitable processing components. The processors may be configured to execute computer code or instructions stored in the memory or received from other computer readable media (e.g., CDROM, network storage, a remote server, etc.). The memory (shown in subsequent figures as memory 223) may include one or more devices (e.g., memory units, memory devices, storage devices, etc.) for storing data and/or computer code for completing and/or facilitating the various processes described in the present disclosure. The memory may include random access memory (RAM), read-only memory (ROM), hard drive storage, temporary storage, non-volatile memory, flash memory, optical memory, or any other suitable memory for storing software objects and/or computer instructions. The memory may include database components, object code components, script components, or any other type of information structure for supporting the various activities and information structures described in the present disclosure. The memory may be communicably connected to the processors via processing circuit 127 and may include computer code for executing (e.g., by the processors) one or more processes described herein.

Communications interface 128 may include wired or wireless interfaces (e.g., jacks, antennas, transmitters, receivers, transceivers, wire terminals, etc.) for conducting data communications with various systems, devices, or networks. For example, communications interface 128 may include an Ethernet card and port for sending and receiving data via an Ethernet-based communications network and/or a Wi-Fi transceiver for communicating via a wireless communications network. Communications interface 128 may be configured to communicate via local area networks or wide area networks (e.g., the Internet, a building WAN, etc.) and may use a variety of communications protocols (e.g., BACnet, IP, LON, etc.). Communications interface 128 may be configured to facilitate electronic data communications between controller 126 and various other systems or devices of data center cooling system 100 (e.g., sensors, controllable equipment, etc.) or other external data sources, systems, or devices outside data center cooling system 100. For example, controller 126 may be configured to communicate with any or all of the controllable equipment of data center cooling system 100 (e.g., CDU 106, air cooler 108, fan 109, chillers 110, fan 112, compressor 117, expansion valve 119, pump 121, valve 123, valve 125, valves 133, pump 131, dampers 103, dampers 105, inlet dampers 168, outlet dampers 170, valves 166, fans 165, etc.) and any or all of the sensors in data center cooling system 100 (e.g., any of the temperature sensors, pressure sensors, flow rate sensors, power sensors, etc.).

Controller 126 can be configured to receive measurements from the sensors and operate the controllable equipment of data center cooling system 100 to control the flow rates, pressures, temperatures, or other variable states or conditions of cooled air supply 114, hot air return 142, the refrigerant in refrigeration circuit 111, the condenser water in condenser water loop 144, the primary coolant in primary coolant loop 120, the secondary coolant in secondary coolant loop 130, or any portions thereof. In some embodiments, controller 126 receives reported values of temperatures, power consumption, or other measured or calculated variables from heat-generating components 164, PDU 176, or other data center equipment configured to report their own operating conditions (e.g., temperatures, power consumption, power delivered, computing load, etc.).

Controller 126 can use any of a variety of feedback control processes (e.g., closed-loop control, reset control, etc.), feedforward or predictive control processes (e.g., model predictive control, prediction-based control, etc.), or other control processes to operate the controllable equipment of data center cooling system 100 based on the measured values from installed sensors or reported variables from the data center equipment. Several examples of particular control processes which can be performed by controller 126 are described in detail below. Advantageously, controller 126 can be configured to precisely modulate the amount of cooling provided to each of racks 102, server trays 104, and/or individual heat-generating components 164 (referred to generally as “heat loads”) by both the air cooling equipment and the liquid cooling equipment of data center cooling system 100. Controller 126 can independently adjust the amount of cooling provided individual heat loads within the data center by controlling the air cooling equipment and the liquid cooling equipment that serve each heat load independently. This allows controller 126 to provide targeted cooling to various heat loads as needed without overcooling other heat loads more than necessary to dissipate the amount of heat generated during operation.

In some embodiments, data center cooling system 100 includes some or all of the components, features, or functionality described in U.S. patent application Ser. No. 17/741,108 filed May 10, 2022, U.S. Pat. No. 11,497,144 granted Nov. 8, 2022, U.S. patent application Ser. No. 18/308,418 filed Apr. 27, 2023, U.S. patent application Ser. No. 18/308,422 filed Apr. 27, 2023, U.S. patent application Ser. No. 18/641,658 filed Apr. 22, 2024, and/or Indian Provisional Patent Application No. 202441090506 filed Nov. 21, 2024, all of which are incorporated by reference herein in their entireties. For example, controller 126 can be configured to execute any or all of the control processes described in any of the patents, patent applications, or other documents incorporated by reference throughout the present disclosure in the context of data center cooling system 100. Data center cooling system 100 can include any or all of the equipment described in any of the aforementioned documents in various embodiments. In addition to the functionality described in these documents, controller 126 can be configured to execute a variety of new control processes that improve upon the prior art in various ways, several examples of which are described in detail below.

### Coolant Flow Rate and Pressure Control

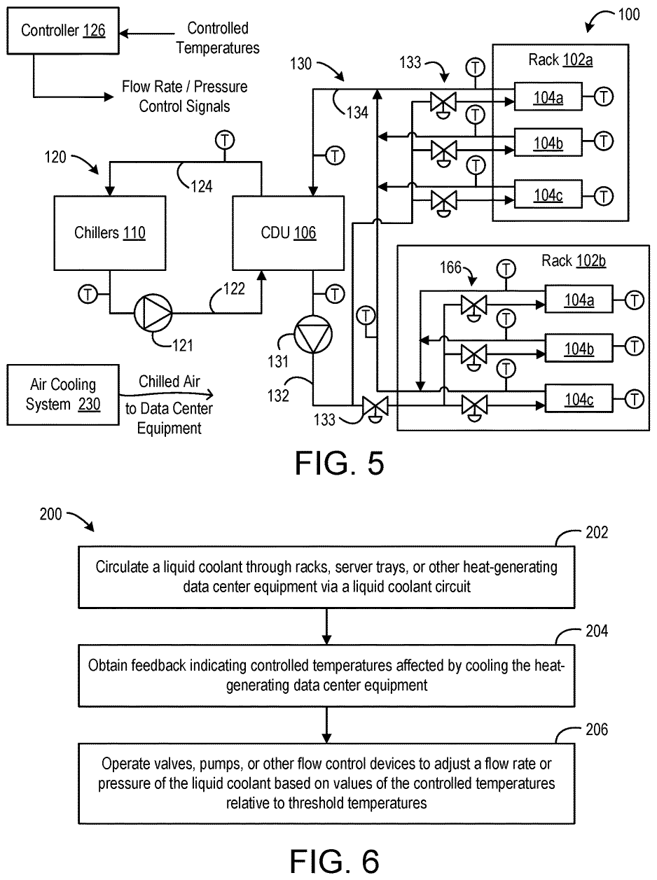

Referring now to FIG. 5, a block diagram of data center cooling system 100 is shown, according to an example implementation. Data center cooling system 100 can include chillers 110, CDU 106, racks 102, server trays 104, and a controller 126. System 100 may also include a liquid coolant circuit, such as a primary coolant circuit (e.g., a primary coolant loop 120) and a secondary coolant circuit (e.g., a secondary coolant loop 130). In some implementations, the liquid coolant circuit can include one or more coolant supply headers configured to deliver liquid coolant to the racks 102, server trays 104, and/or components (e.g., computing devices) provided in or on the racks 102 and/or server trays 104. It should be noted that, in some implementations, components shown in FIG. 5 having the same terminology as and/or sharing common reference numerals with corresponding components shown in other figures may be the same as or similar to the components shown in the other figures (e.g., such components may have the same or similar structure, function, and/or features as described in other figures).

Racks 102 can include AI rack 102a, CPU rack 102b, and GPU racks 102c. Although only two types of racks 102a and 102b are shown in FIG. 5, it is contemplated that any number or type of racks 102 can be included in various embodiments. Server trays 104 can include AI tray 104a, GPU tray 104b, and CPU tray 104c. In various implementations, the controller 126 can be implemented using hardware, software, or a combination thereof. In some implementations, the controller 126 can be implemented using one or more processors and one or more computer-readable storage media having instructions stored thereon executable by the processors as previously described.

In various embodiments, AI rack 102a, CPU rack 102b, and GPU racks 102c can be configured to house different types of computing devices, for example, based on the type of computing applications they run during operation. For example, AI rack 102a can contain servers configured or designed for artificial intelligence workloads, CPU rack 102b can contain general-purpose servers, and GPU racks 102c can contain servers with graphics processing units for specialized (e.g., high computing load) computing tasks. Different types of racks 102 can have different cooling requirements, for example, based on the heat generated by the computing devices contained within each of the different types of racks 102.

In some implementations, AI tray 104a, GPU tray 104b, and CPU tray 104c can be server trays configured to be installed within racks 102. Each type of server tray 104 can contain different types of computing devices configured or designed for specific workloads. Server trays 104 can be similar to or the same as the server trays described with reference to FIG. 3 and FIG. 4 in some implementations. Server trays 104 can include valves 133 or 166 to control the flow of secondary coolant to individual server trays 104 and/or to individual components (e.g., individual computing devices) within server trays 104. In some embodiments, valves 133 are located outside racks 102 and configured to control the flow of the secondary coolant to each of racks 102 and/or each of server trays 104 individually. For example, three of valves 133 shown in FIG. 5 are arranged in series with corresponding server trays 104a, 104b, and 104c of rack 102a and can be operated by controller 126 to control the flow of the secondary coolant directly to the corresponding server trays 104 of rack 102a.

In some embodiments, valves 166 are located within racks 102 and configured to control the flow of the secondary coolant to each of server trays 104 within a given rack 102. For example, as shown in FIG. 5, each of valves 166 is located within rack 102b and arranged in series with a corresponding server tray 104 within rack 102b. Each of valves 166 may be operated by controller 126 to control the flow of the secondary coolant to the corresponding server tray 104 within rack 102b. The remaining valve 133 shown in FIG. 5 (i.e., the valve 133 near the bottom of FIG. 5) is located upstream of rack 102b and can be operated by controller 126 to control the flow of the secondary coolant into rack 102b as a whole. Individual valves 166 within rack 102b can then be operated to allocate different amounts of the secondary coolant supplied to rack 102 to various server trays 104 within rack 102b based on the individual cooling needs of each of server trays 104 within rack 102b.

In various embodiments, data center cooling system 100 can be configured to circulate a liquid coolant through racks 102 of the data center to cool heat-generating data center equipment within each of racks 102. The liquid coolant can be circulated through primary coolant loop 120 and secondary coolant loop 130. Pumps 121 and 131 can serve as flow control devices operable to control a flow rate and/or a pressure of the liquid coolant in the primary coolant loop 120 and the secondary coolant loop 130. In some implementations, pumps 121 and 131 may control the flow rate and/or the pressure (e.g., by increasing or decreasing the flow rate and/or pressure) of the liquid coolant in response to signals/parameters received from controller 126.

In some implementations, chillers 110 can be configured to provide cooling to a primary coolant circulating through primary coolant loop 120. Primary coolant loop 120 can include pump 121 configured to circulate the primary coolant between chillers 110 and CDU 106. Primary coolant loop 120 can include primary coolant supply 122 for delivering chilled primary coolant from chillers 110 to CDU 106 and primary coolant return 124 for returning warmed primary coolant from CDU 106 to chillers 110. CDU 106 can be configured to transfer heat between the primary coolant in primary coolant loop 120 and a secondary coolant in secondary coolant loop 130. The primary coolant loop 120 can be configured to circulate the primary coolant through a heat exchanger in CDU 106 to absorb heat from the secondary coolant within the heat exchanger.

In various embodiments, secondary coolant loop 130 can be configured to circulate the secondary coolant between CDU 106 and racks 102 or server trays 104. Secondary coolant loop 130 can include pump 131 configured to circulate the secondary coolant within secondary coolant loop 130. Secondary coolant loop 130 can include secondary coolant supply 132 for delivering chilled secondary coolant from CDU 106 to racks 102 and/or server trays 104 and secondary coolant return 134 for returning warmed secondary coolant from racks 102 and/or server trays 104 to CDU 106. Secondary coolant loop 130 can include multiple valves 133 positioned along secondary coolant loop 130 to control the flow of secondary coolant to individual racks 102 and/or server trays 104. The secondary coolant is configured to absorb heat generated by the heat-generating data center equipment (e.g., CPUs, GPUs, and/or other processing circuitry and/or heat-generating electronic equipment) within racks 102. In some implementations, valves 133 and/or 166 can be configured to modulate the flow rate or pressure of the liquid coolant circulating through rack 102 or individual server trays 104, alone or in combination with pumps 121 and/or 131. Controller 126 can be configured to open or close valves 133 and/or 166, partially or fully, to increase or decrease the flow rate and/or the pressure of the liquid coolant circulating through rack 102 or server trays 104. In some implementations, valves 133 and/or 166 may be or include variable flow/variable position valves configured to be controllable to modulate flow between a fully open and fully closed position such that the valves can provide a plurality of different flow rates therethrough.

In some implementations, controller 126 can be configured to monitor and manage the operation of data center cooling system 100. Controller 126 can receive temperature information from one or more of various sensors positioned throughout data center cooling system 100. The temperature sensors (shown in FIG. 5 as circles marked with the letter “T”) can be positioned at any location within primary coolant circuit 120 and/or secondary coolant circuit 130 to measure the temperatures of the primary coolant and/or the secondary coolant. For example the sensors can be located along primary coolant supply 122, primary coolant return 124, secondary coolant supply 132, secondary coolant return 134, and/or downstream of racks 102 and/or server trays 104 such that the temperature sensors can measure the temperature of the liquid coolant discharged from each of racks 102 and/or server trays 104 individually. For example, sensors can be located immediately downstream of server trays 104 outside of racks 102 (e.g., as shown for rack 102a) or within racks 102 (e.g., as shown for rack 102b), immediately downstream of one or more of racks 102, or otherwise located to measure the temperatures of the coolant exiting each rack 102 and/or server tray 104 before the coolant mixes with coolant exiting other racks 102 and/or server trays 104. Advantageously, such an arrangement of the temperature sensors allows controller 126 to determine the amount of heat added to the secondary coolant by each of racks 102 and/or server trays 104 individually (e.g., based on the difference in temperature of the secondary coolant entering and exiting each of racks 102 and/or server trays 104).

In some implementations, controller 126 may obtain temperature sensor data from one or more of various sources within data center cooling system 100. For example, controller 126 may receive temperature sensor data from a basic input/output system (BIOS) or other firmware or thermal management interface of one or more servers, server trays 104, processors, or other components of the heat-generating data center equipment within racks 102. Additionally or alternatively, controller 126 may receive temperature sensor data from a data center infrastructure management (DCIM) system communicatively coupled to data center cooling system 100. Controller 126 may use the temperature data obtained from the BIOS, the DCIM system, and/or other sources in conjunction with, or in lieu of, temperature data measured by dedicated temperature sensors of data center cooling system 100.

In some implementations, controller 126 may obtain the temperature sensor data from a baseboard management controller (BMC), BIOS/UEFI interface, operating-system-exposed hardware monitor, or other firmware or platform management interface of a server, processor, accelerator, or other IT equipment. The temperature sensor data can be obtained using one or more standardized management protocols, such as the Intelligent Platform Management Interface (IPMI), Redfish, the Simple Network Management Protocol (SNMP), the Platform Environment Control Interface (PECI), the System Management Bus (SMBus), or any other suitable in-band or out-of-band management protocol. Controller 126 may obtain the temperature sensor data from the DCIM system through an application programming interface (API), a database query, a publish/subscribe messaging interface, or other communications interface exposed by the DCIM system. In some such implementations, the DCIM system may aggregate temperature data, power data, and/or other operational data from multiple sources within the data center (e.g., from servers, racks, PDUs, environmental sensors, etc.) and provide such aggregated data to controller 126. Using temperature sensor data obtained from the BIOS, BMC, and/or DCIM system may allow controller 126 to leverage temperature measurements that are already collected by the heat-generating data center equipment itself or by existing data center management infrastructure, potentially reducing the number of additional dedicated temperature sensors required to be installed within data center cooling system 100.

In some implementations, one or more temperature sensors of data center cooling system 100 may be connected to or in thermal communication with a coolant supply line and/or a coolant return line at one or more locations within secondary coolant loop 130. For example, one or more temperature sensors may be connected to a coolant supply line and/or a coolant return line of rack 102 (e.g., a portion of secondary coolant supply 132 and/or secondary coolant return 134 within or coupled to rack 102). One or more temperature sensors may be connected to a coolant supply line and/or a coolant return line of a server or server tray 104 (e.g., a portion of the coolant supply or return that delivers coolant to or removes coolant from server tray 104). One or more temperature sensors may be connected to a coolant supply line and/or a coolant return line of a cold plate that is thermally coupled to one or more components of the heat-generating data center equipment (e.g., a heat sink mounted on or near a CPU, GPU, PCB, or other heat-generating component).

In some implementations, one or more temperature sensors may be embedded within components of data center cooling system 100. For example, one or more temperature sensors may be embedded within a cold plate (e.g., within a body or wall of the cold plate, in or near one or more microchannels of the cold plate, or otherwise integrated into the cold plate structure), within a coolant supply line and/or a coolant return line (e.g., within a wall of the line or in a flow path of the line). One or more temperature sensors may be embedded within a coupling that fluidly connects a supply or return line to a manifold (e.g., such that one end of the coupling is connected to the supply or return line and the other end of the coupling is connected to the manifold, with the temperature sensor disposed within the coupling to measure the temperature of coolant flowing through the coupling). One or more temperature sensors may be embedded within a manifold of rack 102 and/or server tray 104 (e.g., a coolant manifold of secondary coolant loop 130 that delivers coolant to or collects coolant from a plurality of server trays 104 or components). Embedding temperature sensors at these locations may allow controller 126 to obtain temperature measurements representative of coolant temperatures at or near the heat-generating data center equipment with reduced thermal lag.

In some implementations, one or more sensors (e.g., temperature, pressure, flow rate, etc.) of data center cooling system 100 may be implemented as energy-harvesting sensors. An energy-harvesting sensor may include an energy transducer configured to convert locally available ambient energy into electrical energy, a power-management circuit configured to condition and regulate the harvested energy, and an energy-storage element, such as a capacitor, supercapacitor, or rechargeable micro-cell, configured to store energy for intermittent or continuous operation of the sensor and associated communications circuitry. For example, an energy-harvesting temperature sensor may be positioned within an information technology (IT) space of the data center and configured to harvest energy from a temperature difference between the liquid coolant (e.g., water) flowing through one or more coolant lines of data center cooling system 100 and the ambient air within the IT space. Other types of energy-harvesting sensors may harvest energy from fluid flows (e.g., air flows, water flows, etc.), vibrational or mechanical energy (e.g., caused by pump operation, valve actuation, turbulent flow, structural vibration, etc.). In some embodiments, an energy-harvesting sensor may harvest radio-frequency energy from intentionally transmitted RF power or from ambient electromagnetic fields generated by nearby equipment.

In some implementations, an energy-harvesting temperature sensor that harvests energy from a temperature difference between the liquid coolant and the ambient air may include a thermoelectric generator (TEG), such as a Seebeck-effect device, having a hot-side surface placed in thermal contact with a coolant supply line, a coolant return line, a manifold, a cold plate, or another component in thermal communication with the liquid coolant, and a cold-side surface placed in thermal contact with the ambient air of the IT space (or vice versa, depending on the relative temperatures of the coolant and the ambient air). The TEG may generate an electrical voltage proportional to the temperature differential between its hot-side and cold-side surfaces, which voltage may be conditioned by the power-management circuit and stored in the energy-storage element to power the sensor and its communications circuitry. Because the liquid coolant in data center cooling system 100 typically operates at a temperature that is meaningfully different from the ambient air temperature within the IT space (e.g., the coolant supply may be cooler than the ambient air, while the coolant return after absorbing heat from the heat-generating data center equipment may be warmer than the ambient air), a usable temperature differential is typically available throughout normal operation of data center cooling system 100.

The harvested energy may be used to power operation of the sensor and/or to power wireless or wired communication of data measured by the sensor (e.g., temperature measurements, pressure measurements, flow rate measurements, etc.) to controller 126 or another component of data center cooling system 100. In some embodiments, the energy-harvesting sensor may operate intermittently, such that harvested energy is accumulated over time and then used to perform a measurement and transmit the resulting data at scheduled intervals, upon occurrence of a threshold event, or in response to a polling signal. In some embodiments, where sufficient energy is available, the sensor may support more frequent measurements, local trending, edge analytics, alarm generation, and/or mesh-network relaying for other nearby sensors. Such energy-harvesting sensors may operate without a dedicated wired power source and without battery replacement, which may simplify deployment of additional temperature sensors throughout the data center.

Controller 126 can be configured to send flow rate and pressure control signals to regulate the operation of pumps 121 and/or 131, valves 133 and/or 166, and/or other components of data center cooling system 100. Controller 126 can be similar to or the same as the controller described with reference to FIG. 2 in some implementations. Controller 126 includes one or more processing circuits and is configured to operate the one or more flow control devices to adjust the flow rate and/or the pressure of the liquid coolant in the liquid coolant circuit.

In some implementations, controller 126 can be configured to operate the flow control devices (e.g., pumps 121 and/or 131 and/or valves 133 and/or 166) to adjust the flow rate and/or the pressure of the liquid coolant in the liquid coolant circuits based on feedback indicating a value of a controlled temperature affected by cooling the heat-generating data center equipment. The controlled temperature can be a temperature of the heat-generating data center equipment within rack 102, a coolant return temperature of the liquid coolant exiting one or more of racks 102 after absorbing heat from the heat-generating data center equipment, a coolant return temperature of the liquid coolant exiting one or more of server trays 104 after absorbing heat from the heat-generating data center equipment, or any other temperature affected by the cooling process. In various implementations, the controlled temperature affected by cooling the heat-generating data center equipment can include one or more of: a temperature of the heat-generating data center equipment within the rack; a temperature measured by a temperature sensor positioned at or near a location of the heat-generating data center equipment; a temperature of a processor, GPU, CPU, memory module, or other hardware component of the heat-generating data center equipment; a temperature reported by one or more devices of the heat-generating data center equipment; a coolant return temperature of the liquid coolant exiting the rack after absorbing heat from the heat-generating data center equipment; a temperature of a secondary coolant that absorbs heat from the heat-generating data center equipment within the rack; and/or a temperature of a primary coolant used to absorb heat from the secondary coolant.

In various embodiments, controller 126 can be configured to obtain a reference temperature and operate the flow control devices (e.g., pumps 121 and/or 131 and/or valves 133 and/or 166) to adjust the flow rate and/or the pressure of the liquid coolant to maintain the controlled temperature at or below the reference temperature. The reference temperature can be a maximum permissible temperature of the heat-generating data center equipment, a target value of the coolant return temperature, or a predetermined temperature at which a processor within the heat-generating data center equipment is configured to throttle.

In some implementations, controller 126 is configured to operate the flow control devices to adjust the flow rate and/or the pressure of the liquid coolant in the liquid coolant circuit to maintain the temperature of the heat-generating data center equipment at or below a maximum permissible temperature. For example, in some implementations, certain data center equipment may have a maximum permissible temperature associated therewith. This maximum permissible temperature may vary depending on the specific type of equipment and its operational requirements. For example, some equipment may have a maximum temperature above which physical damage could occur to components. Some equipment may have a maximum temperature above which performance degradation begins to occur, reducing computational efficiency. In some examples, equipment may have a listed maximum temperature provided by the manufacturer, above which prolonged operation may significantly shorten the equipment's lifespan or void warranties.

Controller 126 may be configured to identify the applicable maximum permissible temperature for one or more pieces of equipment being cooled, in some implementations. This identification process may involve determining the type of server or component installed in a particular rack or server tray. Controller 126 may access a database or lookup table that associates different equipment types with their respective maximum permissible temperatures. For instance, a high-performance GPU may have a different maximum permissible temperature compared to a standard CPU.

Controller 126 may monitor the temperature of the server or component using one or more of the various sensors distributed throughout the data center cooling system 100. These sensors may measure the temperature of the equipment directly, or they may measure related temperatures such as the coolant temperature near the equipment or the air temperature surrounding the equipment.

Using the temperature data from the sensors, controller 126 may adjust the flow rate and/or pressure of the liquid coolant in the cooling system to maintain the equipment temperature below the identified maximum permissible temperature. For example, if the temperature of a particular GPU approaches its maximum permissible temperature, controller 126 may increase the flow rate of coolant to that specific GPU by adjusting valves or pump speeds in the coolant circuit serving that equipment.

In some implementations, controller 126 may implement or utilize predictive algorithms to anticipate temperature increases based on workload patterns or environmental factors. This may allow controller 126 to proactively adjust cooling parameters before the equipment temperature reaches the maximum permissible temperature. In some implementations, controller 126 may receive input from one or more Hall effect sensors (e.g., Hall sensors arranged to measure current draw of one or more processors, server trays 104, racks 102, or other heat-generating data center equipment) and use the Hall sensor measurements as a proxy for the power consumption of such heat-generating data center equipment (e.g., chip power, CPU power, GPU power, etc.). Advantageously, changes in power consumption or power draw can be observed by a Hall sensor before corresponding changes in temperature propagate through the thermal mass and time constants of the chip case, the cold plate, the thermal interface material (TIM), and the liquid coolant. Accordingly, controller 126 may use the Hall sensor data to detect a change in the power consumption of the heat-generating data center equipment in advance of the temperature sensors detecting a corresponding change in temperature, and may proactively adjust the flow rate, pressure, and/or temperature of the liquid coolant based on the Hall sensor data before such temperature change is observed.

The one or more Hall effect sensors may be positioned at any of various locations within the data center to measure current draw of the heat-generating data center equipment. For example, a Hall effect sensor may be positioned around or proximate to a power conductor that supplies electrical power to a particular processor, server tray 104, rack 102, or PDU 176 (e.g., clamped around a power cable, integrated into a busbar, integrated into a power distribution unit, mounted on a printed circuit board carrying a heat-generating component, etc.) such that the Hall effect sensor produces an output signal proportional to the magnetic field generated by current flowing through the conductor. Controller 126 may convert the Hall effect sensor signal into a corresponding current measurement and, in combination with a known or measured supply voltage, derive an estimated power consumption of the corresponding heat-generating data center equipment. In some implementations, multiple Hall effect sensors may be deployed to provide power consumption estimates at different levels of granularity (e.g., at the rack level, at the server-tray level, at the chip level, etc.), enabling controller 126 to detect changes in power consumption of individual components and to direct cooling adjustments to those specific components in advance of the temperature changes propagating through the thermal mass of the equipment.

In some embodiments, controller 126 may be programmed with different cooling strategies for different types of maximum permissible temperatures. For equipment with a damage threshold, controller 126 may prioritize maintaining temperature well below this limit at all times. For equipment with performance-based temperature limits, controller 126 may allow temperatures to approach but not exceed the limits to balance cooling efficiency with computational performance.

It should also be understood that, in various implementations, controller 126 may allow the temperature to exceed the maximum permissible temperature for some amount of time. For example, for a maximum permissible temperature above which prolonged exposure will result in reduced component life, controller 126 may allow the temperature to exceed the limit for a small amount of time (e.g., a time short enough to not significantly shorten the lifespan of the component).

In some implementations, controller 126 is additionally or alternatively configured to operate the flow control devices to adjust the flow rate and/or the pressure of the liquid coolant in the liquid coolant circuit to maintain the coolant return temperature at or below a target temperature. Controller 126 may obtain measured temperatures of the primary coolant return 124 and/or secondary coolant return 134, such as through temperature sensors positioned along the respective coolant return lines. The controller 126 may compare the measured return temperatures to one or more target temperature values (e.g., predefined target temperature values stored in memory).

Controller 126 may adjust the flow rate and/or pressure of the coolant to maintain the return temperatures at or below the target values. For example, if a measured return temperature exceeds its target value, controller 126 may increase the coolant flow rate by adjusting pump speeds (e.g., pumps 121 and/or 131) and/or modulating valve positions (e.g., valves 133 and/or 166). Conversely, if the return temperature is significantly below the target value, controller 126 may decrease the flow rate and/or pressure to increase energy efficiency. Controller 126 may implement proportional-integral-derivative (PID) control algorithms or other feedback control methods to adjust the cooling parameters and maintain the desired temperature conditions.

In some implementations, controller 126 is additionally or alternatively configured to operate the flow control devices to adjust the flow rate and/or the pressure of the liquid coolant in the liquid coolant circuit to maintain a temperature of one or more processors within the heat-generating data center equipment at or below the predetermined temperature at which the processor is configured to throttle. In some implementations, certain data center equipment such as processors (e.g., CPUs, GPUs, etc.) may have a temperature threshold above which the equipment may be designed to throttle, or enter a state of reduced performance. This throttling mechanism may involve reducing clock frequency, voltage, or other operational parameters to decrease heat generation and protect the processor from potential damage due to overheating. The specific throttle temperature may vary depending on the processor model, manufacturer, and intended use case.

Controller 126 may be configured to identify the applicable throttle temperature for one or more (e.g., each) processors or components being cooled within the data center. This identification process may involve determining the type of processor installed in a particular server tray or rack. Controller 126 may access a database or lookup table that associates different processor types with their respective throttle temperatures. For instance, a high-performance GPU designed for AI workloads may have a different throttle temperature compared to a general-purpose CPU.

In some implementations, controller 126 may be configured to implement or utilize a model (e.g., a regression model, an artificial intelligence (AI) model, a machine learning (ML) model, or other predictive model) to anticipate thermal throttling of one or more processors or other components of the heat-generating data center equipment. For example, the model may be trained or configured to predict, based on inputs such as workload patterns, processor utilization, power consumption data, Hall sensor measurements indicative of chip power, current temperature measurements, historical temperature trends, and/or other relevant parameters, that a processor or other component is approaching its applicable throttle temperature. In response to a prediction by the model that a processor or other component is approaching its throttle temperature, controller 126 may operate the coolant distribution network of data center cooling system 100 (e.g., pumps 121 and/or 131, valves 133 and/or 166, and/or other flow control devices) to direct an increased flow of coolant to the affected processor, server tray 104, or rack 102, thereby acting to reduce the temperature of the processor before throttling occurs.

In some implementations, the model implemented by controller 126 to anticipate thermal throttling may be trained or configured using historical operational data collected from data center cooling system 100 and/or the heat-generating data center equipment, such as historical workload traces, processor utilization logs, power consumption traces (e.g., obtained from PDUs 176 or Hall effect sensors), historical temperature traces, historical coolant flow rates and pressures, and/or recorded throttling events. The model may, for example, be trained to output a predicted temperature of a processor or other component at one or more future time horizons (e.g., 1 second, 10 seconds, 1 minute, etc. into the future), a predicted time-to-throttle (e.g., an estimated amount of time remaining before the processor reaches its applicable throttle temperature given current conditions), and/or a probability that the processor will throttle within a specified time window. Controller 126 may use the output of the model as a leading indicator of impending throttling and may select a magnitude and/or a target location of the cooling adjustment (e.g., how much to increase the coolant flow rate to a particular processor, server tray 104, or rack 102) based on the predicted severity and timing of the impending throttling event. In some implementations, controller 126 may continuously or periodically update or retrain the model using newly collected data, allowing the model to adapt to changes in workload patterns, equipment characteristics, or data center operating conditions over time.

To monitor the temperature of the processors, controller 126 may utilize various sensors distributed throughout the data center cooling system 100. These sensors may measure the temperature of the processors directly, such as through on-die temperature sensors integrated into the processors themselves. Alternatively, the sensors may measure related temperatures that can be used to infer processor temperatures, such as the temperature of the liquid coolant near the processors or the air temperature in the vicinity of the server components.

Using the temperature data from these sensors, controller 126 may adjust the flow rate and/or pressure of the liquid coolant in the cooling system to maintain the processor temperatures below their identified throttle temperatures. For example, if the temperature of a particular GPU approaches its throttle temperature, controller 126 may increase the flow rate of coolant to that specific GPU by adjusting valves or pump speeds in the coolant circuit serving that equipment.

In some cases, controller 126 may implement predictive algorithms to anticipate temperature increases based on workload patterns, power consumption data, or other relevant factors. This predictive approach may allow controller 126 to proactively adjust cooling parameters before the processor temperature reaches the throttle point, thereby maintaining increased energy efficiency without triggering thermal throttling.

Controller 126 may also be programmed with different cooling strategies based on the specific characteristics of the processors being cooled. In some implementations, for processors with a narrow operating temperature range, controller 126 may prioritize maintaining temperatures well below the throttle point at all times. In some implementations, for processors with wider temperature tolerances, controller 126 may allow temperatures to approach the throttle point more closely to balance cooling efficiency with computational performance.

In some implementations, controller 126 may be configured to communicate with built-in thermal management systems of the processors. This communication may allow for coordinated cooling efforts, where the controller can adjust liquid cooling parameters in response to signals from the processors indicating their current thermal state or impending throttling events.

In various embodiments, secondary coolant loop 130 can include a coolant manifold configured to deliver the liquid coolant to multiple server trays 104 within rack 102. Valves 133 or 166 can be operable to independently control the flow rate and/or the pressure of the liquid coolant delivered to one or more server trays 104 of the plurality of server trays. This can allow for targeted cooling of individual server trays based on their specific cooling requirements.

In some implementations, rack 102 can include multiple compartments and the heat-generating data center equipment can be distributed across the multiple compartments. Secondary coolant loop 130 can be configured to circulate the liquid coolant through one or more compartments of the multiple compartments. Controller 126 can be configured to operate valves 133 or 166 to independently adjust the flow rate and/or the pressure of the liquid coolant circulating through one or more compartments of the multiple compartments.

In various embodiments, data center cooling system 100 can include an air cooling system 230 configured to transfer heat into an airflow from the heat-generating data center equipment within rack 102. Controller 126 can be further configured to operate one or more flow control devices of air cooling system 230 based on the value of the controlled temperature. The flow control devices of air cooling system 230 can include fans or dampers operable to affect a flow rate or a pressure of the airflow provided to rack 102 by air cooling system 230. Controller 126 is configured to adjust a speed of the fan or a position of the damper based on the value of the controlled temperature. The air cooling system 230 can include one or more computer room air conditioner (CRAC) units, one or more computer room air handler (CRAH) units, one or more direct evaporative cooling (DEC) units, one or more indirect evaporative cooling (IEC) units, one or more free cooling units, or any other type of airside HVAC equipment.

In some implementations, controller 126 may be configured to control both the liquid cooling system and the air cooling system to remove heat from the heat-generating data center equipment. In various embodiments, controller 126 may coordinate operation of both the air cooling system and liquid cooling system to maintain target temperatures for the heat-generating data center equipment. For example, controller 126 may implement a tiered cooling approach based on measured temperatures. If the temperature is below a first threshold, controller 126 may activate only the air cooling system. For temperatures in a medium range between the first threshold and a second higher threshold, controller 126 may utilize both the air cooling system and the liquid cooling system, with the liquid cooling operating at a lower flow rate or pressure. When temperatures exceed the second threshold, controller 126 may increase cooling by running the air cooling system at higher capacity and/or increasing the liquid coolant flow rate and/or pressure. This adaptive control strategy may allow for energy-efficient cooling under varying heat loads.

In some implementations, data center cooling system 100 may include or implement one or more virtual flow sensors configured to estimate a flow rate of the liquid coolant at one or more locations within the liquid coolant circuit without directly measuring the flow rate at those locations. For example, controller 126 may be configured to implement a model (e.g., a regression model, an artificial intelligence (AI) model, a machine learning (ML) model, or other model) that relates an input coolant temperature (e.g., a coolant supply temperature measured upstream of a cold plate, server tray 104, or rack 102), an output coolant temperature (e.g., a coolant return temperature measured downstream of the cold plate, server tray 104, or rack 102), and a Hall sensor reading indicative of chip power (e.g., as a proxy for the heat being added to the coolant by the heat-generating data center equipment) to an estimated flow rate of the liquid coolant. The estimated flow rate generated by the virtual flow sensor may be used by controller 126 in lieu of, or in conjunction with, measurements from one or more physical flow sensors.

In some implementations, the model implemented by the virtual flow sensor may be based on, or otherwise reflect, an energy balance between the heat absorbed by the liquid coolant as it flows through the cold plate, server tray 104, or rack 102 and the heat generated by the corresponding heat-generating data center equipment. For example, an amount of heat absorbed by the liquid coolant may be expressed as the product of the mass flow rate of the liquid coolant, the specific heat capacity of the liquid coolant, and the difference between the output coolant temperature and the input coolant temperature (e.g., Q=\dot{m}×Cₚ×(Tₒᵤₜ−Tᵢₙ)), while the heat generated by the heat-generating data center equipment may be estimated based on the Hall sensor reading indicative of chip power. Solving this relationship for the mass flow rate (or equivalently the volumetric flow rate, given a known coolant density) yields an estimated flow rate of the liquid coolant. In implementations using a regression, AI, or ML model, the model may be trained on historical data sets that include simultaneous measurements of input coolant temperature, output coolant temperature, Hall sensor readings, and physically measured flow rates so that the model can learn the mapping between these inputs and the corresponding flow rate, including effects that may not be captured by a simple energy balance (e.g., heat losses to ambient, transient thermal effects, sensor offsets, etc.).

In some implementations, controller 126 may use the estimated flow rate produced by the virtual flow sensor for fault detection and diagnostics (FDD) within data center cooling system 100. For example, controller 126 may compare the estimated flow rate to an expected flow rate (e.g., based on the current operating state of pumps 121 and/or 131 and/or valves 133 and/or 166) and identify a deviation between the estimated flow rate and the expected flow rate as indicative of a fault condition, such as fouling, scaling, or blockage in one or more microchannels of a cold plate, in a coolant supply line, in a coolant return line, in a manifold, or in another component of the liquid coolant circuit. Controller 126 may generate an alert, log a fault, and/or adjust operation of one or more flow control devices in response to identifying such a fault condition. In some embodiments, controller 126 may automatically adjust a control strategy or perform a control action in response to identifying such a fault condition (e.g., redirecting or rerouting fluid flow to bypass the faulty component or blockage, opening/closing valves to direct coolant through alternative paths, etc.).

By way of further example, in response to identifying a fault condition based on the estimated flow rate, controller 126 may take any of various automatic remedial actions. For example, controller 126 may close one or more valves 133 or 166 associated with the affected branch of the liquid coolant circuit and open one or more valves 133 or 166 associated with an alternative branch to redirect coolant around the suspected fouling, scaling, or blockage. Controller 126 may increase the speed of pump 121 and/or pump 131 to increase the flow rate of the liquid coolant in an attempt to compensate for, or temporarily mitigate the effects of, the increased flow resistance caused by the fault condition. Controller 126 may shift cooling load to air cooling system 230 or to other portions of liquid cooling system 220 that are not affected by the fault condition. In some implementations, controller 126 may initiate a maintenance workflow (e.g., generating a work order, scheduling a flush or descaling cycle, etc.) and may continue to monitor the estimated flow rate to assess whether the fault condition is improving, stable, or worsening over time.

In various implementations, controller 126 may be configured to independently control the flow of secondary coolant at different levels of granularity within the data center cooling system 100. For example, controller 126 may adjust the flow rate and/or pressure of coolant supplied to individual racks 102, such that one rack 102 receives a different coolant flow compared to another rack 102. In some embodiments, controller 126 may independently control coolant flow to individual server trays 104 within a single rack 102. This allows for different flow rates and/or pressures to be applied to separate trays 104, even if they are housed in the same rack 102. In some implementations, controller 126 may adjust coolant flow to specific heat-generating components. In some such implementations, controller 126 may adjust coolant flow to different heat-generating components in different trays 104 or the same tray 104. This approach may allow controller 126 to provide for different flow rates and/or pressures to be applied to individual components, even if they are located on the same tray 104 or within the same rack 102. Such fine-tuned control may allow for highly targeted cooling based on the specific thermal requirements of different equipment at various levels of the data center infrastructure. While this level of control is discussed with respect to the example embodiment of FIG. 5, it should be understood that similar features may be utilized in conjunction with other embodiments described herein, including, but not limited to, the embodiments described below with respect to FIGS. 6-17.

Referring now to FIG. 6, illustrated is a method 200 of controlling a data center cooling system. The method 200 can be executed, performed, or otherwise carried out by data center cooling system 100 described herein (e.g., the embodiment of data center cooling system 100 illustrated in FIG. 5), in some implementations. In brief overview of the method 200, the method 200 can include circulating a liquid coolant through one or more racks, one or more server trays, or one or more components of the heat-generating data center equipment to cool the heat-generating data center equipment (step 202), obtaining feedback indicating a controlled temperature affected by cooling the heat-generating data center equipment (step 204), and operating one or more pumps, valves, or other flow control devices to adjust a flow rate and/or a pressure of the liquid coolant in the liquid coolant circuit based on a value of the controlled temperature (step 206).

In some implementations, step 202 can involve circulating the liquid coolant through the primary coolant loop 120 and the secondary coolant loop 130. The controller 126 can operate pump 121 to circulate the primary coolant through the primary coolant loop 120, which can include the primary coolant supply 122 and the primary coolant return 124. The controller 126 can also operate pump 131 to circulate the secondary coolant through the secondary coolant loop 130, which can include the secondary coolant supply 132 and the secondary coolant return 134.

In various embodiments, step 202 can involve circulating the liquid coolant through racks 102, such as AI rack 102a, CPU rack 102b, and GPU racks 102c. The liquid coolant can additionally or alternatively be circulated through server trays 104, such as AI tray 104a, GPU tray 104b, and CPU tray 104c. The controller 126 can operate valves 133 and 166 to control the flow of liquid coolant to individual racks 102 and server trays 104.

In some implementations, step 204 can involve obtaining temperature measurements from various sensors positioned throughout the data center cooling system 100. The controller 126 can receive temperature information from sensors located in the primary coolant loop 120, the secondary coolant loop 130, the racks 102, the server trays 104, and/or other locations. The controlled temperature can be a temperature of the heat-generating data center equipment, a coolant return temperature, or any other temperature affected by the cooling process.

In various embodiments, step 206 can involve the controller 126 adjusting the flow rate and/or pressure of the liquid coolant based on the obtained temperature feedback. The controller 126 can operate pump 121 and/or pump 131 to increase or decrease the flow rate of the liquid coolant in the primary coolant loop 120 and/or the secondary coolant loop 130, respectively. The controller 126 can additionally or alternatively operate valves 133 and/or valves 166 to modulate the flow of liquid coolant to specific racks 102 or server trays 104.

In some implementations, step 206 can involve the controller 126 implementing a control algorithm, such as a proportional-integral-derivative (PID) control algorithm, to adjust the cooling parameters. The controller 126 can compare the controlled temperature to a target temperature or temperature range and adjust the flow rate and/or pressure of the liquid coolant accordingly. For example, if the controlled temperature exceeds a target value, the controller 126 can increase the coolant flow rate by adjusting the speed of pumps 121 and/or 131, or by modulating the position of valves 133 and/or 166.

In various implementations, method 200 may include any of the steps, features, or functions described with respect to FIG. 5, and all such implementations are contemplated within the scope of the present disclosure. As one non-limiting example, method 200 may involve controlling the flow rate and/or pressure to maintain the temperature of one or more processors below applicable throttle temperatures. In another example, method 200 may involve controlling the flow rate and/or pressure to maintain the temperature below a maximum permissible temperature for equipment.

### Coolant Temperature Control

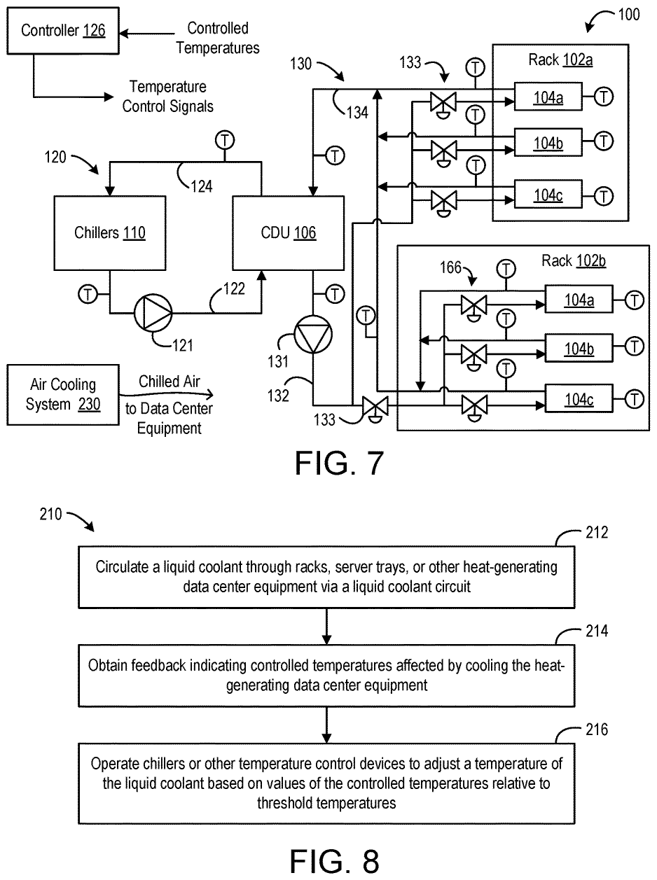

Referring now to FIG. 7, illustrated is a block diagram of a data center cooling system 100, according to another example embodiment. Various components illustrated in FIG. 7 are the same or similar to those illustrated in other figures, including FIG. 5. Where components have the same or similar description and/or share reference numerals in common with corresponding components described in relation to other figures, such as FIG. 5, it should be understood that, in various implementations, the structure, features, and/or functions of the components described in relation to the other figures can be utilized in conjunction with the embodiments and features described in FIG. 7, and vice versa.

As depicted in FIG. 7, system 100 may have the same or similar structural arrangement as described with reference to FIG. 5. For example, system 100 can include chillers 110 connected to a CDU 106 through a primary coolant loop 120. A pump 121 can circulate coolant through primary coolant loop 120, which can include a primary coolant supply 122 and primary coolant return 124.

CDU 106 can interface with racks 102 through a secondary coolant loop 130. Secondary coolant loop 130 can include a pump 131 that circulates coolant through a secondary coolant supply 132 and secondary coolant return 134. Valves 133 can be positioned along secondary coolant loop 130 to control coolant flow to individual racks 102. In some embodiments, heat may be transferred between primary coolant loop 120 and secondary coolant loop 130, such as via a heat exchanger within CDU 106.

Racks 102 can include several types of server configurations, in various embodiments: AI rack 102a, CPU rack 102b, and GPU racks 102c. Server trays 104 can be installed within racks 102, including, in some implementations, AI tray 104a, GPU tray 104b, and CPU tray 104c. Valves 133 and 166 can control coolant flow to individual racks 102, individual server trays 104, and/or to individual components within server trays 104 (e.g., individual CPUs, GPUs, DIMMs, power supplies, etc.).

In the embodiment shown in FIG. 7, controller 126 may operate in a similar manner as described with reference to FIG. 5 (i.e., to achieve a target or reference temperature at one or more locations within system 100). However, instead of operating one or more flow control devices to achieve the target or reference temperature as described with reference to FIG. 5, controller 126 may operate one or more temperature control devices to affect the temperature of the liquid coolant. For example, controller 126 can monitor controlled temperatures and provide temperature control signals to regulate operation of cooling system components. Controller 126 can receive temperature feedback from one or more of various points in system 100 and adjust cooling parameters accordingly. In some implementations, controller 126 can control one or more temperature control devices to control a temperature of the liquid coolant circulated through the liquid coolant circuit (e.g., primary coolant loop 120 and/or secondary coolant loop 130). In some embodiments, controller 126 may control the temperature control devices by generating and transmitting one or more temperature control signals configured to cause the temperature control devices to modify (e.g., increase or decrease) the temperature of the liquid coolant.

The temperature control devices can include any component or device of system 100 which can be operated to affect the temperature of the primary coolant in primary coolant loop 120, the secondary coolant in secondary coolant loop 130, the chilled air supplied to racks 102 and/or server trays 104, the liquid coolant supplied to racks 102 and/or server trays 104, or any other controlled temperature in system 100. In some implementations, the one or more temperature control devices can include the one or more chillers 110 operable to cool the liquid coolant supplied to racks 102 and/or trays 104. Controller 126 may generate control signals configured to cause chiller 110 to increase or decrease an amount of cooling provided to the liquid coolant.

In implementations in which the one or more temperature control devices include chillers 110, controller 126 may adjust the temperature of the liquid coolant by adjusting any of various operating parameters of chillers 110, such as a setpoint temperature of the primary coolant leaving evaporator 115, a speed of compressor 117 (e.g., via a variable frequency drive), a number of compressors 117 staged on or off (in implementations having multiple compressors), a position of expansion valve 119, a flow rate of condenser water through condenser 113, and/or any other operating parameter that affects the cooling capacity of chillers 110. In implementations in which one or more of chillers 110 includes a free cooling component (e.g., an outdoor air heat exchanger, a cooling tower, a waterside economizer, etc.), controller 126 may also adjust the temperature of the liquid coolant by selectively engaging or disengaging the free cooling component or by adjusting the proportion of the cooling load served by free cooling versus mechanical cooling.

In some implementations, the one or more temperature control devices can include the CDU 106. Controller 126 may generate control signals configured to cause CDU 106 to modify operation to increase or decrease an amount of cooling provided to the liquid coolant. In some such implementations, the control signals may cause CDU 106 to modify an operational state to change the temperature of the liquid coolant provided via secondary coolant loop 130 to the racks 102, server trays 104, and/or components in the server trays 104.

In some implementations, CDU 106 may be configured to adjust the temperature of the liquid coolant supplied to racks 102 by, for example, modulating the flow rate of the primary coolant through the heat exchanger of CDU 106 (e.g., by controlling a primary-side pump or valve to vary the rate of heat transfer from the secondary coolant to the primary coolant), modulating the flow rate of the secondary coolant through the heat exchanger of CDU 106 (e.g., by controlling a secondary-side pump or valve), opening or closing a bypass valve that allows a portion of the secondary coolant to bypass the heat exchanger and mix with the cooled secondary coolant downstream of the heat exchanger, and/or operating a mixing valve that controls the proportion of cooled secondary coolant and warmer return secondary coolant in the supply provided to racks 102. By controlling the position of the bypass valve or mixing valve, controller 126 can modulate the temperature of secondary coolant supply 132 between the temperature of the cooled secondary coolant exiting the heat exchanger of CDU 106 and the temperature of secondary coolant return 134 returning from racks 102.

In some implementations, controller 126 can be configured to operate flow control devices, such as pumps (e.g., pump 121) and/or valves, to affect an amount of heat transferred from the secondary coolant to the primary coolant in the heat exchanger within CDU 106 by modulating a flow rate of the primary coolant through the heat exchanger. In some implementations, controller 126 can additionally or alternatively be configured to operate flow control devices, such as pumps (e.g., pump 131) and/or valves (e.g., valves 133 and/or 166), to affect an amount of heat transferred from the secondary coolant to the primary coolant in the heat exchanger within CDU 106 by modulating a flow rate of the secondary coolant through the heat exchanger.

In some implementations, data center cooling system 100 may include multiple coolant loops or coolant supply lines configured to circulate liquid coolant at different temperatures (e.g., a relatively colder loop, a relatively warmer loop, and/or one or more loops at intermediate temperatures), such as the multiple primary coolant loops 120 described above. In such implementations, controller 126 may adjust the temperature of the liquid coolant supplied to a particular rack 102, server tray 104, and/or heat-generating component by selecting which of the multiple coolant loops or supply lines is fluidly coupled to that rack 102, server tray 104, and/or heat-generating component (e.g., by operating one or more selection valves) and/or by mixing coolant from two or more of the multiple coolant loops or supply lines in selected proportions to achieve a target supply temperature. For example, a particular server tray 104 containing high-power processors may be supplied with coolant from a relatively colder loop, while another server tray 104 containing lower-power components may be supplied with coolant from a relatively warmer loop, allowing controller 126 to match the supply coolant temperature to the cooling needs of each portion of the heat-generating data center equipment.

In some implementations, the liquid coolant circuit (e.g., secondary coolant loop 130) can include a coolant supply manifold configured to deliver liquid coolant to server trays 104 within rack 102. The liquid coolant circuit can include a coolant return manifold configured to receive liquid coolant from server trays 104 within rack 102. The liquid coolant circuit can include a plurality of branches connecting the coolant supply manifold to the coolant return manifold via the server trays 104. In some such implementations, the controlled temperature can be a temperature of one of the plurality of branches.

In some implementations, two or more of server trays 104 can add different amounts of heat to different flows of liquid coolant through the plurality of branches, causing temperatures of liquid coolant to vary across outlets of the branches. Controller 126 can be configured to operate one or more temperature control devices to maintain a temperature of liquid coolant (e.g., a maximum temperature) at outlets of plurality of branches at or below a reference temperature.

Controller 126 may maintain the temperature of the liquid coolant at outlets of the plurality of branches at or below the reference temperature by, for example, decreasing the temperature of the liquid coolant supplied to the coolant supply manifold (e.g., by operating chillers 110 and/or CDU 106 to provide additional cooling to the supply coolant) so that, even after absorbing heat from the heat-generating data center equipment within the various server trays 104, the warmest of the branch outlet temperatures remains at or below the reference temperature. In some implementations, controller 126 may identify the branch having the highest outlet temperature (e.g., the branch serving the highest-heat server tray 104 at a given time) and may adjust the supply coolant temperature based on the outlet temperature of that branch. In some implementations, controller 126 may additionally or alternatively operate one or more dedicated temperature control devices associated with individual branches (e.g., per-branch mixing valves or supplemental heat exchangers) to independently adjust the temperature of liquid coolant supplied to one or more branches based on the corresponding branch outlet temperature.

In some implementations, the branches may supply liquid coolant to particular computing devices or other circuitry located within the server trays 104. In some such implementations, controller 126 can be configured to operate one or more temperature control devices based on the controlled temperature relative to one or more reference temperatures for one or more of the plurality of computing devices installed on server tray 104.

In some implementations, rack 102 can include a plurality of compartments and heat-generating data center equipment can be distributed across plurality of compartments. The liquid coolant circuit can be configured to circulate liquid coolant through the compartments. Controller 126 can be configured to operate one or more temperature control devices to adjust temperature of liquid coolant circulating through one or more compartments of plurality of compartments.

In some implementations, controller 126 can be configured to operate the one or more temperature control devices to adjust temperature of the liquid coolant supplied to rack 102 based on feedback indicating value of controlled temperature affected by cooling the heat-generating data center equipment relative to a reference temperature.

In some implementations, the controlled temperature affected by cooling heat-generating data center equipment can include at least one of: a temperature of heat-generating data center equipment within rack 102, a temperature measured by a temperature sensor positioned at or near a location of the heat-generating data center equipment, a temperature of a processor, GPU, CPU, memory module, or other hardware component of the heat-generating data center equipment, a temperature reported by one or more devices of the heat-generating data center equipment, a coolant return temperature of the liquid coolant exiting rack 102 after absorbing heat from heat-generating data center equipment, a temperature of a secondary coolant that absorbs heat from the heat-generating data center equipment within rack 102, and/or a temperature of a primary coolant used to absorb heat from the secondary coolant.

In some implementations, the controlled temperature affected by cooling heat-generating data center equipment can be a temperature of the heat-generating data center equipment within rack 102. Controller 126 can be configured to obtain a reference temperature including a maximum permissible temperature of the heat-generating data center equipment within rack 102, such as in a manner described above with respect to FIG. 5. Controller 126 can be configured to operate one or more temperature control devices to adjust the temperature of liquid coolant supplied to rack 102 to maintain the temperature of heat-generating data center equipment at or below the maximum permissible temperature.

In some implementations, the heat-generating data center equipment can include one or more processors configured to throttle upon reaching a predetermined temperature. Controller 126 can be configured to obtain a reference temperature including a predetermined temperature at which the processor is configured to throttle, such as in a manner described above with respect to FIG. 5. Controller 126 can be configured to operate the one or more temperature control devices to adjust the temperature of the liquid coolant supplied to rack 102 to maintain a temperature of the processor at or below predetermined temperature at which processor is configured to throttle.

In some implementations, the controlled temperature affected by cooling heat-generating data center equipment can be a coolant return temperature of the liquid coolant exiting rack 102 after absorbing heat from heat-generating data center equipment (e.g., a temperature of coolant in the secondary coolant return 134). Controller 126 can be configured to obtain a reference temperature including a target value of the coolant return temperature, such as in a manner described above with respect to FIG. 5. Controller 126 can be configured to operate the one or more temperature control devices to adjust temperature of liquid coolant supplied to rack 102 based on a measured value of the coolant return temperature relative to the target value of the coolant return temperature.

In some implementations, the controlled temperature affected by cooling heat-generating data center equipment can be a coolant return temperature of liquid coolant exiting rack 102 after absorbing heat from heat-generating data center equipment. Controller 126 can be configured to obtain a reference temperature including a target temperature difference between the coolant return temperature and a coolant supply temperature of liquid coolant supplied to rack 102. Controller 126 can be configured to operate the one or more temperature control devices based on a measured value of the coolant return temperature and the target temperature difference.

Operating the one or more temperature control devices to maintain a target temperature difference between the coolant return temperature and the coolant supply temperature can advantageously help maintain operation of CDU 106 and/or chillers 110 within an efficient operating range and can help confirm that an appropriate amount of heat is being absorbed from the heat-generating data center equipment by the liquid coolant. For example, a coolant return temperature that is significantly lower than the coolant supply temperature plus the target temperature difference may indicate that the supply coolant is colder than necessary to cool the heat-generating data center equipment, in which case controller 126 may operate the one or more temperature control devices to increase the supply coolant temperature, thereby increasing energy efficiency. Conversely, a coolant return temperature that exceeds the coolant supply temperature plus the target temperature difference by more than a threshold amount may indicate that the heat-generating data center equipment is generating more heat than the current flow rate of the liquid coolant can absorb at the current supply temperature, in which case controller 126 may operate the one or more temperature control devices to decrease the supply coolant temperature.

In some implementations, system 100 can further include an air cooling system configured to transfer heat into an airflow from the heat-generating data center equipment within rack 102. Controller 126 can be further configured to operate one or more temperature control devices of air cooling system based on the value of the controlled temperature. In some such implementations, the air cooling system may include one or more computer room air conditioner (CRAC) units, one or more computer room air handler (CRAH) units, one or more direct evaporative cooling (DEC) units, one or more indirect evaporative cooling (IEC) units, one or more free cooling units, and/or any other type of airside HVAC equipment.

In some implementations, one or more temperature control devices of air cooling system can include a fan or a damper operable to affect a temperature of airflow provided to rack 102 by the air cooling system. Controller 126 can be configured to adjust a speed of the fan or a position of the damper based on the value of the controlled temperature.

In some implementations, controller 126 may control the cooling of the heat-generating data center equipment using both the liquid coolant circuit and the air cooling system. In some implementations, controller 126 may coordinate control of both the liquid cooling temperature and the air cooling system to provide cooling to the heat-generating data center equipment. Controller 126 may obtain feedback indicating controlled temperatures affected by cooling the heat-generating data center equipment, such as temperatures of components within racks 102 or server trays 104, coolant return temperatures, or air temperatures. Controller 126 may adjust the temperature of the liquid coolant supplied by the liquid cooling system and parameters of the air cooling system in tandem.

For example, if the controlled temperatures are below target values, controller 126 may increase the temperature of the liquid coolant supplied by chillers 110 or CDU 106 while simultaneously reducing airflow or increasing air temperature provided by the air cooling system. Conversely, if controlled temperatures are above target values, controller 126 may decrease liquid coolant temperature while increasing airflow or decreasing air temperature from the air cooling system.

Controller 126 may implement various control algorithms to determine combinations of liquid coolant temperature and air cooling parameters. In some cases, controller 126 may prioritize liquid cooling (e.g., use greater cooling of the liquid coolant) for high-heat components like processors or GPUs while relying more on air cooling for lower-heat components. The controller may also adjust the balance between liquid and air cooling based on factors such as outside air temperature, overall heat load in the data center, or energy costs associated with each cooling method, in various implementations.

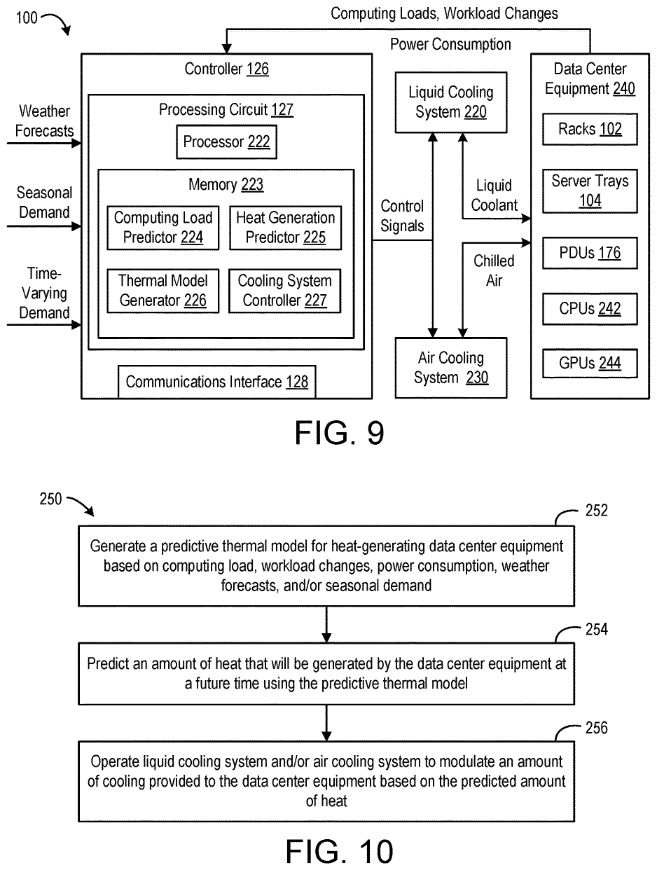

In some implementations, controller 126 may implement a tiered or cascaded control strategy that prioritizes one of the air cooling system (e.g., air cooling system 230 shown in FIG. 9) or the liquid cooling system (e.g., liquid cooling system 220 shown in FIG. 9) based on the magnitude of the controlled temperature relative to one or more reference temperatures. For example, while a controlled temperature is below a first threshold, controller 126 may rely primarily on air cooling system 230 and may maintain the supply coolant temperature at a relatively warmer setpoint (e.g., to reduce mechanical cooling energy at chillers 110). As the controlled temperature approaches or exceeds the first threshold, controller 126 may begin to decrease the supply coolant temperature and/or activate additional temperature control devices of liquid cooling system 220 to engage liquid cooling. As the controlled temperature approaches or exceeds a second, higher threshold, controller 126 may further decrease the supply coolant temperature provided by liquid cooling system 220 and/or operate air cooling system 230 at a higher capacity (e.g., increasing fan speed or decreasing supply air temperature). In some implementations, controller 126 may select the supply coolant temperature based on a continuous function of the controlled temperature (e.g., using a reset schedule, a PID control loop, or a model predictive control formulation) such that the supply coolant temperature varies smoothly with the controlled temperature.

In various embodiments, controller 126 may control the temperature of coolant provided to various components at different levels of granularity. For example, controller 126 may control the temperature for different racks 102, different trays 104 (e.g., within the same or different racks 102), and/or different components within the trays 104 (e.g., within the same or different trays 104 and/or racks 102). In some examples, this may be performed in a manner similar to that described above, for example, with respect to FIG. 5.

Controller 126 may control the temperature of liquid coolant provided to different racks 102, different server trays 104, and/or different heat-generating components at different levels of granularity using any of various mechanisms. For example, in some implementations, separate temperature control devices (e.g., separate chillers 110, CDUs 106, mixing valves, secondary heat exchangers, etc.) may be associated with different racks 102, different server trays 104, or different groups thereof, and controller 126 may independently operate each such temperature control device to provide a different supply coolant temperature to the corresponding rack 102, server tray 104, or group. In some implementations, the liquid coolant circuit may include per-rack, per-tray, or per-component mixing valves that mix relatively colder supply coolant with relatively warmer return coolant in different proportions to achieve different local supply coolant temperatures at different locations within data center cooling system 100. In some implementations, controller 126 may control the temperature of the liquid coolant at the cold plate level by adjusting the flow rate of the liquid coolant through the cold plate (e.g., using valves 133 or 166), thereby altering the rate of heat absorption and the resulting temperature of the coolant within or downstream of the cold plate, even where the coolant supply temperature is not separately controlled at the cold plate level.

In some implementations, controller 126 may obtain temperature sensor data from one or more of various sources within data center cooling system 100, in a manner similar to that described above with reference to FIG. 5. For example, controller 126 may receive temperature sensor data from a basic input/output system (BIOS), baseboard management controller (BMC), or other firmware or thermal management interface of one or more servers, server trays 104, processors, or other components of the heat-generating data center equipment within racks 102. Additionally or alternatively, controller 126 may receive temperature sensor data from a data center infrastructure management (DCIM) system communicatively coupled to data center cooling system 100. In some implementations, one or more temperature sensors of data center cooling system 100 may be connected to or in thermal communication with a coolant supply line and/or a coolant return line of rack 102, server tray 104, and/or a cold plate of the heat-generating data center equipment, and/or may be embedded within a cold plate, a coolant supply line, a coolant return line, a coupling that fluidly connects a supply or return line to a manifold, and/or a manifold of rack 102 and/or server tray 104. Controller 126 may use temperature data obtained from any combination of these sources as the controlled temperature, or as an input from which the controlled temperature is derived, when operating the one or more temperature control devices to adjust the temperature of the liquid coolant.

In some implementations, one or more sensors (e.g., temperature, pressure, flow rate, etc.) of data center cooling system 100 may be implemented as energy-harvesting sensors, in a manner similar to that described above with reference to FIG. 5. For example, an energy-harvesting temperature sensor may be positioned within an information technology (IT) space of the data center and configured to harvest energy from a temperature difference between the liquid coolant flowing through one or more coolant lines of data center cooling system 100 and the ambient air within the IT space (e.g., using a thermoelectric generator or other thermal-to-electrical energy transducer). The harvested energy may be used to power operation of the sensor and/or to power wireless or wired communication of data measured by the sensor to controller 126 or another component of data center cooling system 100. Such energy-harvesting sensors may operate without a dedicated wired power source and without battery replacement, which may simplify deployment of additional sensors throughout the data center for use in monitoring and controlling the temperature of the liquid coolant supplied to the heat-generating data center equipment.

In some implementations, controller 126 may receive input from one or more Hall effect sensors (e.g., Hall sensors arranged to measure current draw of one or more processors, server trays 104, racks 102, or other heat-generating data center equipment) and use the Hall sensor measurements as a proxy for the power consumption of such heat-generating data center equipment (e.g., chip power, CPU power, GPU power, etc.). The one or more Hall effect sensors may be positioned around or proximate to a power conductor that supplies electrical power to a particular processor, server tray 104, rack 102, or PDU 176 (e.g., clamped around a power cable, integrated into a busbar, integrated into a power distribution unit, mounted on a printed circuit board carrying a heat-generating component, etc.) such that the Hall effect sensor produces an output signal proportional to the magnetic field generated by current flowing through the conductor. Advantageously, changes in power consumption or power draw can be observed by a Hall sensor before corresponding changes in temperature propagate through the thermal mass and time constants of the chip case, the cold plate, the thermal interface material (TIM), and the liquid coolant. Accordingly, controller 126 may use the Hall sensor data to detect a change in the power consumption of the heat-generating data center equipment in advance of the temperature sensors detecting a corresponding change in temperature, and may proactively operate the one or more temperature control devices to adjust the temperature of the liquid coolant supplied to rack 102, server tray 104, and/or individual heat-generating components based on the Hall sensor data before such temperature change is observed. For example, in response to detecting an increase in chip power based on the Hall sensor data, controller 126 may operate chillers 110, CDU 106, and/or other temperature control devices to decrease the temperature of the liquid coolant supplied to the affected heat-generating data center equipment in advance of the temperature of the heat-generating data center equipment increasing.

In some implementations, controller 126 may be configured to implement or utilize a model (e.g., a regression model, an artificial intelligence (AI) model, a machine learning (ML) model, or other predictive model) to anticipate thermal throttling of one or more processors or other components of the heat-generating data center equipment. For example, the model may be trained or configured to predict, based on inputs such as workload patterns, processor utilization, power consumption data, Hall sensor measurements indicative of chip power, current temperature measurements, historical temperature trends, and/or other relevant parameters, that a processor or other component is approaching its applicable throttle temperature. The model may be trained or configured using historical operational data collected from data center cooling system 100 and/or the heat-generating data center equipment, such as historical workload traces, processor utilization logs, power consumption traces, historical temperature traces, historical coolant temperatures, and/or recorded throttling events, and may output, for example, a predicted temperature of a processor or other component at one or more future time horizons, a predicted time-to-throttle, and/or a probability that the processor will throttle within a specified time window. In response to a prediction by the model that a processor or other component is approaching its throttle temperature, controller 126 may operate the one or more temperature control devices of data center cooling system 100 (e.g., chillers 110, CDU 106, and/or other temperature control devices) to decrease the temperature of the liquid coolant supplied to the affected processor, server tray 104, or rack 102, thereby acting to reduce the temperature of the processor before throttling occurs. Controller 126 may select a magnitude of the temperature adjustment (e.g., how much to decrease the supply temperature of the liquid coolant) based on the predicted severity and timing of the impending throttling event.

In some implementations, data center cooling system 100 may include or implement one or more virtual flow sensors configured to estimate a flow rate of the liquid coolant at one or more locations within the liquid coolant circuit without directly measuring the flow rate at those locations. For example, controller 126 may be configured to implement a model (e.g., a regression model, an artificial intelligence (AI) model, a machine learning (ML) model, or other model) that relates an input coolant temperature (e.g., a coolant supply temperature measured upstream of a cold plate, server tray 104, or rack 102), an output coolant temperature (e.g., a coolant return temperature measured downstream of the cold plate, server tray 104, or rack 102), and a Hall sensor reading indicative of chip power (e.g., as a proxy for the heat being added to the coolant by the heat-generating data center equipment) to an estimated flow rate of the liquid coolant. In some implementations, the model may be based on, or otherwise reflect, an energy balance between the heat absorbed by the liquid coolant as it flows through the cold plate, server tray 104, or rack 102 and the heat generated by the corresponding heat-generating data center equipment (e.g., Q=\dot{m}×Cₚ×(Tₒᵤₜ−Tᵢₙ)). The estimated flow rate generated by the virtual flow sensor may be used by controller 126 in lieu of, or in conjunction with, measurements from one or more physical flow sensors, including, for example, when controller 126 determines an amount of heat being absorbed from the heat-generating data center equipment by the liquid coolant for use in selecting a temperature setpoint for the liquid coolant.

In some implementations, controller 126 may use the estimated flow rate produced by the virtual flow sensor for fault detection and diagnostics (FDD) within data center cooling system 100. For example, controller 126 may compare the estimated flow rate to an expected flow rate (e.g., based on the current operating state of pumps 121 and/or 131 and/or valves 133 and/or 166) and identify a deviation between the estimated flow rate and the expected flow rate as indicative of a fault condition, such as fouling, scaling, or blockage in one or more microchannels of a cold plate, in a coolant supply line, in a coolant return line, in a manifold, or in another component of the liquid coolant circuit. Controller 126 may generate an alert, log a fault, and/or perform a remedial action in response to identifying such a fault condition, such as decreasing the temperature of the liquid coolant supplied to the affected portion of the liquid coolant circuit to compensate for a reduced flow rate caused by the fault condition, redirecting or rerouting fluid flow to bypass the affected component (e.g., by opening or closing one or more valves 133 or 166), shifting cooling load to air cooling system 230 or to other portions of liquid cooling system 220 not affected by the fault condition, and/or initiating a maintenance workflow.

Referring now to FIG. 8, illustrated is a method 210 of controlling a data center cooling system. The method 210 can be executed, performed, or otherwise carried out by data center cooling system 100 described herein (e.g., the embodiment of data center cooling system 100 illustrated in FIG. 7), in some implementations. In brief overview of the method 210, the method 210 can include circulating a liquid coolant through one or more racks, one or more server trays, or one or more components of the heat-generating data center equipment to cool the heat-generating data center equipment (step 212), obtaining feedback indicating a controlled temperature affected by cooling the heat-generating data center equipment (step 214), and operating one or more chillers or other temperature control devices to adjust a temperature of the liquid coolant supplied to the one or more racks, the one or more server trays, or the one or more components of the heat-generating data center equipment based on a value of the controlled temperature (step 216).

In some implementations, step 212 can involve circulating the liquid coolant through the primary coolant loop 120 and the secondary coolant loop 130. The controller 126 can operate pump 121 to circulate the primary coolant through the primary coolant loop 120, which can include the primary coolant supply 122 and the primary coolant return 124. The controller 126 can also operate pump 131 to circulate the secondary coolant through the secondary coolant loop 130, which can include the secondary coolant supply 132 and the secondary coolant return 134.

In various embodiments, step 212 can involve circulating the liquid coolant through racks 102, such as AI rack 102a, CPU rack 102b, and GPU racks 102c. The liquid coolant can additionally or alternatively be circulated through server trays 104, such as AI tray 104a, GPU tray 104b, and CPU tray 104c. The controller 126 can operate valves 133 and 166 to control the flow of liquid coolant to individual racks 102 and server trays 104.

In some implementations, step 214 can involve obtaining temperature measurements from one or more of various sensors positioned throughout the data center cooling system 100. The controller 126 can receive temperature information from sensors located in the primary coolant loop 120, the secondary coolant loop 130, the racks 102, the server trays 104, and/or other locations. The controlled temperature can be a temperature of the heat-generating data center equipment, a coolant return temperature, or any other temperature affected by the cooling process.

In various embodiments, step 216 can involve the controller 126 adjusting the temperature of the liquid coolant based on the obtained temperature feedback. The controller 126 can operate chillers 110 to increase or decrease the temperature of the liquid coolant in the primary coolant loop 120 and/or the secondary coolant loop 130. The controller 126 can additionally or alternatively operate CDU 106 to adjust the temperature of the liquid coolant supplied to racks 102 or server trays 104.

In some implementations, step 216 can involve the controller 126 implementing a control algorithm, such as a proportional-integral-derivative (PID) control algorithm, to adjust the cooling parameters. The controller 126 can compare the controlled temperature to a target temperature or temperature range and adjust the temperature of the liquid coolant accordingly. For example, if the controlled temperature exceeds a target value, the controller 126 can decrease the temperature of the liquid coolant by operating chillers 110 and/or CDU 106 to provide additional cooling (e.g., by sending control signals to chillers 110 and/or CDU 106).

In various implementations, method 210 may include any of the steps, features, or functions described with respect to FIG. 7, and all such implementations are contemplated within the scope of the present disclosure. As one non-limiting example, method 210 may involve controlling the temperature of the liquid coolant to maintain the temperature of one or more processors below applicable throttle temperatures. In another example, method 200 may involve controlling the temperature of the liquid coolant to maintain the temperature below a maximum permissible temperature for equipment.

### Predictive Temperature Control

Referring now to FIG. 9, a block diagram of data center cooling system 100 is shown according to another example implementation. The components shown in FIG. 9 may be structured, function, and/or have features similar to those described with respect to the same or similar components described elsewhere in the present disclosure. For example, controller 126 can provide control signals to a liquid cooling system 220 (e.g., chillers 110, primary coolant loop 120, secondary coolant loop 130, pumps 121 and 131, CDU 106, valves 123, 125, 133, and 166, etc.) and an air cooling system 230 (e.g., air cooler 108, fans 109 and 112, dampers 103 and 105, etc.). Liquid cooling system 220 can supply liquid coolant to data center equipment 240, while air cooling system 230 can provide chilled air as described with reference to previous figures.

Data center equipment 240 can include racks 102 containing server trays 104, central processing units (CPUs) 242, and/or graphics processing units (GPUs) 244. In some implementations, data center equipment 240 includes power distribution units (PDUs) 176 configured to provide power to various of data center equipment 240. Liquid cooling system 220 and air cooling system 230 can modulate cooling provided to these components based on power consumption measurements and/or predictions and control signals from controller 126, in some implementations.

Controller 126 is shown to include a processing circuit 127 and a communications interface 128. Processing circuit 127 can contain a processor 222 and memory 223. It should be understood that, in various embodiments, processor 222 and memory 223 may include a single processor and/or a single memory or may include multiple processors and/or multiple memories (e.g., multiple local processors and/or memories, distributed or cloud computing devices, etc.).

Memory 223 can include a computing load predictor 224, a heat generation predictor 225, a thermal model generator 226, and a cooling system controller 227. In various implementations, the components shown in memory 223 may be implemented using hardware, software, or a combination thereof. In some implementations, the components may be implemented using instructions stored on memory 223 and executable by processor 222 to implement the functions and steps described herein. The components of controller 126 may function to predict a computing load of data center equipment 240 at a future time and predict an amount of heat that will be generated by each component of data center equipment 240 based on the predicted computing load. Controller 126 may then operate liquid cooling system 220 and/or air cooling system 230 to provide targeted cooling to data center equipment 240 based on the predicted amounts of heat that will be generated by each component of data center equipment 240.

In some implementations, controller 126 can operate only air cooling system 230 and not liquid cooling system 220 to cool heat-generating data center equipment 240 at a future time in response to a predicted amount of heat being below a threshold value. Controller 126 can operate both air cooling system 230 and liquid cooling system 220 to cool heat-generating data center equipment 240 at the future time in response to the predicted amount of heat being above the threshold value.

In some implementations, controller 126 can operate only liquid cooling system 220 and not air cooling system 230 to cool heat-generating data center equipment 240 at the future time in response to the predicted amount of heat being below a threshold value. Controller 126 can operate both liquid cooling system 220 and air cooling system 230 to cool heat-generating data center equipment 240 at the future time in response to the predicted amount of heat being above the threshold value.

In some implementations, controller 126 may utilize both air cooling system 230 and liquid cooling system 220 and control their operation according to the measured and/or predicted heat generation conditions. For example, controller 126 may operate liquid cooling system 220 such that the liquid coolant is at a higher temperature or lower flow rate or pressure in response to the measured or predicted temperature or heat generation being below a threshold. Controller 126 may operate liquid cooling system 220 such that the liquid coolant is at a lower temperature or higher flow rate or pressure in response to the measured or predicted temperature or heat generation being above a threshold.

Computing load predictor 224 can predict the computing load anticipated to be present for one or more racks 102, server trays 104, and/or components within racks 102 and/or server trays 104 (e.g., CPUs 242 and/or GPUs 244) at one or more future times/timeframes. Computing load predictor 224 can predict the computing load information based on historical computing load information and/or information about current or historical workload changes.

In some implementations, controller 126 may receive, generate, or otherwise obtain time-varying demand information indicative of how the demand for computing resources provided by data center equipment 240 varies as a function of time. The time-varying demand information may include, for example, intra-day demand patterns (e.g., demand variations across different hours of the day, such as a lull during the early morning hours and one or more spikes at other times of the day for a data center serving a population of users in a particular geographic region), day-of-week demand patterns (e.g., differences between weekdays and weekends, or between specific weekdays such as Monday versus Friday), holiday or special-event demand patterns (e.g., reduced demand on public holidays observed within the data center's primary service region, or elevated demand during scheduled events such as product launches or sales events), seasonal demand patterns (e.g., demand variations across months or quarters of the year), and/or time-zone-specific demand patterns (e.g., demand patterns that follow business hours in one or more time zones served by the data center). For example, a data center located in North America and primarily serving users in North America may experience relatively lower demand during the very early morning hours of the local time zone and relatively higher demand (e.g., one or more spikes in demand) at other times of the day, while also exhibiting different demand patterns on weekdays, weekends, and holidays observed in North America.

Computing load predictor 224 and/or heat generation predictor 225 may use the time-varying demand information when generating predictions of future computing load and/or heat generation for data center equipment 240. For example, computing load predictor 224 may apply a time-of-day demand profile, a day-of-week demand profile, a holiday calendar, and/or a seasonal demand profile to a baseline computing load to generate a predicted computing load at one or more future times. Computing load predictor 224 may identify the time-varying demand patterns by analyzing historical computing load data, historical power consumption data, historical request or transaction logs, and/or historical user activity data collected over one or more prior time periods, and may update the time-varying demand patterns over time as additional data becomes available. In some implementations, controller 126 may use the time-varying demand information to proactively adjust operation of liquid cooling system 220 and/or air cooling system 230 in advance of an anticipated change in demand (e.g., increasing cooling capacity in advance of a predicted demand spike, reducing cooling capacity in advance of a predicted lull, etc.), thereby helping to maintain the temperatures of data center equipment 240 within target ranges as the demand for computing resources varies over time.

In some implementations, computing load predictor 224 can receive the computing load information from data center equipment 240 or data center management equipment. In some implementations, computing load predictor 224 can analyze the computing load and workload change information received from data center equipment 240 or data center management equipment to identify temporal patterns for particular racks 102, server trays 104, and/or components within server trays 104 (e.g., CPUs 242 and/or GPUs 244). Computing load predictor 224 can examine historical data to detect recurring patterns of higher or lower computing loads associated with specific time periods, such as certain times of day, days of the week, or seasons of the year. For example, computing load predictor 224 can identify that a particular rack 102 experiences consistently higher computing loads during weekday business hours and lower loads during nights and weekends.

In some implementations, computing load predictor 224 can use machine learning algorithms to analyze the historical computing load data and identify more complex patterns or trends. Computing load predictor 224 can train a predictive model using features such as time of day, day of week, month, and historical load data for each rack 102, tray 104, or component (e.g., CPUs 242 or GPUs 244). The trained model can then be used to forecast future computing loads for specific time periods. For example, computing load predictor 224 can use the trained model to predict that a certain GPU 244 will experience a spike in computing load every Friday afternoon due to a recurring batch processing job.

In some implementations, the machine learning algorithms used by computing load predictor 224 may include any of various model architectures suitable for time-series forecasting and pattern recognition. For example, computing load predictor 224 may use one or more of an autoregressive model (e.g., ARIMA or SARIMA), a regression model (e.g., linear regression, ridge regression, gradient boosted trees, random forest, etc.), an artificial neural network (e.g., a feedforward neural network, a recurrent neural network (RNN), a long short-term memory (LSTM) network, a gated recurrent unit (GRU) network, a transformer-based model, etc.), a Gaussian process regression model, or any other suitable model. The model may be trained using supervised learning techniques on a labeled training data set comprising historical input features (e.g., time-of-day indicators, day-of-week indicators, recent computing load history, recent power consumption history, recent temperature history, etc.) and corresponding labels representing the observed computing load. Computing load predictor 224 may evaluate the model on a validation data set, may periodically retrain or fine-tune the model using newly collected data, and may select among multiple candidate models based on accuracy or other performance metrics.

In some implementations, computing load predictor 224 can also incorporate external factors into the load predictions. For example, computing load predictor 224 can receive information about scheduled maintenance, planned software updates, or upcoming high-demand events from the data center management equipment. Computing load predictor 224 can adjust the predicted computing loads based on these external factors. For example, if a major software update is scheduled for a particular rack 102, computing load predictor 224 can anticipate a temporary increase in computing load for that rack 102 during the update process and for a period of time afterward as the system stabilizes.

In some implementations, computing load predictor 224 can base the prediction on historical cooling and/or temperature sensor information obtained by controller 126. In some implementations, computing load predictor 224 can use historical cooling and temperature sensor data to predict future computing loads for data center equipment 240. Computing load predictor 224 can analyze temperature trends and cooling system responses recorded over time to infer patterns in heat generation, which can be correlated with computing activity. For example, computing load predictor 224 can examine temperature readings from sensors located near CPUs 242 or GPUs 244 to identify periods of increased heat output, which may indicate higher computational demands. Computing load predictor 224 can also analyze data from coolant temperature sensors in primary coolant loop 120 and secondary coolant loop 130 to detect fluctuations in heat dissipation requirements across different areas of the data center.

In some implementations, computing load predictor 224 can incorporate cooling system operational data into the prediction model. Computing load predictor 224 can analyze historical records of chiller 110 activity, pump 121 and pump 131 speeds, and valve 133 and 166 positions to identify periods of increased cooling demand. By correlating the cooling system operational data with known computing events or schedules, computing load predictor 224 can develop a more comprehensive understanding of the relationship between cooling requirements and computational workloads. Computing load predictor 224 can use machine learning algorithms to process the historical cooling and temperature data, enabling computing load predictor 224 to recognize complex patterns and seasonal variations in cooling needs that may be indicative of recurring computational demands.

In some implementations, computing load predictor 224 can combine the insights gained from historical cooling and temperature data with other predictive factors to enhance the accuracy of future computing load forecasts. Computing load predictor 224 can integrate the cooling-based predictions with information about scheduled maintenance, software updates, or anticipated high-demand events to create a more holistic view of expected computational requirements. For example, if the historical cooling data indicates a pattern of increased heat generation in a particular rack 102 during certain times, and a major data processing task is scheduled for that rack 102, computing load predictor 224 can adjust the predicted computing load accordingly. Computing load predictor 224 can refine the predictive models as new cooling and temperature data becomes available (e.g., by retraining or fine-tuning the models with the new data), allowing for increasingly accurate forecasts of future computing loads based on thermal management patterns observed in the data center.

Heat generation predictor 225 can use the predicted computing load information from computing load predictor 224 to predict the heat anticipated to be generated by data center equipment 240 at one or more future times/timeframes. Heat generation predictor 225 can apply thermal models or heat generation coefficients to the predicted computing load for each component of data center equipment 240, such as CPUs 242, GPUs 244, trays 104, racks 102, or other heat-generating elements. In some implementations, heat generation predictor 225 can account for variations in heat generation efficiency across different types of components or under different operating conditions. For example, heat generation predictor 225 can apply different heat generation factors to CPUs 242 versus GPUs 244, or can adjust heat generation estimates based on predicted clock speeds, voltage levels, or other operational parameters.

In some implementations, the heat generation coefficients applied by heat generation predictor 225 may be derived from manufacturer-specified thermal design power (TDP) values for particular component types, from empirically measured power-to-heat conversion ratios determined by characterizing components under known load conditions, and/or from look-up tables that map operating points (e.g., processor utilization, clock frequency, supply voltage, etc.) to corresponding heat generation rates. In some implementations, heat generation predictor 225 may apply different heat generation coefficients to different components based on their operating mode (e.g., a higher coefficient when a processor is operating at a boosted clock frequency, a lower coefficient when the processor is operating at a reduced clock frequency or in a power-saving mode). For example, where the predicted computing load corresponds to a fraction of a component's maximum utilization, heat generation predictor 225 may estimate the heat output as a corresponding fraction of the component's TDP, optionally adjusted by an idle-power offset (e.g., to account for the baseline power consumed by the component even at very low utilization).

In some implementations, heat generation predictor 225 can incorporate additional factors beyond raw computing load to refine heat generation predictions. Heat generation predictor 225 can consider ambient temperature forecasts, cooling system efficiency data, or historical correlations between computing load and actual measured heat output. Heat generation predictor 225 can analyze patterns in how heat dissipation lags behind changes in computing load, allowing for more accurate predictions of thermal conditions at specific future times. For example, heat generation predictor 225 can account for thermal inertia in data center equipment 240, predicting how quickly components will heat up or cool down in response to anticipated changes in workload.

In some implementations, heat generation predictor 225 may use a thermal model that accounts for thermal time constants of various components of data center equipment 240, of liquid cooling system 220, and/or of air cooling system 230. For example, the thermal model may account for the thermal mass and time constants of the chip case, the cold plate, the thermal interface material (TIM), and the liquid coolant, which together may cause the temperature of a heat-generating component to lag behind a change in the power consumption of the component. By accounting for these thermal time constants, heat generation predictor 225 may predict not only the steady-state heat generation associated with a predicted future computing load but also the transient temperature response of data center equipment 240 to changes in computing load, allowing controller 126 to time or schedule cooling adjustments such that the cooling adjustment is made (e.g., cooling is increased or decreased) before the corresponding temperature change manifests at the heat-generating components.

By way of example, the thermal model may represent the thermal mass and time constants of various components using one or more lumped-capacitance thermal nodes connected by thermal resistances, with each thermal node corresponding to a physical component (e.g., the chip die, the chip case, the TIM, the cold plate, the liquid coolant within the cold plate, etc.) and each thermal resistance representing the conductive, convective, or interfacial heat transfer between adjacent nodes. Solving such a thermal network for a given input power profile yields a predicted temperature trajectory for each node, allowing controller 126 to estimate when and to what extent the temperature of a particular component will respond to a predicted change in computing load. Additionally or alternatively, the thermal model may be implemented as a transfer function or state-space model fit to historical input/output data (e.g., power consumption as input and component temperature as output) to capture the effective thermal time constants of the system without explicitly modeling each physical thermal node.

Heat generation predictor 225 can generate heat generation predictions at various levels of granularity within data center equipment 240. Heat generation predictor 225 can provide overall heat generation estimates for entire racks 102, more specific predictions for individual server trays 104, or predictions for components within a single tray (e.g., individual CPUs, GPUs, boards, etc.). In some implementations, heat generation predictor 225 can use machine learning algorithms trained on historical data to improve prediction accuracy over time (e.g., by retraining and/or fine-tuning the algorithms or models).

In some implementations, heat generation predictor 225 can predict the heat anticipated to be generated without computing load predictor 224 first predicting the computing load. For example, controller 126 can predict heat generation directly using historical heat generation, temperature sensor, and/or cooling information, alone or in combination with external information such as information about heat generation characteristics for different types of data center equipment 240. In some such embodiments, heat generation predictor 225 may predict the heat anticipated to be generated in a manner similar to that described above with respect to computing load predictor 224 (e.g., without correlating the cooling, temperature sensor, and/or heat generation information to predicted computing loads).

In some implementations, heat generation predictor 225 can predict the heat generation and/or computing load using power data for power distributed to the different data center equipment 240, such as information received from PDUs 176 that serve power to the equipment 240. In some embodiments, controller 126 (e.g., heat generation predictor 225) may obtain power consumption data for data center equipment 240 from any of various power data sources, alone or in combination. For example, controller 126 may obtain power consumption data from a data center infrastructure management (DCIM) system communicatively coupled to data center cooling system 100 (e.g., via an API, a database query, or a publish/subscribe interface exposed by the DCIM system), from one or more power distribution units (PDUs) 176 that supply power to racks 102, server trays 104, and/or individual heat-generating components, from one or more server power supplies (e.g., power supply units installed within individual servers and configured to report measured input or output power, voltage, and/or current via a management interface such as the Power Management Bus (PMBus), IPMI, Redfish, or another suitable interface), from one or more Hall effect sensors arranged to measure current draw of a power conductor that supplies power to data center equipment 240, from one or more shunt resistors arranged in series with a power conductor that supplies power to data center equipment 240 (e.g., where the voltage drop across the shunt resistor is measured and used to derive a corresponding current and power consumption), and/or from one or more plug load meters configured to measure the power drawn by equipment plugged into a particular outlet or circuit.

In some implementations, controller 126 may additionally or alternatively use model-based estimates of the power consumption of data center equipment 240. For example, controller 126 may implement a power consumption model (e.g., a regression model, an artificial intelligence (AI) model, a machine learning (ML) model, a physics-based model, or other model) configured to estimate the power consumed by a particular processor, server tray 104, rack 102, or other component based on operational signals indicative of the activity level of that component. Such operational signals may include, for example, processor utilization (e.g., CPU or GPU utilization percentages reported by the operating system or BIOS), DRAM activity (e.g., memory bandwidth utilization, read/write counts, etc.), fan power and/or fan speed (e.g., revolutions per minute (RPM)) of one or more cooling fans associated with the component (which can serve as a proxy for the heat dissipated by the component), inlet air temperature and outlet air temperature for the component (e.g., where the rise in air temperature across the component is indicative of the heat being added to the airflow by the component), measurements obtained from one or more of the power data sources described above (e.g., upstream PDU measurements, Hall sensor or shunt resistor readings, etc.), and/or any combination thereof. Controller 126 may use the model-based power consumption estimates in lieu of, or in conjunction with, directly measured power data from the power data sources described above, which may allow controller 126 to obtain power estimates at finer levels of granularity (e.g., for individual components within a server tray 104) than may be available from the directly measured power data alone.

In some implementations, controller 126 may calibrate the model-based power consumption estimates against directly measured power data when such measured data is available, and may apply the calibrated model to estimate the power consumption of similar components or operating regions for which directly measured power data is not available. For example, controller 126 may use direct power measurements from a PDU 176 serving a particular rack 102 to calibrate a model that estimates per-server-tray power consumption based on processor utilization, fan speed, and inlet/outlet air temperature data reported by the servers themselves, and may then apply that calibrated model to other racks 102 that lack tray-level power metering. In some implementations, controller 126 may continuously update or refine the model-based power consumption estimates as additional measured data becomes available, allowing the accuracy of the estimates to improve over time.

In some implementations, heat generation predictor 225 can predict the heat anticipated to be generated by data center equipment 240 over future times/timeframes using distributed power information from power distribution units (PDUs) 176. Heat generation predictor 225 can receive power consumption data from PDUs 176 for racks 102, server trays 104, and/or individual components (e.g., CPUs 242 or GPUs 244) within the data center equipment 240. Based on this power consumption data, heat generation predictor 225 can calculate the expected heat output for each component, as there is typically a direct correlation between power consumption and heat generation in electronic devices. Heat generation predictor 225 can apply specific conversion factors or thermal efficiency coefficients for different types of components to translate power consumption into predicted heat generation.

In some implementations, heat generation predictor 225 can analyze historical power consumption patterns from PDUs 176 to identify trends and cycles in heat generation. The heat generation predictor 225 can use time series analysis techniques or machine learning algorithms to detect recurring patterns in power usage, such as daily, weekly, or seasonal fluctuations. For example, heat generation predictor 225 can recognize that certain racks 102 or server trays 104 consistently draw more power during specific hours of the day or days of the week, indicating higher heat generation during those periods. Heat generation predictor 225 can incorporate these identified patterns into its predictive model to forecast future heat generation more accurately.

Thermal model generator 226 can generate a thermal model describing temporal and/or load condition-based heat generation characteristics of data center equipment 240. In some implementations, heat generation predictor 225 can use the generated thermal model to predict the future heat generation information. Thermal model generator 226 can generate a predictive thermal model for the heat-generating data center equipment 240 based on historical amounts of heat generated by the heat-generating data center equipment 240 over a historical time period and/or based on other data/factors using techniques similar to those described above with respect to heat generation predictor 225. Thermal model generator 226 can generate one or more thermal models at any level of granularity (e.g., a thermal model for a rack 102, for a server tray 104, for a CPU or GPU, etc.). In some embodiments, thermal model generator 226 generates multiple thermal models for various components of data center equipment 240. For example, thermal model generator 226 may generate a different thermal model for each of racks 102, server trays 104, CPUs 242, GPUs 244, and/or PDUs 176 in some embodiments.

Cooling system controller 227 can use the predicted heat generation information to generate control signals to control liquid cooling system 220 and/or air cooling system 230 to cool data center equipment 240. Cooling system controller 227 can operate one or more flow control devices of liquid cooling system 220 to adjust a flow rate and/or a pressure of the liquid coolant through rack 102 of the data center based on the predicted amount of heat.

In some implementations, cooling system controller 227 can operate one or more temperature control devices of the liquid cooling system 220 to adjust a temperature of the liquid coolant supplied to rack 102 of the data center based on the predicted amount of heat. Cooling system controller 227 can operate the one or more temperature control devices of the liquid cooling system 220 to supply the liquid coolant at a first temperature in response to the predicted amount of heat being below a first level, supply the liquid coolant at a second temperature lower than the first temperature in response to the predicted amount of heat being above the first level and below a second level, and supply the liquid coolant at a third temperature lower than the second temperature in response to the predicted amount of heat being above the second level.

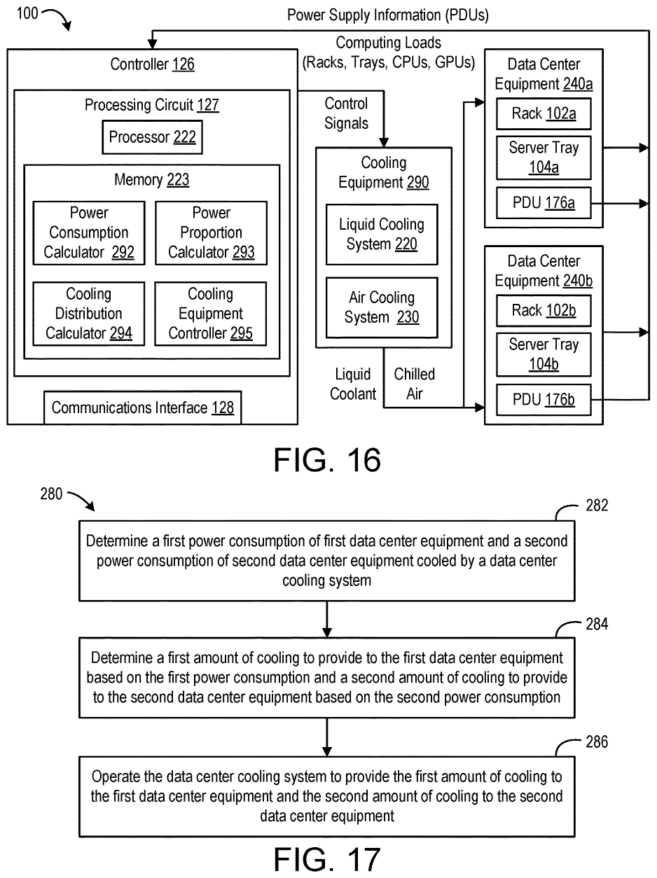

In some implementations, cooling system controller 227 may select the supply coolant temperature, the supply coolant flow rate, the supply coolant pressure, and/or other operating parameters of liquid cooling system 220 by solving an optimization problem that balances cooling capacity against energy consumption of cooling equipment 290 (e.g., liquid cooling system 220 and/or air cooling system 230, as shown in FIG. 16). For example, cooling system controller 227 may evaluate multiple candidate combinations of operating parameters using one or more equipment performance models (e.g., a chiller efficiency curve as a function of part-load ratio and condenser water temperature, a pump power curve as a function of flow rate, a fan power curve as a function of airflow, etc.) and may select the combination that satisfies the predicted cooling load with the lowest predicted total energy consumption. In some implementations, cooling system controller 227 may apply a model predictive control (MPC) formulation that optimizes operation of liquid cooling system 220 and/or air cooling system 230 over a future time horizon based on the predicted heat generation, allowing cooling system controller 227 to account for ramp-up/ramp-down dynamics, equipment startup costs, and constraints on equipment operating ranges.

Cooling system controller 227 can operate one or more flow control devices of the air cooling system 230 to adjust a flow rate and/or a pressure of the cooled air supplied to rack 102 of the data center based on the predicted amount of heat. In some implementations, cooling system controller 227 can operate one or more temperature control devices of the air cooling system 230 to adjust a temperature of the cooled air supplied to rack 102 of the data center based on the predicted amount of heat.

In some implementations, the liquid coolant supplied to rack 102 can be a secondary coolant and the liquid cooling system 220 can include a secondary coolant circuit configured to absorb heat generated by the heat-generating data center equipment 240 within rack 102 by circulating the secondary coolant through rack 102. The liquid cooling system 220 can include a primary coolant circuit configured to circulate a primary coolant through a heat exchanger to absorb heat from the secondary coolant within the heat exchanger. Cooling system controller 227 can operate both the primary coolant circuit and the secondary coolant circuit based on the predicted amount of heat.

In some implementations, rack 102 can include a plurality of compartments and the heat-generating data center equipment 240 can be distributed across the plurality of compartments. Controller 126 can predict compartment-specific amounts of heat that can be generated by the heat-generating data center equipment 240 within one or more compartments of the plurality of compartments at the future time. Controller 126 can operate at least one of the liquid cooling system 220 or the air cooling system 230 to independently modulate the amount cooling provided to the one or more compartments based on the predicted compartment-specific amounts of heat.

In some implementations, rack 102 can include a plurality of server trays 104 and the heat-generating data center equipment 240 can be installed on the plurality of server trays 104. Controller 126 can predict server tray-specific amounts of heat that can be generated by the heat-generating data center equipment 240 installed on one or more server trays 104 of the plurality of server trays 104 at the future time. Controller 126 can operate at least one of the liquid cooling system 220 or the air cooling system 230 to independently modulate the amount cooling provided to the one or more server trays 104 based on the predicted server tray-specific amounts of heat.

In some implementations, rack 102 can include a server tray 104 comprising a plurality of components of the heat-generating data center equipment 240 installed on the server tray 104. Controller 126 can predict component-specific amounts of heat that can be generated by one or more components of the plurality of components installed on server tray 104 at the future time. Controller 126 can operate at least one of the liquid cooling system 220 or the air cooling system 230 to independently modulate the amount cooling provided to the one or more components installed on server tray 104 based on the predicted component-specific amounts of heat.

In some implementations, controller 126 may use the predicted heat generation information together with workload-scheduling information to coordinate operation of liquid cooling system 220 and air cooling system 230 with the placement of computing workloads within the data center. For example, if heat generation predictor 225 predicts that a particular rack 102 or server tray 104 will experience a sustained high heat load over a future time horizon, controller 126 may communicate with a workload-scheduling system of the data center (e.g., via the DCIM system or another management interface) to redistribute incoming workloads to other racks 102 or server trays 104 having available cooling capacity. Conversely, if the predicted heat load for a particular rack 102 or server tray 104 is low, controller 126 may indicate that additional workloads can be assigned to that rack 102 or server tray 104 without exceeding its available cooling capacity. Such coordination between cooling control and workload scheduling may help balance heat loads across the data center, reducing the likelihood of localized thermal hotspots and helping to avoid throttling events.

Controller 126 can obtain feedback indicating a value of a controlled temperature affected by cooling the heat-generating data center equipment 240. Controller 126 can operate the liquid cooling system 220 and the air cooling system 230 to modulate the amount of cooling provided to the heat-generating data center equipment 240 based on both the predicted amount of heat and the feedback. In some implementations, the feedback can indicate the value of the controlled temperature affected by cooling the heat-generating data center equipment 240 relative to a reference temperature.

In some implementations, controller 126 may combine feedforward control based on the predicted amount of heat with feedback control based on the value of the controlled temperature. For example, controller 126 may use the predicted amount of heat to generate a feedforward control signal that pre-positions one or more flow control devices, temperature control devices, or other components of liquid cooling system 220 and/or air cooling system 230 to a state expected to satisfy the predicted cooling load, and may use the feedback indicating the value of the controlled temperature to apply a closed-loop correction (e.g., via a PID control loop, a model predictive control formulation, or another feedback control method) that compensates for any difference between the predicted and actual cooling requirements. This combination of feedforward and feedback control may allow controller 126 to respond rapidly to anticipated changes in heat generation while still maintaining accurate temperature control in the presence of model errors, unmodeled disturbances, or unexpected workload changes.

In some implementations, controller 126 (e.g., heat generation predictor 225) can obtain a weather forecast for the future time and predict the amount of heat that can be generated by the heat-generating data center equipment 240 at the future time based on the weather forecast. In some implementations, heat generation predictor 225 can predict the heat anticipated to be generated by data center equipment 240 over future times/timeframes using weather forecast data obtained from external sources. The heat generation predictor 225 can receive weather forecast data for the location of the data center, such as temperature, humidity, and/or atmospheric pressure predictions for various time intervals. Based on the weather forecast data, heat generation predictor 225 can estimate the impact of external environmental conditions on the cooling efficiency of liquid cooling system 220 and/or air cooling system 230. For example, heat generation predictor 225 can adjust predicted heat dissipation rates based on forecasted outdoor temperatures, as higher ambient temperatures may reduce the efficiency of heat exchange processes in the chillers or air cooler.

In some implementations, heat generation predictor 225 may use the weather forecast data to predict not only the impact of outdoor conditions on the cooling efficiency of liquid cooling system 220 and air cooling system 230 but also the impact of outdoor conditions on the heat load itself. For example, if air cooling system 230 includes one or more air-cooled components that draw outside air directly (e.g., free-cooling units or airside economizers), higher forecasted outdoor temperatures may increase the temperature of the air supplied to data center equipment 240 and thereby increase the cooling load on liquid cooling system 220. Similarly, higher forecasted outdoor humidity may affect the operating efficiency of evaporative cooling components (e.g., DEC or IEC units) of air cooling system 230. Heat generation predictor 225 may use the weather forecast data to estimate, for one or more future times, the available cooling capacity of each portion of cooling equipment 290 and may provide such estimates to cooling system controller 227 for use in selecting an appropriate combination of cooling equipment operating parameters.

In some implementations, heat generation predictor 225 can incorporate the weather forecast data into a multi-factor predictive model. The heat generation predictor 225 can combine the weather forecast data with historical power consumption patterns, scheduled workloads, and/or thermal characteristics of data center equipment 240 to generate more accurate heat generation predictions. For example, heat generation predictor 225 can predict higher heat generation on days with forecasted high temperatures, especially if those days coincide with periods of historically high computing loads. The heat generation predictor 225 can use machine learning algorithms to identify correlations between weather patterns and heat generation trends, in some implementations.

Controller 126 can obtain a seasonal demand for computing resources provided by the heat-generating data center equipment 240 and predict the amount of heat that can be generated by the heat-generating data center equipment 240 at the future time based on the seasonal demand. The heat generation predictor 225 can predict the heat anticipated to be generated by data center equipment 240 over future times/timeframes using seasonal demand data obtained from various sources. The heat generation predictor 225 can receive seasonal demand data for computing resources provided by the heat-generating data center equipment 240, such as historical usage patterns, scheduled workloads, or anticipated resource requirements for different seasons. Based on the seasonal demand data, heat generation predictor 225 can estimate the impact of seasonal variations on the computing load and corresponding heat generation of data center equipment 240. For example, heat generation predictor 225 can adjust predicted heat generation rates based on seasonal trends in resource utilization, as higher demand periods may lead to increased heat output from the heat-generating data center equipment 240.

In some implementations, heat generation predictor 225 can incorporate the seasonal demand data into a multi-factor predictive model. The heat generation predictor 225 can combine the seasonal demand data with other factors such as historical power consumption patterns, thermal characteristics of data center equipment 240, and/or expected changes in workload distribution to generate more accurate heat generation predictions. For example, heat generation predictor 225 can predict higher heat generation during seasons with historically high computing demands, especially if those seasons coincide with periods of increased resource-intensive tasks. The heat generation predictor 225 can use machine learning algorithms to identify correlations between seasonal patterns and heat generation trends, in some implementations.

Controller 126 can identify a planned workload change of heat-generating data center equipment 240 at the future time and predict the amount of heat that can be generated by heat-generating data center equipment 240 at the future time based on the planned workload change. Heat generation predictor 225 can predict the heat anticipated to be generated by data center equipment 240 over future times/timeframes using planned workload change data obtained from various sources. Heat generation predictor 225 can receive planned workload change data for heat-generating data center equipment 240, such as scheduled software updates, maintenance activities, or anticipated changes in resource allocation. Based on the planned workload change data, heat generation predictor 225 can estimate the impact of these changes on the computing load and corresponding heat generation of data center equipment 240. For example, heat generation predictor 225 can adjust predicted heat generation rates based on the expected intensity and duration of planned workloads, as more computationally intensive tasks may lead to increased heat output from heat-generating data center equipment 240.

In some implementations, the planned workload change data may be obtained from any of various sources within or external to the data center. For example, the planned workload change data may be obtained from a workload-scheduling system, a job-queue system, a maintenance management system, a configuration management system, a calendar of scheduled software updates or batch jobs, a customer-facing reservation system that allocates computing capacity to customers in advance, or another data source that provides advance notice of changes in computing activity. In some implementations, the planned workload change data may include, for each planned workload change, an identification of the affected racks 102, server trays 104, or components, a start time and duration of the planned change, and an expected magnitude of the resulting change in computing load (e.g., a percentage change in processor utilization, a number of additional virtual machines or containers to be deployed, etc.). Heat generation predictor 225 may use such structured planned workload change data to compute a corresponding predicted change in heat generation for the affected portions of data center equipment 240 over the relevant time period.

In some implementations, heat generation predictor 225 can incorporate the planned workload change data into a multi-factor predictive model. Heat generation predictor 225 can combine the planned workload change data with other factors such as historical power consumption patterns, thermal characteristics of data center equipment 240, and expected changes in resource utilization to generate more accurate heat generation predictions. For example, heat generation predictor 225 can predict higher heat generation during periods of planned software updates or batch processing jobs, especially if those periods coincide with times of historically high computing loads. Heat generation predictor 225 can use machine learning algorithms to identify correlations between planned workload changes and heat generation trends, allowing for more nuanced predictions that account for complex interactions between workload variations and data center thermal dynamics.

In some implementations, heat generation predictor 225 can use the planned workload change data to anticipate potential cooling system adjustments. Heat generation predictor 225 can analyze the planned workload patterns to predict when data center cooling system 100 may need to adjust cooling capacity or distribution. For example, if the planned workload change data indicates an upcoming period of increased computational intensity for specific racks 102 or server trays 104, heat generation predictor 225 can anticipate the need for increased cooling capacity in those areas, potentially requiring localized adjustments to liquid cooling system 220 or air cooling system 230. Heat generation predictor 225 can provide these predictions to cooling system controller 227, allowing for proactive adjustments to cooling strategies based on anticipated workload changes and their effects on heat generation within specific areas of the data center.

Referring now to FIG. 10, illustrated is a method 250 of predictive control for a data center cooling system. The method 250 can be executed, performed, or otherwise carried out by data center cooling system 100 (e.g., the embodiment of data center cooling system 100 shown in FIG. 9) described herein. In brief overview of the method 250, the method 250 can include generating a predictive thermal model (step 252), predicting future heat generation (step 254), and operating cooling systems based on predicted heat generation (step 256).

In some implementations, step 252 may involve thermal model generator 226 generating a predictive thermal model for heat-generating data center equipment 240 based on historical amounts of heat generated by heat-generating data center equipment 240 over a historical time period. Thermal model generator 226 can use various inputs to create the predictive thermal model, such as computing load information from computing load predictor 224, workload change data, power consumption data from power distribution units 176, weather forecasts, and seasonal demand information. The predictive thermal model can incorporate machine learning algorithms to identify patterns and correlations between various factors and heat generation trends.

In some embodiments, step 254 may involve heat generation predictor 225 using the predictive thermal model generated in step 252 to predict an amount of heat that can be generated by heat-generating data center equipment 240 at a future time. Heat generation predictor 225 can apply the predictive thermal model to current and forecasted conditions to estimate future heat output. For example, heat generation predictor 225 can use current computing load information, planned workload changes, forecasted weather conditions, and expected seasonal demand to predict heat generation for specific components, server trays 104, or entire racks 102 within data center equipment 240.

In various implementations, step 256 may involve cooling system controller 227 operating liquid cooling system 220 and/or air cooling system 230 to modulate an amount of cooling provided to heat-generating data center equipment 240 based on the predicted amount of heat from step 254. Cooling system controller 227 can adjust various parameters of liquid cooling system 220, such as flow rates, pressures, or temperatures of liquid coolant circulating through racks 102 and server trays 104. Cooling system controller 227 can also modify settings of air cooling system 230, such as fan speeds, damper positions, or air temperature setpoints to provide appropriate cooling based on the predicted heat generation.

In some embodiments, step 256 can involve cooling system controller 227 implementing different cooling strategies based on the predicted heat generation levels. For example, cooling system controller 227 can operate only air cooling system 230 and not liquid cooling system 220 to cool heat-generating data center equipment 240 at the future time in response to the predicted amount of heat being below a threshold value. Conversely, cooling system controller 227 can operate both air cooling system 230 and liquid cooling system 220 to cool heat-generating data center equipment 240 at the future time in response to the predicted amount of heat being above the threshold value.

In various implementations, step 256 can include cooling system controller 227 adjusting cooling parameters for individual components or sections of data center equipment 240 based on their specific predicted heat generation. For example, cooling system controller 227 can increase liquid coolant flow or decrease coolant temperature for a particular server tray 104 predicted to generate higher amounts of heat, while maintaining standard cooling levels for other server trays 104 within the same rack 102.

In various implementations, method 250 may include any of the steps, features, or functions described with respect to FIG. 9, and all such implementations are contemplated within the scope of the present disclosure.

### Flow Balancer Control

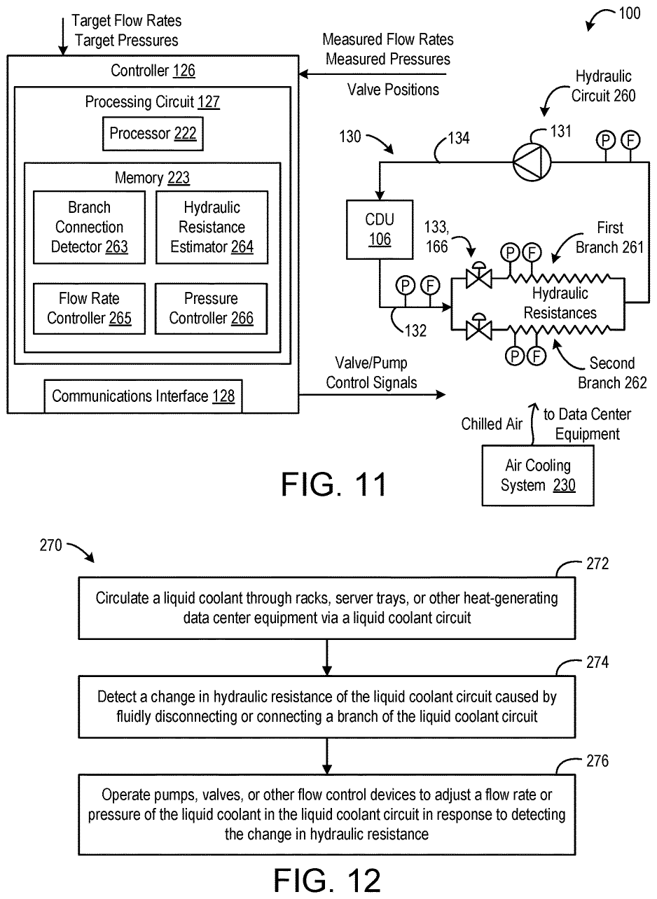

Referring now to FIG. 11, illustrated is another block diagram of data center cooling system 100 and associated control components, according to another exemplary embodiment. System 100 is shown to include many of the same components described previously. For example, system 100 is shown to include a controller 126 having a processing circuit 127 and a communications interface 128. Processing circuit 127 can contain a processor 222 and memory 223. It should be understood that, in various embodiments, processor 222 and memory 223 may include a single processor and/or a single memory or may include multiple processors and/or multiple memories (e.g., multiple local processors and/or memories, distributed or cloud computing devices, etc.).

Memory 223 can include a branch connection detector 263, a hydraulic resistance estimator 264, a flow rate controller 265, and a pressure controller 266. In various implementations, the components shown in memory 223 may be implemented using hardware, software, or a combination thereof. In some implementations, the components may be implemented using instructions stored on memory 223 and executable by processor 222 to implement the functions and steps described herein. These components of controller 126 may cooperate to model secondary coolant loop 130 as a hydraulic circuit 260 including multiple branches (e.g., branches 261 and 262). The branches can be selectively connected and disconnected by operating valves 133, which affects the hydraulic resistance of hydraulic circuit 260 as a whole. Controller 126 can compensate for changes in the hydraulic resistance caused by connecting or disconnecting various branches to ensure that the pressure and/or flow rate of the liquid coolant through racks 102, server trays 104, and/or other heat-generating data center equipment 240 is maintained at target levels regardless of which branches are connected or disconnected.

As shown in FIG. 11, controller 126 can be configured to model a portion of system 100 (e.g., secondary coolant loop 130) as a hydraulic circuit 260 having a first branch 261 and a second branch 262. A CDU 106 can be connected to the branches of hydraulic circuit 260 through secondary coolant loop 130, which can include a secondary coolant supply 132 and secondary coolant return 134. Secondary coolant loop 130 can include a pump 131 and valves 133 for controlling fluid flow. Pressure (P) and flow (F) sensors can be positioned at various points along hydraulic circuit 260 and branches.

Although first branch 261 and second branch 262 are illustrated in FIG. 11 as supplying liquid coolant to respective racks 102 (e.g., such that the branches are at a row level of the data center), it should be understood that hydraulic circuit 260 may include branches at any level or combination of levels of the hydraulic network of data center cooling system 100. For example, branches of hydraulic circuit 260 may be defined at a row level (e.g., where each branch supplies liquid coolant to a row of racks 102), at a rack level (e.g., where each branch supplies liquid coolant to an individual rack 102), at a server level (e.g., where each branch supplies liquid coolant to an individual server tray 104 within a rack 102), at a chip level (e.g., where each branch supplies liquid coolant to a cold plate 162 thermally coupled to an individual heat-generating component 164 such as a CPU 242 or GPU 244), and/or at any other level of the hydraulic network.

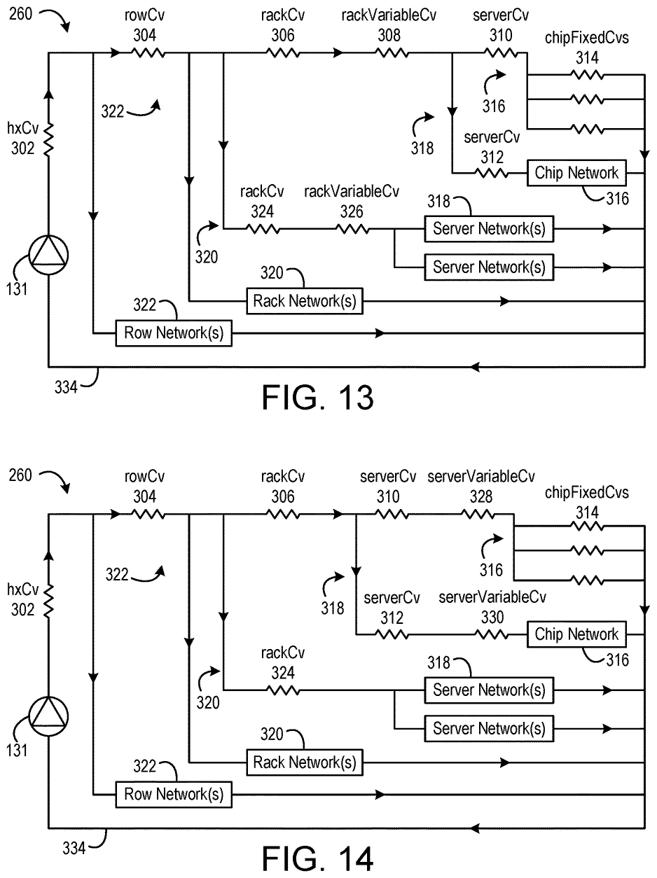

In various embodiments, hydraulic circuit 260 may include branches at multiple different levels of the hydraulic network simultaneously (e.g., a row-level branch that includes one or more nested rack-level branches, each of which includes one or more nested server-level branches, etc.). Examples of hydraulic circuit 260 with valve arrangements at the rack level, the server level, and the chip level are described in greater detail below with reference to FIGS. 13-15, respectively. The principles described herein with respect to first branch 261 and second branch 262 (e.g., detecting connection or disconnection of a branch, estimating the resulting change in hydraulic resistance of hydraulic circuit 260, and adjusting flow control devices to compensate for the change) may be applied analogously to branches at any of these levels of the hydraulic network.

Although first branch 261 and second branch 262 are illustrated in FIG. 11 as having a single rack 102 located along each branch, it should also be understood that any number of racks 102, server trays 104, cold plates 162, or other heat-generating data center equipment 240 may be located along a given branch of hydraulic circuit 260, in any series, parallel, and/or hierarchical arrangement. For example, a single branch may include multiple racks 102 arranged in series along the branch, multiple racks 102 arranged in parallel as nested sub-branches of the branch, or a combination of series and parallel arrangements. Similarly, a single rack 102 may include multiple server trays 104 arranged in series and/or in parallel along a coolant flow path within the rack 102, and a single server tray 104 may include multiple cold plates 162 arranged in series and/or in parallel along a coolant flow path within the server tray 104. Hydraulic resistance estimator 264 may use the parallel and series resistor relationships described in greater detail below to model such arrangements at any level or combination of levels within hydraulic circuit 260.

Referring now to FIGS. 13-15, schematic diagrams of hydraulic circuit 260 are shown, according to several example embodiments. Hydraulic circuit 260 is shown to include a hierarchical organization of the liquid coolant flow paths of data center cooling system 100, in which liquid coolant flows from one or more upstream sources (e.g., pump 131, etc.) through a heat exchanger (e.g., CDU 106), into one or more row networks 322, into one or more rack networks 320 within each row, into one or more server networks 318 within each rack, and ultimately into one or more chip networks 316 in which the liquid coolant absorbs heat from heat-generating components 164 (e.g., CPUs 242, GPUs 244, etc.), before returning toward the upstream sources via a corresponding return path 334.

Hydraulic circuit 260 may include a variety of components positioned along the flow paths to characterize and/or modulate the hydraulic resistance of hydraulic circuit 260. For example, hydraulic circuit 260 is shown to include a heat exchanger hydraulic resistance (denoted hxCv 302) representing the hydraulic resistance of one or more heat exchangers (e.g., within CDU 106) within hydraulic circuit 260. Row networks 322 are shown to include a row hydraulic resistance (denoted rowCv 304) representing the hydraulic resistance of a row-level segment of hydraulic circuit 260. Rack networks 320 are shown to include a rack-level hydraulic resistance (denoted rackCv 306 and rackCv 324) representing the hydraulic resistance of a rack-level segment of hydraulic circuit 260. Server networks 318 are shown to include a server-level hydraulic resistance (denoted serverCv 310 and serverCv 312) representing the hydraulic resistance of a server-level segment of hydraulic circuit 260. Chip networks 316 are shown to include one or more chip-level fixed-resistance elements (denoted chipFixedCvs 314) representing the substantially fixed hydraulic resistance of cold plates 162 or other components associated with particular heat-generating components 164.

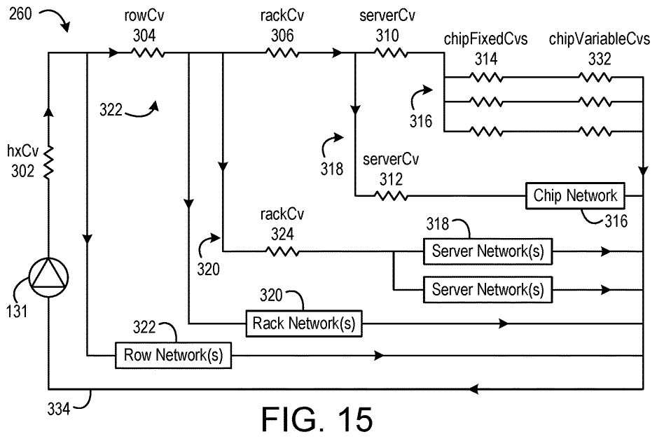

Hydraulic circuit 260 may further include one or more variable hydraulic resistance (denoted variable-Cv) flow control valves operable to modulate the hydraulic resistance of one or more portions of hydraulic circuit 260, and thereby to modulate the flow rate and/or pressure of the liquid coolant in those portions. The variable-Cv flow control valves may be implemented as, for example, valves 133 and/or valves 166 described above with reference to other figures, or as any other type of variable-position valve having a controllable flow coefficient (Cv). The location of the variable-Cv flow control valves within hydraulic circuit 260 determines the level of granularity at which controller 126 can independently modulate flow of the liquid coolant. As described in greater detail below, the variable-Cv flow control valves may be positioned at the rack level (FIG. 13), at the server level (FIG. 14), at the chip level (FIG. 15), at multiple levels simultaneously, and/or at any other level or combination of levels of hydraulic circuit 260.

Referring particularly to FIG. 13, hydraulic circuit 260 is shown to include one or more rack-level variable-Cv flow control valves (denoted rackVariableCv 308 and 326) positioned at the rack level of hydraulic circuit 260. Each rack-level variable-Cv valve 308, 326 may be arranged in series with one or more corresponding server networks 318 (e.g., upstream or downstream of the corresponding server network 318) such that the rack-level variable-Cv valve controls the flow rate and/or pressure of liquid coolant supplied to all of the server networks 318 and chip networks 316 arranged in series with the rack-level variable Cv valve. In the arrangement shown in FIG. 13, the server-level segment may include a fixed or non-controllable serverCv 310 or serverCv 312, and the chip-level segment 316 may include the chipFixedCvs 314, such that the rack-level variable-Cv valves 308 and 326 may serve as the primary point of flow modulation for liquid coolant supplied to that rack. Controller 126 may operate the rack-level variable-Cv valves 308 and 326 to independently modulate flow to different rack networks 320 within a given row network 322 based on, for example, the cooling needs of the heat-generating components 164 within each rack 102 (e.g., as determined from temperature feedback, power feedback, predicted heat generation, etc., as described above with respect to other embodiments).

Referring particularly to FIG. 14, hydraulic circuit 260 is shown to include one or more server-level variable-Cv flow control valves (denoted serverVariableCv 328 and 330) positioned at the server level of hydraulic circuit 260. Each server-level variable-Cv valve 328 or 330 may be arranged in series with a corresponding chip network 316 (e.g., upstream or downstream of the corresponding chip network 316) such that the server-level variable-Cv valve 328 or 330 controls the flow rate and/or pressure of liquid coolant supplied to all of the chips within the corresponding chip network 316. In the arrangement shown in FIG. 14, the rack-level segment and the chip-level segment may include fixed or non-controllable flow coefficient elements 306, 324, and 314, respectively, such that the server-level variable-Cv valves 328 and 330 may serve as the primary point of flow modulation for liquid coolant supplied to individual server trays 104 within a given rack 102. Controller 126 may operate the server-level variable-Cv valves 328 and 330 to independently modulate flow to different server networks 318 within a given rack network 320 based on the individual cooling needs of the server trays 104 within the rack, allowing controller 126 to provide more or less coolant to different server trays 104 within the same rack 102.

Referring particularly to FIG. 15, hydraulic circuit 260 is shown to include one or more chip-level variable-Cv flow control valves 332 (denoted chipVariableCv) positioned at the chip level of hydraulic circuit 260. Each chip-level variable-Cv valve 332 may be arranged in series with a corresponding chip or other heat-generating component 164 (e.g., upstream or downstream of the cold plate 162 associated with a particular heat-generating component 164) such that the valve 332 controls the flow rate and/or pressure of liquid coolant supplied to that particular cold plate 162. In the arrangement shown in FIG. 15, the rack-level segment and the server-level segment may include fixed or non-controllable flow coefficient elements 306, 324 and 310, 312, respectively, while the chip-level segment includes the chip-level variable-Cv valves 332 (e.g., in series with, or in place of, the chip-level fixed-Cv elements 314 of FIGS. 13 and 14). Controller 126 may operate the chip-level variable-Cv valves 332 to independently modulate flow to different individual heat-generating components 164 (e.g., individual CPUs 242, individual GPUs 244, etc.) within a given server tray 104, allowing controller 126 to provide highly granular, component-specific coolant flow control matched to the cooling needs of each heat-generating component 164.

It should be understood that the rack-level, server-level, and chip-level variable-Cv valve arrangements illustrated in FIGS. 13-15 are provided as non-limiting examples, and that variable-Cv flow control valves may be positioned at any other level of hydraulic circuit 260 (e.g., at the row level, at the heat exchanger level, etc.) and/or at multiple levels simultaneously (e.g., a combination of rack-level and chip-level variable-Cv valves) within the same data center cooling system 100. Where variable-Cv flow control valves are present at multiple levels of hydraulic circuit 260, controller 126 may operate the variable-Cv flow control valves at the different levels in coordination with one another to achieve a desired distribution of liquid coolant across the hydraulic network. Hydraulic resistance estimator 264 may model the hydraulic resistance of hydraulic circuit 260 using parallel and/or series resistor relationships as described above with reference to FIG. 11, with the variable-Cv flow control valves modeled as variable hydraulic resistances whose values depend on the current valve positions and the fixed-Cv elements modeled as fixed hydraulic resistances. The principles described above with reference to FIG. 11 (e.g., detecting connection or disconnection of branches of hydraulic circuit 260, estimating the resulting change in hydraulic resistance, and operating one or more flow control devices to compensate for the change) may be applied to any of the example arrangements illustrated in FIGS. 13-15 and to any other hierarchical or hybrid arrangement of variable-Cv flow control valves within hydraulic circuit 260.

In some implementations, controller 126 can receive target flow rates and/or target pressures as inputs. In some implementations, controller 126 can additionally or alternatively receive measured flow rates, measured pressures, and/or valve positions as feedback from hydraulic circuit 260. Controller 126 can output valve/pump control signals to regulate the operation of valves 133 and/or pump 131.

In some implementations, the target flow rates and/or target pressures used by controller 126 may be obtained from any of various sources, such as a fixed setpoint stored in memory 223, a setpoint received from a user via a user interface, a setpoint received from a building management system or DCIM system, a setpoint computed based on the cooling needs of the heat-generating data center equipment 240 (e.g., based on temperature feedback, power feedback, predicted heat generation, etc., as described above with respect to other embodiments), and/or a setpoint computed based on equipment specifications or hydraulic constraints (e.g., a minimum flow rate required to ensure adequate cooling of a particular cold plate 162, a maximum pressure permitted at the inlet of a particular component, etc.). Controller 126 may dynamically update the target flow rates and/or target pressures over time as the cooling needs of data center cooling system 100 change.

In some implementations, hydraulic circuit 260 can be configured to circulate a liquid coolant through one or more racks 102 of the data center to cool heat-generating data center equipment 240 within racks 102. Hydraulic circuit 260 can include one or more flow control devices operable to control a flow rate and/or a pressure of the liquid coolant in hydraulic circuit 260. For example, pump 131 can be operable to circulate the liquid coolant through racks 102. Valves 133 can be operable to modulate the flow rate or pressure of the liquid coolant circulating through racks 102.

Branch connection detector 263 can be configured to detect whether the branches of hydraulic circuit 260 are connected or disconnected from hydraulic circuit 260 as a whole. The branches can be conduits or paths of secondary coolant loop 130 which can be arranged in parallel with each other. Each branch of hydraulic circuit 260 can include a coolant flow path that can pass through or proximate to one or more of racks 102, server trays 104, and/or other heat-generating data center equipment 240.

In some implementations, branch connection detector 263 can determine the branch connection status of a given branch based on the position of one or more valves 133 or 166 located along the branch. For example, if valve 133 or 166 is open, the branch is connected, whereas if valve 133 or 166 is closed, the branch is disconnected. A branch can be fully connected, fully disconnected, or partially connected/disconnected based on the valve position (e.g., in some implementations, the valve may have a variable valve position that can be controlled to be at a position in between being fully open and fully closed, such that partial flow is allowed through the valve).

In some implementations, branch connection detector 263 may additionally or alternatively detect connection or disconnection of a branch based on signals from one or more sensors associated with quick-disconnect couplings or blind-mate fluid connectors that fluidly couple a rack 102, a server tray 104, or other heat-generating data center equipment 240 to hydraulic circuit 260, on a status signal from the rack 102 or server tray 104 indicating that it has been installed within or removed from the data center, on inventory or asset-management data received from a DCIM system or other management system communicatively coupled to data center cooling system 100, or on a change in the flow rate and/or pressure of the liquid coolant detected by one or more flow sensors and/or pressure sensors of hydraulic circuit 260. Branch connection detector 263 may combine multiple such signals to confirm the branch connection status and may distinguish between an intentional disconnection (e.g., for maintenance or replacement) and an unintentional disconnection (e.g., a leak or coupling failure), in some embodiments.

Hydraulic resistance estimator 264 can be configured to estimate the total hydraulic resistance of hydraulic circuit 260 based on which of the branches are connected and disconnected, as determined by branch connection detector 263. Hydraulic resistance estimator 264 can be configured to generate and/or use a hydraulic circuit model of hydraulic circuit 260 which can model each branch as a hydraulic resistance and the various branches as combinations of parallel and/or series hydraulic resistances. Hydraulic resistance estimator 264 can use parallel and/or series resistor equations to estimate or calculate the total or combined hydraulic resistance of the set of hydraulic resistances. For example, for two or more branches arranged fluidly in parallel between common upstream and downstream nodes (e.g., between secondary coolant supply 132 and secondary coolant return 134), hydraulic resistance estimator 264 can compute the combined hydraulic resistance Rₚₐᵣₐₗₗₑₗ of the parallel branches according to a parallel-resistor relationship, such as 1/Rₚₐᵣₐₗₗₑₗ=1/R₁+1/R₂+ . . . +1/Rₙ, where R₁, R₂, . . . , Rₙ are the hydraulic resistances of the individual branches that are currently fluidly connected to hydraulic circuit 260 (with disconnected branches treated as having effectively infinite hydraulic resistance and therefore omitted from the parallel sum).

As another example, for two or more hydraulic elements arranged fluidly in series along a common flow path (e.g., a coolant supply line, a valve, a cold plate, and a coolant return line arranged in series along a single branch), hydraulic resistance estimator 264 can compute the combined hydraulic resistance Rₛₑᵣᵢₑₛ of the series elements according to a series-resistor relationship, such as Rₛₑᵣᵢₑₛ=R₁+R₂+ . . . +Rₙ, where R₁, R₂, . . . , Rₙ are the hydraulic resistances of the individual series elements. Hydraulic resistance estimator 264 can identify the various elements of hydraulic circuit 260 that cause hydraulic resistance (e.g., pipes, valves, racks 102, server trays 104, cold plates 162, etc.) and identify which elements are arranged in series and/or in parallel with each other. Hydraulic resistance estimator 264 may apply the corresponding hydraulic resistance equations to calculate the parallel and series hydraulic resistances at various levels of hydraulic circuit 260.

In some embodiments, hydraulic resistance estimator 264 can apply these parallel and series relationships recursively at multiple levels of the hydraulic network of data center cooling system 100 (e.g., to combine series resistances within a given branch, then to combine the resulting branch resistances in parallel at a manifold, then to combine that combined resistance in series with upstream supply piping, and so on) to estimate the total hydraulic resistance of hydraulic circuit 260 as seen by pump 131 or another flow control device. The individual hydraulic resistances R₁, R₂, . . . , Rₙ used in these calculations may be based on, for example, manufacturer-supplied flow coefficients (e.g., Cᵥ values) for valves, cold plates, and other components, empirically determined pressure-drop versus flow-rate characteristics, current valve positions (e.g., as reported by valve-position feedback signals), and/or values stored in a configuration database accessible to controller 126.

In some implementations, hydraulic resistance estimator 264 may additionally or alternatively use a calibrated, data-driven model (e.g., a regression model, an artificial intelligence (AI) model, or a machine learning (ML) model) trained on historical operating data to estimate the hydraulic resistance of one or more elements of hydraulic circuit 260. For example, hydraulic resistance estimator 264 may train such a model on historical pump speeds, valve positions, measured flow rates, and measured pressures collected during operation of data center cooling system 100, and may use the trained model to estimate the hydraulic resistance of one or more elements as a function of one or more measured operating variables. The data-driven model may capture nonlinear effects, manufacturing tolerances, fouling-related changes in resistance, and other effects that may not be fully captured by manufacturer-supplied Cv values or static configuration data, allowing the estimated hydraulic resistance to remain accurate as the operating conditions of data center cooling system 100 change over time.

Flow rate controller 265 can be configured to control the flow rate of the liquid coolant through various portions or branches of hydraulic circuit 260 by operating flow control devices such as pump 131 and valves 133 and 166. In some implementations, flow rate controller 265 can be configured to modulate the flow control devices to achieve a target flow rate at a predetermined location within hydraulic circuit 260 regardless of which branches are connected or disconnected. Flow rate controller 265 can compensate for changes in hydraulic resistance caused by some branches being connected or disconnected to ensure the flow rate remains stable, constant, and/or at a setpoint flow rate.

Flow rate controller 265 can operate based on the hydraulic resistance estimated by hydraulic resistance estimator 264 and/or the branch connection statuses detected by branch connection detector 263. For example, in response to a branch becoming disconnected and/or the hydraulic resistance increasing, flow rate controller 265 can operate the flow control devices to open valves 133 or 166 more or operate pump 131 to achieve a higher pressure for the liquid coolant to ensure that the increase in hydraulic resistance does not cause the flow rate to decrease below a target or threshold. Conversely, in response to a branch becoming connected and/or the hydraulic resistance decreasing, flow rate controller 265 can operate the flow control devices to close valves 133 or 166 more or operate pump 131 to achieve a lower pressure for the liquid coolant to ensure that the decrease in hydraulic resistance does not cause the flow rate to increase above a target or threshold. Advantageously, flow rate controller 265 can compensate for changes in hydraulic resistance that would otherwise affect the flow rate.

Pressure controller 266 can be configured to control the pressure of the liquid coolant at various locations or branches of hydraulic circuit 260 by operating pressure control devices such as pump 131 and valves 133 and 166. In some implementations, pressure controller 266 can be configured to modulate the pressure control devices to achieve a target pressure at a predetermined location within hydraulic circuit 260 regardless of which branches are connected or disconnected. Pressure controller 266 can compensate for changes in hydraulic resistance caused by some branches being connected or disconnected to provide that the pressure remains stable, constant, or at a setpoint pressure.

Pressure controller 266 can operate based on the hydraulic resistance estimated by hydraulic resistance estimator 264 and/or the branch connection statuses detected by branch connection detector 263. For example, in response to a branch becoming disconnected and/or the hydraulic resistance increasing, pressure controller 266 can operate the pressure control devices to open valves 133 or 166 more (e.g., to reduce the hydraulic resistance caused by valves 133 and 166) or operate pump 131 at a lower setpoint or pump speed to ensure that the increase in hydraulic resistance does not cause the pressure to increase below a target or threshold. Conversely, in response to a branch becoming connected and/or the hydraulic resistance decreasing, pressure controller 266 can operate the pressure control devices to close valves 133 or 166 more (e.g., to increase the hydraulic resistance caused by valves 133 and 166) or operate pump 131 at a higher setpoint or pump speed to ensure that the decrease in hydraulic resistance does not cause the pressure to decrease below a target or threshold. Advantageously, pressure controller 266 can compensate for changes in hydraulic resistance that would otherwise affect the pressure.

In some implementations, controller 126 can be configured to operate the flow control devices to adjust the flow rate and/or the pressure of the liquid coolant in hydraulic circuit 260 in response to a change in a hydraulic resistance of hydraulic circuit 260 caused by fluidly disconnecting first branch 261 from hydraulic circuit 260 or fluidly connecting first branch 261 to hydraulic circuit 260. The controller 126 can detect the change in the hydraulic resistance of hydraulic circuit 260 in response to a change in position of one or more disconnect valves 133 operable to fluidly disconnect first branch 261 from hydraulic circuit 260.

Controller 126 can detect the change in the hydraulic resistance of hydraulic circuit 260 based on feedback indicating a change in the flow rate and/or the pressure of the liquid coolant in hydraulic circuit 260. For example, system 100 can include one or more first flow sensors or pressure sensors located along first branch 261 of hydraulic circuit 260. The feedback indicating the change in the flow rate and/or the pressure of the liquid coolant can be provided by the one or more first flow sensors or pressure sensors located along first branch 261 of hydraulic circuit 260.

In some implementations, system 100 can include one or more second flow sensors or pressure sensors located along second branch 262 of hydraulic circuit 260. The feedback indicating the change in the flow rate and/or the pressure of the liquid coolant can be provided by the one or more second flow sensors or pressure sensors located along second branch 262 of hydraulic circuit 260. System 100 can include one or more third flow sensors or pressure sensors located along a coolant supply line that can supply the liquid coolant to both first branch 261 and second branch 262. The feedback indicating the change in the flow rate and/or the pressure of the liquid coolant can be provided by the one or more third flow sensors or pressure sensors located along the coolant supply line.

The first heat-generating data center equipment can include a first rack 102 of the data center located along first branch 261. The second heat-generating data center equipment can include a second rack 102 of the data center located along second branch 262. The change in the hydraulic resistance of hydraulic circuit 260 can be caused by fluidly disconnecting first rack 102 from hydraulic circuit 260 or fluidly connecting first rack 102 to hydraulic circuit 260.

In some implementations, the first heat-generating data center equipment can include a first server tray 104 located within a rack 102 of the data center. The second heat-generating data center equipment can include a second server tray 104 located within rack 102 of the data center. The change in the hydraulic resistance of hydraulic circuit 260 can be caused by fluidly disconnecting first server tray 104 from rack 102 or fluidly connecting first server tray 104 to rack 102.

In some implementations, the first heat-generating data center equipment can include a first component located within a server tray 104 of the data center. The second heat-generating data center equipment can include a second component located within the same server tray 104 or a different server tray 104 of the data center. The change in the hydraulic resistance of hydraulic circuit 260 can be caused by fluidly disconnecting the first component from hydraulic circuit 260 or fluidly connecting the first component to hydraulic circuit 260. For example, the components may include processors, graphics processing units, memory modules, or other heat-generating electronic devices within server trays 104.

The system 100 can include one or more disconnect valves 133 operable to fluidly disconnect first branch 261 from hydraulic circuit 260 without fluidly disconnecting second branch 262 from hydraulic circuit 260. The change in the hydraulic resistance of hydraulic circuit 260 can be caused by operating the one or more disconnect valves to fluidly disconnect first branch 261 from hydraulic circuit 260.

In some implementations, operating the one or more flow control devices can include adjusting the flow rate and/or the pressure of the liquid coolant in hydraulic circuit 260 to achieve a target flow rate and/or target pressure for the liquid coolant in hydraulic circuit 260. The one or more flow control devices can include one or more valves operable to affect the hydraulic resistance of hydraulic circuit 260. Operating the one or more flow control devices can include operating the one or more valves to compensate for the change in the hydraulic resistance caused by fluidly disconnecting first branch 261 from hydraulic circuit 260 or fluidly connecting first branch 261 to hydraulic circuit 260.

The one or more flow control devices can include one or more valves operable to affect the flow rate and/or the pressure of the liquid coolant hydraulic circuit 260. Operating the one or more flow control devices can include operating the one or more valves to achieve a target for the flow rate and/or the pressure of the liquid coolant hydraulic circuit 260. The one or more flow control devices can include one or more pumps operable to affect the flow rate and/or the pressure of the liquid coolant hydraulic circuit 260. Operating the one or more flow control devices can include operating the one or more pumps to achieve a target for the flow rate and/or the pressure of the liquid coolant hydraulic circuit 260.

In some implementations, operating the one or more flow control devices can include setting a pump speed of the one or more pumps to a minimum pump speed required to achieve a target for the flow rate and/or the pressure of the liquid coolant hydraulic circuit 260 after the change in the hydraulic resistance. First branch 261 and second branch 262 of hydraulic circuit 260 can be arranged fluidly in parallel with each other such that disconnecting first branch 261 from hydraulic circuit 260 can affect the hydraulic resistance of hydraulic circuit 260 while allowing the liquid coolant to flow through second branch 262.

The change in the hydraulic resistance of hydraulic circuit 260 can be an increase in the hydraulic resistance caused by fluidly disconnecting first branch 261, the increase in the hydraulic resistance causing a decrease in the flow rate of the liquid coolant in hydraulic circuit 260. The controller 126 can be configured to operate the one or more flow control devices to increase the flow rate of the liquid coolant in hydraulic circuit 260 to compensate for the decrease in the flow rate caused by the increase in the hydraulic resistance.

In some implementations, the change in the hydraulic resistance of hydraulic circuit 260 can be a decrease in the hydraulic resistance caused by fluidly connecting first branch 261, the decrease in the hydraulic resistance causing an increase in the flow rate of the liquid coolant in hydraulic circuit 260. The controller 126 can be configured to operate the one or more flow control devices to decrease the flow rate of the liquid coolant in hydraulic circuit 260 to compensate for the increase in the flow rate caused by the decrease in the hydraulic resistance.

System 100 can include one or more temperature control devices operable to control a temperature of the liquid coolant in hydraulic circuit 260. The controller 126 can be configured to operate the one or more temperature control devices to adjust the temperature of the liquid coolant in hydraulic circuit 260 in response to detecting the change in the hydraulic resistance of hydraulic circuit 260. For example, if the hydraulic resistance increases, controller 126 can be configured to decrease the temperature of the liquid coolant in hydraulic circuit 260 to compensate for a decreased flow rate of the coolant that may result from the increased hydraulic resistance to ensure that the same amount of cooling is provided. Conversely, if the hydraulic resistance decreases, controller 126 can be configured to increase the temperature of the liquid coolant in hydraulic circuit 260 to compensate for an increased flow rate of the coolant that may result from the decreased hydraulic resistance to ensure that the same amount of cooling is provided.

In some implementations, controller 126 may use the estimated total hydraulic resistance of hydraulic circuit 260 to operate one or more flow control devices in a feedforward manner, in addition to or in lieu of relying solely on feedback from flow sensors or pressure sensors. For example, in response to detecting a change in branch connection status, controller 126 may compute an updated estimate of the total hydraulic resistance of hydraulic circuit 260 and may pre-position one or more flow control devices (e.g., set a pump speed or valve position to a value calculated to achieve a target flow rate or target pressure given the updated hydraulic resistance) in advance of any measurable change in the flow rate or pressure of the liquid coolant. Controller 126 may then apply closed-loop feedback control based on measurements from the flow sensors and/or pressure sensors to refine the operation of the one or more flow control devices and compensate for any difference between the estimated and actual hydraulic resistance.

Referring now to FIG. 12, illustrated is a method 270 of controlling a data center cooling system. The method 270 can be executed, performed, or otherwise carried out by data center cooling system 100 described herein (e.g., the embodiment of data center cooling system 100 illustrated in FIG. 11). In brief overview of the method 270, the method 270 can include circulating a liquid coolant through one or more racks, one or more server trays, and/or one or more other heat-generating data center equipment via a liquid coolant circuit (step 272), detecting a change in hydraulic resistance of the liquid coolant circuit caused by fluidly disconnecting or connecting a branch of the liquid coolant circuit (step 274), and operating one or more pumps, one or more valves, or one or more other flow control devices to adjust a flow rate and/or a pressure of the liquid coolant in the liquid coolant circuit in response to detecting the change in hydraulic resistance (step 276).

In some implementations, step 272 may involve circulating the liquid coolant through hydraulic circuit 260 using pump 131. The controller 126 can operate pump 131 to circulate the liquid coolant through secondary coolant loop 130, which can include secondary coolant supply 132 and secondary coolant return 134. The controller 126 can also operate valves 133 to control the flow of liquid coolant to individual branches of hydraulic circuit 260, such as first branch 261 and second branch 262.

In various embodiments, step 274 may involve branch connection detector 263 detecting a change in the connection status of first branch 261 or second branch 262. The branch connection detector 263 can determine the connection status based on the position of one or more valves 133 located along the respective branch. For example, if valve 133 is open, the branch can be considered connected, whereas if valve 133 is closed, the branch can be considered disconnected. The branch connection detector 263 can provide the connection status information to hydraulic resistance estimator 264.

In some implementations, step 274 may involve hydraulic resistance estimator 264 estimating the total hydraulic resistance of hydraulic circuit 260 based on the connection status of first branch 261 and second branch 262. The hydraulic resistance estimator 264 can use a hydraulic circuit model that represents the various branches and elements of hydraulic circuit 260 as combinations of parallel and/or series hydraulic resistances. The hydraulic resistance estimator 264 can apply parallel and/or series resistor equations (e.g., the parallel-resistor and series-resistor relationships described above with reference to FIG. 11) to calculate the overall hydraulic resistance of the connected branches.

In various embodiments, step 274 may involve controller 126 detecting the change in hydraulic resistance based on feedback from flow sensors or pressure sensors located along hydraulic circuit 260. For example, controller 126 can receive feedback from sensors located along first branch 261, second branch 262, or a common coolant supply line. The controller 126 can compare the received feedback to previous measurements or expected values to detect changes in flow rate or pressure indicative of a change in hydraulic resistance.

In some implementations, step 276 may involve flow rate controller 265 adjusting the operation of pump 131 and/or valves 133 to maintain a target flow rate at a predetermined location within hydraulic circuit 260. The flow rate controller 265 can compensate for the detected change in hydraulic resistance by increasing or decreasing the pump speed or adjusting valve positions to achieve the target flow rate. For example, if disconnecting first branch 261 causes an increase in hydraulic resistance and a corresponding decrease in flow rate, flow rate controller 265 can increase the speed of pump 131 to compensate.

In various embodiments, step 276 may involve pressure controller 266 adjusting the operation of pump 131 and/or valves 133 to maintain a target pressure at a predetermined location within hydraulic circuit 260. The pressure controller 266 can compensate for the detected change in hydraulic resistance by modifying pump speed or valve positions to achieve the target pressure. For example, if connecting first branch 261 causes a decrease in hydraulic resistance and a corresponding increase in flow rate, pressure controller 266 can decrease the speed of pump 131 or adjust valve positions to maintain the target pressure.

In some implementations, step 276 may involve controller 126 operating one or more temperature control devices to adjust the temperature of the liquid coolant in hydraulic circuit 260 in response to detecting the change in hydraulic resistance. The controller 126 can modify the operation of chillers or other cooling equipment to compensate for changes in heat transfer characteristics resulting from the altered flow distribution in hydraulic circuit 260.

In various implementations, method 270 may include any of the steps, features, or functions described with respect to FIG. 11, and all such implementations are contemplated within the scope of the present disclosure.

### Cooling Matched to Power Consumption

Referring now to FIG. 16, illustrated is a block diagram of data center cooling system 100 according to another example implementation. System 100 is shown to include many of the same components as previously described such as a controller 126 having a processing circuit 127 and a communications interface 128. Processing circuit 127 can contain a processor 222 and memory 223. It should be understood that, in various embodiments, processor 222 and memory 223 may include a single processor and/or a single memory or may include multiple processors and/or multiple memories (e.g., multiple local processors and/or memories, distributed or cloud computing devices, etc.).

In FIG. 16, memory 223 is shown to include a power consumption calculator 292, power proportion calculator 293, cooling distribution calculator 294, and cooling equipment controller 295. In various implementations, the components shown in memory 223 may be implemented using hardware, software, or a combination thereof. In some implementations, the components may be implemented using instructions stored on memory 223 and executable by processor 222 to implement the functions and steps described herein. These components of controller 126 may cooperate to allocate cooling to the heat-generating components of data center equipment 240 based on their respective power consumptions.

System 100 can include some or all of the same cooling architecture as previously described such as cooling equipment 290 including a liquid cooling system 220 and an air cooling system 230. Cooling equipment 290 can provide liquid coolant and chilled air to data center equipment 240a and 240b. Data center equipment 240a can include a rack 102a, server tray 104a, and power distribution unit (PDU) 176a. Similarly, data center equipment 240b can include a rack 102b, server tray 104b, and PDU 176b. Although only two groups of data center equipment 240a and 240b are shown in FIG. 16, it is contemplated that any number or type of data center equipment 240 can be included in various embodiments.

PDUs 176a and 176b can receive power from a utility or on-site power generation source. PDUs 176a and 176b can distribute power to components of data center equipment 240a and 240b, respectively, based on power consumption requirements of the components of data center equipment 240a and 240b. For example, PDU 176a can supply power to rack 102a and server tray 104a, while PDU 176b can supply power to rack 102b and server tray 104b.

Controller 126 can be configured to independently control a first amount of cooling provided to first heat-generating data center equipment 240a within the data center and a second amount of cooling provided to second heat-generating data center equipment 240b within the data center. Controller 126 can determine a first power consumption of the first heat-generating data center equipment 240a and a second power consumption of the second heat-generating data center equipment 240b. Controller 126 can operate cooling equipment 290 to adjust the first amount of cooling based on the first power consumption and adjust the second amount of cooling based on the second power consumption. In some implementations, controller 126 adjusts the amounts of cooling provided to data center equipment 240a and 240b such that each unit system, device, or component of data center equipment 240 receives an amount of cooling proportional to its power consumption.

In some implementations, power consumption calculator 292 can determine the power consumption of each system, component, or device of data center equipment 240a and 240b. Power consumption calculator 292 can calculate the total power consumption of all data center equipment 240 served by data center cooling system 100 as well as the individual power consumption of each system, component, or device of data center equipment 240a and 240b. Power consumption calculator 292 can determine the first power consumption and the second power consumption based on power supply information provided by PDUs 176a and 176b of the data center equipment 240a and 240b. For example, PDU 176a can report the amount of power supplied to rack 102a or server tray 104a, while PDU 176b can report the amount of power supplied to rack 102b or server tray 104b.

More generally, power consumption calculator 292 may obtain power consumption data for data center equipment 240a and 240b from any of various power data sources, alone or in combination, in a manner similar to that described above with reference to FIG. 9. For example, power consumption calculator 292 may obtain power consumption data from a data center infrastructure management (DCIM) system communicatively coupled to data center cooling system 100 (e.g., via an API, a database query, or a publish/subscribe interface exposed by the DCIM system), from PDUs 176a and 176b that supply power to data center equipment 240a and 240b, from one or more server power supplies (e.g., power supply units installed within individual servers and configured to report measured input or output power, voltage, and/or current via a management interface such as the Power Management Bus (PMBus), the Intelligent Platform Management Interface (IPMI), Redfish, or another suitable interface), from one or more Hall effect sensors arranged to measure current draw of a power conductor that supplies power to data center equipment 240a and 240b, from one or more shunt resistors arranged in series with a power conductor that supplies power to data center equipment 240a and 240b (e.g., where the voltage drop across the shunt resistor is measured and used to derive a corresponding current and power consumption), and/or from one or more plug load meters configured to measure the power drawn by equipment plugged into a particular outlet or circuit.

In some implementations, power consumption calculator 292 may additionally or alternatively use model-based estimates of the power consumption of data center equipment 240a and 240b. For example, power consumption calculator 292 may implement a power consumption model (e.g., a regression model, an artificial intelligence (AI) model, a machine learning (ML) model, a physics-based model, or other model) configured to estimate the power consumed by a particular processor, server tray 104, rack 102, or other component based on operational signals indicative of the activity level of that component. Such operational signals may include, for example, processor utilization (e.g., CPU or GPU utilization percentages reported by the operating system or BIOS), DRAM activity (e.g., memory bandwidth utilization, read/write counts, etc.), fan power and/or fan speed (e.g., revolutions per minute (RPM)) of one or more cooling fans associated with the component, inlet air temperature and outlet air temperature for the component (e.g., where the rise in air temperature across the component is indicative of the heat being added to the airflow by the component), measurements obtained from one or more of the power data sources described above, and/or any combination thereof. Power consumption calculator 292 may use the model-based power consumption estimates in lieu of, or in conjunction with, directly measured power data, which may allow controller 126 to allocate cooling at finer levels of granularity (e.g., for individual components within a server tray 104) than may be available from the directly measured power data alone. Power consumption calculator 292 may also calibrate the model-based estimates against directly measured power data when such measured data is available, and may apply the calibrated model to other equipment for which directly measured power data is not available.

Power proportion calculator 293 can determine the proportion of the power consumption of each system, component, or device of data center equipment 240a and 240b to the total power consumption of all data center equipment 240 served by cooling system 100. Power proportion calculator 293 can operate using the power consumption values calculated by power consumption calculator 292. The power consumption proportion for each system, component, or device of data center equipment 240a and 240b can indicate the ratio or percentage of the total power consumption attributable to that particular system, component, or device. For example, if the total power consumption of all data center equipment 240 served by cooling system 100 is 100kW and the power consumption of a given rack 102 is 10kW, power proportion calculator 293 may calculate the proportion as 10 kW/100 kW =0.1 or 10%. Similar calculations can be made for other racks 102, server trays 104, or other data center equipment 240.

Cooling distribution calculator 294 can determine the amount of cooling to provide to each system, component, or device of data center equipment 240a and 240b based on the power consumption values determined by power consumption calculator 292 and/or the power consumption proportions determined by power proportion calculator 293. In some implementations, cooling distribution calculator 294 can allocate cooling to each system, component, or device of data center equipment 240a and 240b proportional to its power consumption. Cooling distribution calculator 294 can determine a total amount of cooling to be provided by cooling system 100. Cooling distribution calculator 294 can adjust the first amount of cooling such that a proportion of the first amount of cooling to the total amount of cooling can be equal to the first proportion. Cooling distribution calculator 294 can adjust the second amount of cooling such that a proportion of the second amount of cooling to the total amount of cooling can be equal to the second proportion.

In some implementations, cooling distribution calculator 294 may apply scaling factors or weighting factors when allocating cooling proportional to power consumption to account for differences between data center equipment 240a and 240b that affect the conversion of power consumption to required cooling. For example, cooling distribution calculator 294 may apply a higher cooling-per-watt scaling factor to a piece of data center equipment 240 having a relatively lower maximum permissible temperature or a relatively narrower thermal margin, and a lower cooling-per-watt scaling factor to a piece of data center equipment 240 having a relatively higher maximum permissible temperature or a relatively wider thermal margin. Cooling distribution calculator 294 may also apply scaling factors based on equipment type (e.g., a different scaling factor for an AI rack 102a than for a CPU rack 102b), based on the location of the equipment within the data center (e.g., to account for the different ambient air temperatures or different airflow patterns at different locations), and/or based on other factors that affect the cooling-per-watt requirement of a particular piece of data center equipment 240. In some implementations, cooling distribution calculator 294 may also enforce minimum and/or maximum cooling allocations for each piece of data center equipment 240, such that no piece of data center equipment 240 receives less than a minimum amount of cooling necessary to maintain its temperature within a safe range or more than a maximum amount of cooling that the corresponding portion of cooling equipment 290 can deliver.

Cooling equipment controller 295 can operate cooling equipment 290 of data center cooling system 100 to adjust the amounts of cooling provided to each system, component, or device of data center equipment 240. In some implementations, cooling equipment controller 295 operates cooling equipment 290 to achieve the amounts of cooling determined by cooling distribution calculator 294. Cooling equipment controller 295 can operate individual components of cooling equipment 290 to independently control the amount of cooling provided to each system, component, or device of data center equipment 240a and 240b individually. The amount of cooling can be controlled by adjusting the flow rates and/or temperatures of the liquid coolant and/or chilled air supplied to each system, component, or device of data center equipment 240a and 240b independently.

In some implementations, cooling equipment 290 can include liquid cooling system 220 configured to supply a liquid coolant to first heat-generating data center equipment 240a and second heat-generating data center equipment 240b. Controller 126 can operate liquid cooling system 220 to adjust a first flow rate of the liquid coolant supplied to first heat-generating data center equipment 240a based on the first power consumption. Controller 126 can operate liquid cooling system 220 to adjust a second flow rate of the liquid coolant supplied to second heat-generating data center equipment 240b based on the second power consumption.

In some implementations, controller 126 may use the power consumption data as a feedforward signal that pre-positions cooling equipment 290 to satisfy the cooling load implied by the current or anticipated power consumption, in advance of the corresponding temperature change manifesting at the heat-generating data center equipment. For example, where the power consumption data is obtained from one or more Hall effect sensors arranged to measure current draw of data center equipment 240a and/or 240b, controller 126 may detect a change in the power consumption of the heat-generating data center equipment in advance of the temperature sensors detecting a corresponding change in temperature, because changes in power consumption can be observed by a Hall sensor before corresponding changes in temperature propagate through the thermal mass and time constants of the chip case, the cold plate, the thermal interface material (TIM), and the liquid coolant. In response, controller 126 may proactively adjust the first amount of cooling and/or the second amount of cooling (e.g., by increasing the flow rate or decreasing the temperature of the liquid coolant supplied to the affected portion of data center equipment 240) before the temperature of the affected portion of data center equipment 240 begins to rise.

In some implementations, cooling equipment 290 can include air cooling system 230 configured to supply chilled air to first heat-generating data center equipment 240a and second heat-generating data center equipment 240b. Controller 126 can operate the air cooling system 230 to adjust a first flow rate of the chilled air supplied to first heat-generating data center equipment 240a based on the first power consumption. Controller 126 can operate the air cooling system 230 to adjust a second flow rate of the chilled air supplied to second heat-generating data center equipment 240b based on the second power consumption.

Controller 126 can estimate a first cooling load of first heat-generating data center equipment 240a based on the first power consumption. Controller 126 can estimate a second cooling load of second heat-generating data center equipment 240b based on the second power consumption. Controller 126 can operate cooling equipment 290 to provide the first amount of cooling to first heat-generating data center equipment 240a and provide the second amount of cooling to second heat-generating data center equipment 240b based on the first cooling load and the second cooling load respectively.

In some implementations, controller 126 can obtain a first temperature value affected by cooling the first heat-generating data center equipment 240a and a second temperature value affected by cooling the second heat-generating data center equipment 240b. Controller 126 can operate cooling equipment 290 to adjust the first amount of cooling based on the first power consumption and the first temperature value. Controller 126 can operate cooling equipment 290 to adjust the second amount of cooling based on the second power consumption and the second temperature value.

In some implementations, controller 126 may obtain a predicted power consumption of one or more of data center equipment 240a and 240b at a future time and may pre-allocate cooling to data center equipment 240a and 240b based on the predicted power consumption, in addition to or in lieu of the currently measured power consumption. For example, controller 126 may use historical power consumption data, time-varying demand information (e.g., intra-day, day-of-week, holiday, or seasonal demand patterns, as described above with reference to other embodiments), planned workload change data (e.g., scheduled software updates, batch jobs, or anticipated changes in resource allocation), and/or other relevant information to generate a predicted power consumption profile for data center equipment 240a and 240b at one or more future times. Controller 126 may operate cooling equipment 290 in advance of the predicted change in power consumption to provide an amount of cooling matched to the predicted future power consumption, thereby helping to maintain the temperatures of data center equipment 240a and 240b within target ranges as the power consumption varies over time.

In some implementations, controller 126 may continuously update the first power consumption, the second power consumption, the corresponding power consumption proportions, and the corresponding cooling allocations as the power consumption of data center equipment 240a and 240b varies over time. For example, controller 126 may sample the power consumption data from PDUs 176a and 176b, server power supplies, Hall effect sensors, shunt resistors, plug load meters, and/or model-based estimates at a configurable update interval (e.g., every several seconds, every minute, etc.), recompute the corresponding cooling allocations, and update the operation of cooling equipment 290 accordingly. In some implementations, controller 126 may apply hysteresis, dead bands, or rate-of-change limits to the cooling allocations to avoid excessive cycling of cooling equipment 290 in response to small or short-duration variations in power consumption.

In some implementations, the temperature feedback used in conjunction with the power consumption data may be obtained from one or more of various sources within data center cooling system 100, in a manner similar to that described above with reference to other embodiments. For example, controller 126 may receive temperature sensor data from a basic input/output system (BIOS), baseboard management controller (BMC), or other firmware or thermal management interface of one or more servers, server trays 104, processors, or other components of data center equipment 240a and 240b, from a DCIM system communicatively coupled to data center cooling system 100, and/or from one or more dedicated temperature sensors of data center cooling system 100 (e.g., temperature sensors connected to or embedded within a coolant supply line, a coolant return line, a cold plate 162, a coupling, or a manifold of rack 102 or server tray 104). Controller 126 may use the temperature feedback together with the power consumption data to refine the cooling allocations and to confirm that the allocated cooling is achieving the desired thermal conditions for data center equipment 240a and 240b.

Referring now to FIG. 17, illustrated is a method 280 of controlling a data center cooling system. The method 280 can be executed, performed, or otherwise carried out by data center cooling system 100 described herein (e.g., the embodiment of data center cooling system 100 illustrated in FIG. 16). In brief overview of the method 280, the method 280 can include determining a first power consumption of first data center equipment and a second power consumption of second data center equipment cooled by a data center cooling system (step 282), determining a first amount of cooling to provide to the first data center equipment based on the first power consumption and a second amount of cooling to provide to the second data center equipment based on the second power consumption (step 284), and operating the data center cooling system to provide the first amount of cooling to the first data center equipment and the second amount of cooling to the second data center equipment (step 286).

In some implementations, step 282 may involve power consumption calculator 292 determining the power consumption of data center equipment 240a and 240b. In some implementations, power consumption calculator 292 can calculate the total power consumption of all data center equipment 240a and 240b served by data center cooling system 100. Power consumption calculator 292 can also determine the individual power consumption of each system, component, or device of data center equipment 240a and 240b. In various embodiments, power consumption calculator 292 can determine the first power consumption and the second power consumption based on power supply information provided by PDUs 176a and 176b of the data center equipment 240a and 240b. For example, PDU 176a can report the amount of power supplied to rack 102a or server tray 104a, while PDU 176b can report the amount of power supplied to rack 102b or server tray 104b.

In some implementations, step 282 may involve power proportion calculator 293 determining the proportion of the power consumption of each system, component, or device of data center equipment 240a and 240b to the total power consumption of all data center equipment 240 served by cooling system 100. Power proportion calculator 293 can operate using the power consumption values calculated by power consumption calculator 292. The power consumption proportion for each system, component, or device of data center equipment 240a and 240b can indicate the ratio or percentage of the total power consumption attributable to that particular system, component, or device.

In various embodiments, step 284 may involve cooling distribution calculator 294 determining the amount of cooling to provide to each system, component, or device of data center equipment 240a and 240b based on the power consumption values determined by power consumption calculator 292 and/or the power consumption proportions determined by power proportion calculator 293. Cooling distribution calculator 294 can allocate cooling to each system, component, or device of data center equipment 240a and 240b proportional to its power consumption, in some embodiments. In some implementations, cooling distribution calculator 294 can determine a total amount of cooling to be provided by cooling system 100. Cooling distribution calculator 294 can adjust the first amount of cooling such that a proportion of the first amount of cooling to the total amount of cooling can be equal to the first proportion. Cooling distribution calculator 294 can adjust the second amount of cooling such that a proportion of the second amount of cooling to the total amount of cooling can be equal to the second proportion.

In some implementations, step 286 may involve cooling equipment controller 295 operating cooling equipment 290 of data center cooling system 100 to adjust the amounts of cooling provided to each system, component, or device of data center equipment 240a and 240b. Cooling equipment controller 295 can operate individual components of cooling equipment 290 to independently control the amount of cooling provided to each system, component, or device of data center equipment 240a and 240b individually. The amount of cooling can be controlled by adjusting the flow rates and/or temperatures of the liquid coolant and/or chilled air supplied to each system, component, or device of data center equipment 240a and 240b independently.

In various embodiments, step 286 may involve controller 126 operating liquid cooling system 220 to adjust a first flow rate of the liquid coolant supplied to first heat-generating data center equipment 240a based on the first power consumption. Controller 126 can operate liquid cooling system 220 to adjust a second flow rate of the liquid coolant supplied to second heat-generating data center equipment 240b based on the second power consumption. In some implementations, controller 126 can operate air cooling system 230 to adjust a first flow rate of the chilled air supplied to first heat-generating data center equipment 240a based on the first power consumption. Controller 126 can operate air cooling system 230 to adjust a second flow rate of the chilled air supplied to second heat-generating data center equipment 240b based on the second power consumption.

In various implementations, method 280 may include any of the steps, features, or functions described with respect to FIG. 16, and all such implementations are contemplated within the scope of the present disclosure.

### Configuration of Exemplary Embodiments

The arrangement, construction, and description of the systems and methods as shown in the various exemplary examples are illustrative only. While some examples have been described herein, several modifications and/or adjustments are possible (e.g., variations in sizes, dimensions, structures, shapes, and proportions of the various elements, values of parameters, mounting arrangements, use of materials, colors, orientations, etc.). For example, the position of elements can be reversed or otherwise varied and the nature or number of discrete elements or positions can be altered or varied. Accordingly, all such modifications are intended to be included within the scope of the present disclosure. The order or sequence of any process or method steps can be varied or re-sequenced according to alternative embodiments. Other substitutions, modifications, changes, and omissions can be made in the design, operating conditions, and arrangement of the exemplary embodiments without departing from the scope of the present disclosure.

The present disclosure contemplates methods, systems, and program products on any machine-readable media for accomplishing various operations. The embodiments of the present disclosure can be implemented using existing computer processors, or by a special purpose computer processor for an appropriate system, incorporated for this or another purpose, or by a hardwired system. Embodiments within the scope of the present disclosure include program products comprising machine-readable media for carrying or having machine-executable instructions or data structures stored thereon. Such machine-readable media can be any available media that can be accessed by a general purpose or special purpose computer or other machine with a processor. By way of example, such machine-readable media can comprise RAM, ROM, EPROM, EEPROM, CD-ROM or other optical disk storage, magnetic disk storage or other magnetic storage devices, or any other medium which can be used to carry or store desired program code in the form of machine-executable instructions or data structures and which can be accessed by a general purpose or special purpose computer or other machine with a processor. Combinations of the above are also included within the scope of machine-readable media. Machine-executable instructions include, for example, instructions and data which cause a general-purpose computer, special purpose computer, or special purpose processing machines to perform a certain function or group of functions.

As used herein, an element or step recited in the singular and proceeded with the word “a” or “an” should be understood as not excluding plural elements or steps, unless such exclusion is explicitly recited. Furthermore, references to “exemplary embodiment,” “one embodiment,” or “some embodiment” of the present disclosure are not intended to be interpreted as excluding the existence of additional embodiments that also incorporate the recited features.

It should be noted that the term “exemplary” and variations thereof, as used herein to describe various embodiments, are intended to indicate that such embodiments are possible examples, representations, or illustrations of possible embodiments (and such terms are not intended to connote that such embodiments are necessarily extraordinary or superlative examples).

The patent claims at the end of this document are not intended to be construed as means-plus-function elements (e.g., under 35 U.S.C. § 112(f)) unless “means for” or “step for” is expressly recited in the claim(s).

Although the figures show a specific order of method steps, the order of the steps may differ from what is depicted. Also, two or more steps can be performed concurrently or with partial concurrence. Such variation will depend on the software and hardware systems chosen and on designer choice. All such variations are within the scope of the disclosure. Likewise, software implementations could be accomplished with standard programming techniques with rule-based logic and other logic to accomplish the various connection steps, processing steps, comparison steps and decision steps.

Conditional language used herein, such as, among others, “can,” “could,” “might,” “may,” “e.g.,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without other input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list.

It may be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It may be further understood by those within the art that if a specific number of an introduced claim recitation is intended, such an intent may be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to inventions containing only one such recitation, even when the same claim includes the introductory phrases “one or more” or “at least one” and indefinite articles such as “a” or “an” (e.g., “a” and/or “an” should typically be interpreted to mean “at least one” or “one or more”); the same holds true for the use of definite articles used to introduce claim recitations. In addition, even if a specific number of an introduced claim recitation is explicitly recited, those skilled in the art may recognize that such recitation should typically be interpreted to mean at least the recited number (e.g., the bare recitation of “two recitations,” without other modifiers, typically means at least two recitations, or two or more recitations). Furthermore, in those instances where a convention analogous to “at least one of A, B, and C” is used, or “at least one of A, B, or C” is used, in both cases such usage should be interpreted as covering any permutation of A, B, or C, alone or in combination, unless expressly indicated otherwise (e.g., “a system having at least one of A, B, and C” would include systems that have A alone, B alone, C alone, A and B together, A and C together, B and C together, and A, B, and C together). It may be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” may be understood to include the possibilities of “A” or “B” or “A and B.” Further, the use of the words “approximate,” “about,” “around,” “substantially,” etc., may mean plus or minus ten percent, in some implementations.

The term “coupled” and variations thereof, as used herein, means the joining of two members directly or indirectly to one another. Such joining may be stationary (e.g., permanent, or fixed) or moveable (e.g., removable, or releasable). Such joining may be achieved with the two members coupled directly to each other, with the two members coupled to each other using a separate intervening member and any additional intermediate members coupled with one another, or with the two members coupled to each other using an intervening member that is integrally formed as a single unitary body with one of the two members. If “coupled” or variations thereof are modified by an additional term (e.g., directly coupled), the generic definition of “coupled” provided above is modified by the plain language meaning of the additional term (e.g., “directly coupled” means the joining of two members without any separate intervening member), resulting in a narrower definition than the generic definition of “coupled” provided above. Such coupling may be mechanical, electrical, or fluidic.

In various implementations, the steps and operations described herein may be performed on one processor or in a combination of two or more processors. For example, in some implementations, the various operations could be performed in a central server or set of central servers configured to receive data from one or more devices (e.g., edge computing devices/controllers) and perform the operations. In some implementations, the operations may be performed by one or more local controllers or computing devices (e.g., edge devices), such as controllers dedicated to and/or located within a particular industrial environment or portion of an industrial environment. In some implementations, the operations may be performed by a combination of one or more central or offsite computing devices/servers and one or more local controllers/computing devices. All such implementations are contemplated within the scope of the present disclosure. Further, unless otherwise indicated, when the present disclosure refers to one or more computer-readable storage media and/or one or more controllers, such computer-readable storage media and/or one or more controllers may be implemented as one or more central servers, one or more local controllers or computing devices (e.g., edge devices), any combination thereof, or any other combination of storage media and/or controllers regardless of the location of such devices.

What is claimed is:

1. A data center cooling system comprising:
cooling equipment operable to independently control a first amount of cooling provided to first heat-generating data center equipment within a data center and a second amount of cooling provided to second heat-generating data center equipment within the data center; and
a controller comprising one or more processing circuits and configured to:
determine a first power consumption of the first heat-generating data center equipment and a second power consumption of the second heat-generating data center equipment; and
operate the cooling equipment to adjust the first amount of cooling based on the first power consumption and adjust the second amount of cooling based on the second power consumption.

2. The data center cooling system of claim 1, wherein the controller is configured to determine the first power consumption and the second power consumption based on power supply information provided by one or more power distribution units that supply power to the first heat-generating data center equipment and the second heat-generating data center equipment.

3. The data center cooling system of claim 1, wherein
the first heat-generating data center equipment are located within a first rack of the data center;
the second heat-generating data center equipment are located within a second rack of the data center; and
the controller is configured to determine the first power consumption and the second power consumption based on power supply information provided by a first power distribution unit for the first rack and a second power distribution unit for the second rack.

4. The data center cooling system of claim 1, wherein
the first heat-generating data center equipment are installed on a first server tray located within a rack of the data center;
the second heat-generating data center equipment are installed on a second server tray located within the rack of the data center; and
the controller is configured to determine the first power consumption and the second power consumption based on respective amounts of power delivered to the first server tray and the second server tray by a power distribution unit for the rack.

5. The data center cooling system of claim 1, wherein the controller is configured to adjust the first amount of cooling and the second amount of cooling to be proportionate to the first power consumption and the second power consumption respectively.

6. The data center cooling system of claim 1, wherein the controller is configured to:
determine a first proportion of the first power consumption to a total power consumption of heat-generating data center equipment served by the cooling system;
determine a second proportion of the second power consumption to the total power consumption of the heat-generating data center equipment served by the cooling system; and
operate the cooling equipment to adjust the first amount of cooling and the second amount of cooling based on the first proportion and the second proportion respectively.

7. The data center cooling system of claim 6, wherein the controller is configured to:
determine a total amount of cooling to be provided by the cooling system;
adjust the first amount of cooling such that a proportion of the first amount of cooling to the total amount of cooling is equal to the first proportion; and
adjust the second amount of cooling such that a proportion of the second amount of cooling to the total amount of cooling is equal to the second proportion.

8. The data center cooling system of claim 1, wherein:
the cooling equipment comprise a liquid cooling system configured to supply a liquid coolant to the first heat-generating data center equipment and the second heat-generating data center equipment; and
the controller is configured to:
operate the liquid cooling system to adjust a first flow rate of the liquid coolant supplied to the first heat-generating data center equipment based on the first power consumption; and
operate the liquid cooling system to adjust a second flow rate of the liquid coolant supplied to the second heat-generating data center equipment based on the second power consumption.

9. The data center cooling system of claim 8, wherein the controller is configured to adjust the first flow rate of the liquid coolant supplied to the first heat-generating data center equipment and the second flow rate of the liquid coolant supplied to the second heat-generating data center equipment to be proportionate to the first power consumption and the second power consumption respectively.

10. The data center cooling system of claim 1, wherein:
the cooling equipment comprise an air cooling system configured to supply chilled air to the first heat-generating data center equipment and the second heat-generating data center equipment; and
the controller is configured to:
operate the air cooling system to adjust a first flow rate of the chilled air supplied to the first heat-generating data center equipment based on the first power consumption; and
operate the air cooling system to adjust a second flow rate of the chilled air supplied to the second heat-generating data center equipment based on the second power consumption.

11. The data center cooling system of claim 10, wherein the controller is configured to adjust the first flow rate of the chilled air supplied to the first heat-generating data center equipment and the second flow rate of the chilled air supplied to the second heat-generating data center equipment to be proportionate to the first power consumption and the second power consumption respectively.

12. The data center cooling system of claim 1, wherein the controller is configured to:
estimate a first cooling load of the first heat-generating data center equipment based on the first power consumption;
estimate a second cooling load of the second heat-generating data center equipment based on the second power consumption; and
operate the cooling equipment to provide the first amount of cooling the first heat-generating data center equipment and provides the second amount of cooling the second heat-generating data center equipment based on the first cooling load and the second cooling load respectively.

13. The data center cooling system of claim 1, wherein:
the cooling equipment comprise a liquid cooling system configured to supply a liquid coolant to the first heat-generating data center equipment and the second heat-generating data center equipment; and
operating the cooling equipment comprises operating one or more pumps or valves of the liquid cooling system to control a distribution of the liquid coolant to the first heat-generating data center equipment and the second heat-generating data center equipment based on the first power consumption and the second power consumption.

14. The data center cooling system of claim 13, wherein controlling the distribution of the liquid coolant comprises:
adjusting a first flow rate of the liquid coolant supplied to the first heat-generating data center equipment based on the first power consumption; and
adjusting a second flow rate of the liquid coolant supplied to the second heat-generating data center equipment based on the second power consumption.

15. The data center cooling system of claim 1, wherein:
the cooling equipment comprise an air cooling system configured to supply chilled air to the first heat-generating data center equipment and the second heat-generating data center equipment; and
operating the cooling equipment comprises operating one or more fans or dampers of the air cooling system to control a distribution of the chilled air to the first heat-generating data center equipment and the second heat-generating data center equipment based on the first power consumption and the second power consumption.

16. The data center cooling system of claim 15, wherein controlling the distribution of the chilled air comprises:
adjusting a first flow rate of the chilled air supplied to the first heat-generating data center equipment based on the first power consumption; and
adjusting a second flow rate of the chilled air supplied to the second heat-generating data center equipment based on the second power consumption.

17. The data center cooling system of claim 1, wherein the controller is configured to determine the first power consumption and the second power consumption based on measurements from one or more sensors within the data center.

18. A method for cooling heat-generating data center equipment comprising:
determining a first power consumption of first heat-generating data center equipment and a second power consumption of second heat-generating data center equipment cooled by a data center cooling system;
determining a first amount of cooling to provide to the first heat-generating data center equipment based on the first power consumption and a second amount of cooling to provide to the second heat-generating data center equipment based on the second power consumption; and
operating the data center cooling system to provide the first amount of cooling to the first heat-generating data center equipment and the second amount of cooling to the second heat-generating data center equipment.

19. The method of claim 18, comprising determining the first power consumption and the second power consumption based on power supply information provided by one or more power distribution units that supply power to the first heat-generating data center equipment and the second heat-generating data center equipment.

20. The method of claim 18, wherein
the first heat-generating data center equipment are located within a first rack of the data center;
the second heat-generating data center equipment are located within a second rack of the data center; and
the first power consumption and the second power consumption are determined based on power supply information provided by a first power distribution unit for the first rack and a second power distribution unit for the second rack.
